(19) United States
(12) Patent Application Publication
(10) Pub. No.: US 2024/0284754 A1
(43) Pub. Date: Aug. 22, 2024

(54) DISPLAY APPARATUS

(71) Applicant: Semiconductor Energy Laboratory Co., Ltd., Atsugi-shi, Kanagawa-ken (JP)

(72) Inventors: Daisuke KUBOTA, Atsugi (JP); Akio YAMASHITA, Atsugi (JP); Taisuke KAMADA, Niiza (JP); Daiki NAKAMURA, Atsugi (JP)

(21) Appl. No.: 18/560,714

(22) PCT Filed: May 18, 2022
(86) PCT No.: PCT/IB2022/054596

§ 371 Date: Nov. 14, 2023

(30) Foreign Application Priority Data
May 27, 2021 (JP) 2021-089273

(51) Int. Cl. H10K 59/65; H10K 59/40; H10K 102/00

(52) U.S. Cl. CPC H10K 59/65; H10K 59/40; H10K 2102/351

(57) ABSTRACT

A display apparatus having a light detection function with high accuracy is to be provide. The display apparatus includes a light-receiving device, a first light-emitting device, and an insulating layer. The light-receiving device includes a first electrode, a light-receiving layer, and a common electrode. The first light-emitting device includes a second electrode, a first EL layer, and the common electrode. The light-receiving layer includes a first functional layer, a second functional layer, and an active layer provided therebetween. The first functional layer contains a first substance having a hole-transport property. The second functional layer contains a second substance having an electron-transport property. An end portion of the active layer, an end portion of the first functional layer, and an end portion of the second functional layer are aligned or substantially aligned with one another. The first EL layer includes a third functional layer, a fourth functional layer, and a first light-emitting layer provided therebetween. The third functional layer contains a third substance having a hole-transport property. The fourth functional layer contains a fourth substance having an electron-transport property. The insulating layer includes regions in contact with a side surface of the light-receiving layer and a side surface of the first EL layer.

### TECHNICAL FIELD

One embodiment of the present invention relates to a display apparatus. One embodiment of the present invention relates to a method for manufacturing a display apparatus.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a fabricating method thereof. A semiconductor device refers to any device that can function by utilizing semiconductor characteristics.

### BACKGROUND ART

In recent years, display apparatuses have been used in a variety of devices such as information terminal devices such as smartphones, tablet terminals, and laptop PCs, television devices, and monitor devices. In addition, display apparatuses have been required to have a variety of functions such as a touch sensor function and a function of capturing images of fingerprints for authentication, in addition to a function of displaying images.

Light-emitting apparatuses including light-emitting devices (also referred to as light-emitting elements) have been developed as display apparatuses, for example. Light-emitting devices (also referred to as EL devices or EL elements) utilizing electroluminescence (EL) have features such as ease of reduction in thickness and weight, high-speed response to input signals, and driving with a constant DC voltage power source, and have been used in display apparatuses. For example, Patent Document 1 discloses a flexible light-emitting apparatus using an organic EL device (also referred to as organic EL element).

### REFERENCE

### [Patent Document]

[Patent Document 1] Japanese Published Patent Application No. 2014-197522

### SUMMARY OF THE INVENTION

### Problems to be Solved by the Invention

An object of one embodiment of the present invention is to provide a high-resolution display apparatus having a light detection function. An object of one embodiment of the present invention is to provide a display apparatus having a light detection function with high accuracy. An object of one embodiment of the present invention is to provide a display apparatus having a light detection function and low power consumption. An object of one embodiment of the present invention is to provide a highly reliable display apparatus having a light detection function. An object of one embodiment of the present invention is to provide a novel display apparatus.

Note that the description of these objects does not preclude the existence of other objects. Note that one embodiment of the present invention does not have to achieve all the objects. Note that other objects can be derived from the description of the specification, the drawings, the claims, and the like.

### Means for Solving the Problems

One embodiment of the present invention is a display apparatus including a light-receiving device, a first light-emitting device, and an insulating layer. The light-receiving device includes a first electrode, a light-receiving layer, and a common electrode that are stacked in this order. The first light-emitting device includes a second electrode, a first EL layer, and the common electrode that are stacked in this order. The light-receiving layer includes a first functional layer, a second functional layer, and an active layer between the first functional layer and the second functional layer. The first functional layer contains a first substance having a hole-transport property. The second functional layer contains a second substance having an electron-transport property. An end portion of the active layer, an end portion of the first functional layer, and an end portion of the second functional layer are aligned or substantially aligned with one another. The first EL layer includes a third functional layer, a fourth functional layer, and a first light-emitting layer between the third functional layer and the fourth functional layer. The third functional layer contains a third substance having a hole-transport property. The fourth functional layer contains a fourth substance having an electron-transport property. The insulating layer includes a region in contact with a side surface of the light-receiving layer and a region in contact with a side surface of the first EL layer.

In the display apparatus, the first substance is preferably the same as the third substance.

In the display apparatus, the second substance is preferably the same as the fourth substance.

In the display apparatus, the active layer preferably contains a fifth substance, and the first light-emitting layer preferably contains a sixth substance different from the fifth substance.

In the display apparatus, the side surface of the light-receiving layer is preferably perpendicular or substantially perpendicular to a surface where the light-receiving layer is formed.

In the display apparatus, the side surface of the first EL layer is preferably perpendicular or substantially perpendicular to a surface where the first EL layer is formed.

In the display apparatus, an end portion of the first light-emitting layer, an end portion of the third functional layer, and an end portion of the fourth functional layer are preferably aligned or substantially aligned with one another.

In the display apparatus, the first light-emitting layer preferably has a smaller thickness in a region in contact with the insulating layer than a thickness in a region not in contact with the insulating layer.

In the display apparatus, the end portion of the first light-emitting layer is preferably positioned more inwardly than the end portion of the third functional layer and the end portion of the fourth functional layer.

In the display apparatus, an end portion of the light-receiving layer is preferably positioned more inwardly than an end portion of the first electrode. The insulating layer preferably includes a region in contact with the side surface of the light-receiving layer and a region in contact with a top surface and a side surface of the first electrode.

In the display apparatus, an end portion of the first EL layer is preferably positioned more inwardly than an end portion of the second electrode. The insulating layer preferably includes a region in contact with the side surface of the first EL layer and a region in contact with a top surface and a side surface of the second electrode.

In the display apparatus, the active layer preferably includes a region overlapping with the first electrode with the first functional layer therebetween.

In the display apparatus, the active layer preferably includes a region overlapping with the first electrode with the second functional layer therebetween.

In the display apparatus, the first light-emitting layer preferably includes a region overlapping with the second electrode with the third functional layer therebetween.

In the display apparatus, the first light-emitting layer preferably includes a region overlapping with the second electrode with the third functional layer therebetween.

The display apparatus preferably includes a second light-emitting device. The second light-emitting device includes a third electrode, a second EL layer, and the common electrode that are stacked in this order. The second EL layer preferably includes a fifth functional layer, a sixth functional layer, and a second light-emitting layer between the fifth functional layer and the sixth functional layer. The fifth functional layer includes a third substance. The sixth functional layer includes a fourth substance.

The display apparatus preferably includes a second light-emitting device. The second light-emitting device includes a third electrode, a second EL layer, and the common electrode that are stacked in this order. The second EL layer includes a third functional layer, a fourth functional layer, and a second light-emitting layer between the third functional layer and the fourth functional layer.

### Effect of the Invention

According to one embodiment of the present invention, a high-resolution display apparatus having a light detection function can be provided. According to one embodiment of the present invention, a display apparatus having a light detection function with high accuracy can be provided. According to one embodiment of the present invention, a display apparatus having a light detection function and low power consumption can be provided. According to one embodiment of the present invention, a highly reliable display apparatus having a light detection function can be provided. According to one embodiment of the present invention, a novel display apparatus can be provided.

Note that the description of these effects does not preclude the existence of other effects. Note that one embodiment of the present invention does not need to have all the effects. Note that other effects can be derived from the description of the specification, the drawings, and the claims.

### BRIEF DESCRIPTION OF THE DRAWINGS

FIG. 1A to FIG. 1D are cross-sectional views illustrating a structure example of a display apparatus.

FIG. 1E is a diagram illustrating an example of a captured image.

FIG. 2A to FIG. 2D are cross-sectional views illustrating structure examples of a display apparatus.

FIG. 3A and FIG. 3B are cross-sectional views illustrating a structure example of a display apparatus.

FIG. 4A is a top view illustrating a structure example of a display apparatus. FIG. 4B is a cross-sectional view illustrating a structure example of the display apparatus.

FIG. 5A to FIG. 5D are cross-sectional views illustrating a structure example of a display apparatus.

FIG. 6A to FIG. 6C are cross-sectional views each illustrating a structure example of a display apparatus.

FIG. 7A to FIG. 7C are cross-sectional views each illustrating a structure example of a display apparatus.

FIG. 8A to FIG. 8C are cross-sectional views each illustrating a structure example of a display apparatus.

FIG. 9A to FIG. 9C are cross-sectional views each illustrating a structure example of a display apparatus.

FIG. 10A to FIG. 10C are cross-sectional views each illustrating a structure example of a display apparatus.

FIG. 11A to FIG. 11C are cross-sectional views each illustrating a structure example of a display apparatus.

FIG. 12A to FIG. 12C are cross-sectional views each illustrating a structure example of a display apparatus.

FIG. 13A to FIG. 13C are cross-sectional views each illustrating a structure example of a display apparatus.

FIG. 14A to FIG. 14C are cross-sectional views each illustrating a structure example of a display apparatus.

FIG. 15A to FIG. 15C are cross-sectional views each illustrating a structure example of a display apparatus.

FIG. 16A to FIG. 16C are cross-sectional views each illustrating a structure example of a display apparatus.

FIG. 17A to FIG. 17C are cross-sectional views each illustrating a structure example of a display apparatus.

FIG. 18A to FIG. 18E are cross-sectional views illustrating an example of a method for manufacturing a display apparatus.

FIG. 19A to FIG. 19D are cross-sectional views illustrating an example of a method for manufacturing a display apparatus.

FIG. 20A to FIG. 20E are cross-sectional views illustrating an example of a method for manufacturing a display apparatus.

FIG. 21A to FIG. 21D are cross-sectional views illustrating an example of a method for manufacturing a display apparatus.

FIG. 22A and FIG. 22B are cross-sectional views illustrating an example of a method for manufacturing a display apparatus.

FIG. 23A to FIG. 23D are cross-sectional views illustrating an example of a method for manufacturing a display apparatus.

FIG. 24A to FIG. 24D are cross-sectional views illustrating an example of a method for manufacturing a display apparatus.

FIG. 25A to FIG. 25E are cross-sectional views illustrating an example of a method for manufacturing a display apparatus.

FIG. 26A and FIG. 26B are top views each illustrating a structure example of a display apparatus.

FIG. 27A and FIG. 27B are perspective views illustrating an example of a display apparatus.

FIG. 28 is a cross-sectional view illustrating an example of a display apparatus.

FIG. 29 is a cross-sectional view illustrating an example of a display apparatus.

FIG. 30 is a cross-sectional view illustrating an example of a display apparatus.

FIG. 31 is a cross-sectional view illustrating an example of a display apparatus.

FIG. 32 is a cross-sectional view illustrating an example of a display apparatus.

FIG. 33 is a cross-sectional view illustrating an example of a display apparatus.

FIG. 34 is a perspective view illustrating an example of a display apparatus.

FIG. 35A is a cross-sectional view illustrating an example of a display apparatus. FIG. 35B and FIG. 35C are cross-sectional views illustrating examples of transistors.

FIG. 36 is a cross-sectional view illustrating an example of a display apparatus.

FIG. 37A to FIG. 37D are cross-sectional views each illustrating a structure example of a light-emitting device.

FIG. 38A to FIG. 38G are diagrams each illustrating a structure example of a light-emitting and light-receiving device.

FIG. 39A to FIG. 39E are diagrams each illustrating an example of an electronic device.

### MODE FOR CARRYING OUT THE INVENTION

Hereinafter, embodiments will be described with reference to the drawings. Note that the embodiments can be implemented in many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

In each drawing described in this specification, the size, the layer thickness, or the region of each component is exaggerated for clarity in some cases. Therefore, the size, the layer thickness, or the region is not necessarily limited to the illustrated scale.

In this specification and the like, ordinal numbers such as “first,” “second,” and the like are used in order to avoid confusion among components and do not limit the number.

In this specification and the like, the term “film” and the term “layer” can be interchanged with each other. For example, in some cases, the term “conductive layer” or “insulating layer” can be interchanged with the term “conductive film” or “insulating film.”

Note that in this specification and the like, an EL layer means a layer containing at least a light-emitting substance (also referred to as a light-emitting layer) or a stacked-layer body including the light-emitting layer provided between a pair of electrodes of a light-emitting device.

In this specification and the like, a display panel that is one embodiment of a display apparatus has a function of displaying (outputting) an image or the like on (to) a display surface.

Thus, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, a display apparatus of one embodiment of the present invention will be described.

The display apparatus of one embodiment of the present invention includes a display portion, and the display portion includes a plurality of pixels arranged in a matrix. The pixel includes a light-emitting device and a light-receiving device (also referred to as a light-receiving element). The light-emitting device functions as a display device (also referred to as a display element). In the display apparatus of one embodiment of the present invention, the light-emitting devices are arranged in a matrix in the display portion, and an image can be displayed on the display portion. In addition, the display apparatus of one embodiment of the present invention has a function of detecting light with use of the light-receiving devices.

The light-receiving devices are arranged in a matrix in the display portion of the display apparatus of one embodiment of the present invention, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the case where the light-receiving devices are used as an image sensor, the display apparatus can capture an image with use of the light-receiving devices. For example, the display apparatus of this embodiment can be used as a scanner.

For example, data on biological information such as a fingerprint or a palm print can be obtained with use of the image sensor. That is, a biometric authentication sensor can be incorporated in the display apparatus. When the display apparatus incorporates a biometric authentication sensor, the number of components of an electronic device can be reduced as compared with the case where a biometric authentication sensor is provided separately from the display apparatus; thus, a small and lightweight electronic device can be achieved.

In the case where the light-receiving devices are used as the touch sensor, the display apparatus can detect the approach or contact of a target with use of the light-receiving devices.

Note that in this specification and the like, a device manufactured using a metal mask or an FMM (fine metal mask or high-resolution metal mask) is sometimes referred to as a device having an MM (metal mask) structure. In addition, in this specification and the like, a device manufactured without using a metal mask or an FMM is sometimes referred to as a device having an MML (metal maskless) structure.

More specific examples are described below with reference to drawings.

### Structure Example 1

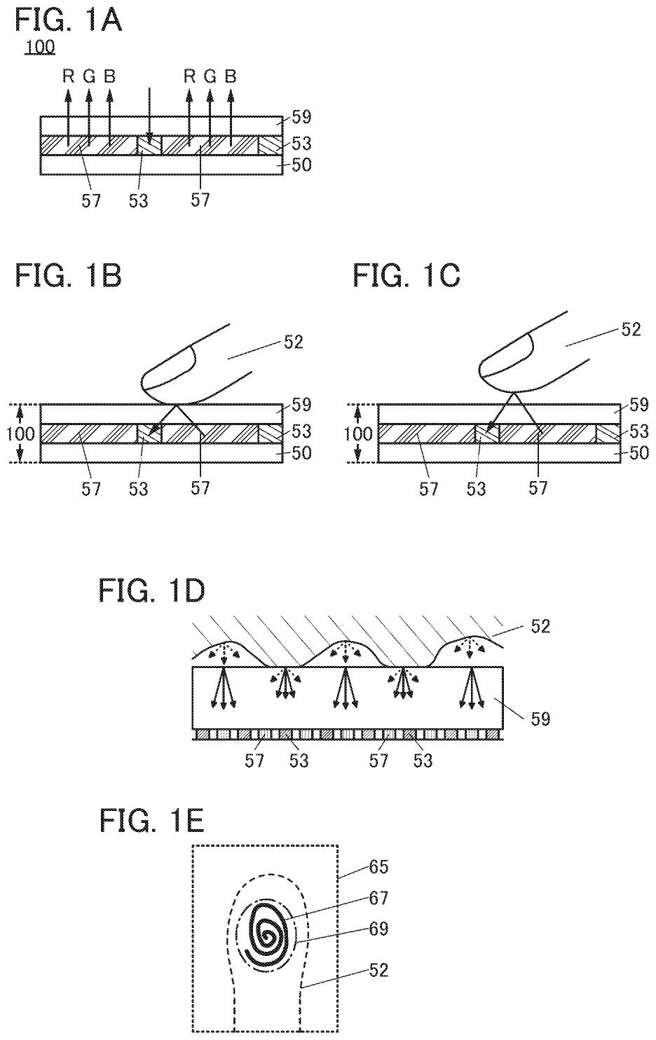

FIG. 1A to FIG. 1D illustrate cross-sectional views illustrating a structure example of a display apparatus of one embodiment of the present invention.

A display apparatus 100 illustrated in FIG. 1A includes a layer 53 including light-receiving devices and a layer 57 including light-emitting devices, between a substrate 50 and a substrate 59.

FIG. 1A illustrates a structure in which light of red (R), green (G), and blue (B) is emitted from the layer 57 including light-emitting devices and light is incident on the layer 53 including light-receiving devices. Note that the light emitted from the layer 57 and the light incident on the layer 53 are indicated by arrows in FIG. 1A.

In this specification and the like, a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range. In this specification and the like, a wavelength range of visible light is greater than or equal to 400 nm and less than 700 nm, and visible light has at least one emission spectrum peak in the wavelength range. An infrared (IR) wavelength range is greater than or equal to 700 nm and less than 900 nm, and infrared (IR) light has at least one emission spectrum peak in the wavelength range.

In the display apparatus of one embodiment of the present invention, the plurality of pixels arranged in a matrix are provided in the display portion. One pixel includes one or more subpixels. Each of the subpixels includes a light-emitting device or a light-receiving device. A pixel can include four subpixels, for example. Specifically, one pixel can include a subpixel that includes a light-emitting device emitting red (R) light, a subpixel that includes a light-emitting device emitting green (G) light, a subpixel that includes a light-emitting device emitting blue (B) light, and a subpixel that includes a light-receiving device. The light-receiving device preferably has sensitivity in the visible light wavelength range. Alternatively, the light-receiving device preferably has sensitivity in the visible light wavelength range and the infrared light wavelength range.

Note that the combination of the colors of light emitted by the light-emitting devices included in the pixel is not limited to three colors of red (R), green (G), and blue (B). The combination of the colors of light emitted by the light-emitting devices included in the pixel can be, for example, three colors of yellow (Y), cyan (C), and magenta (M). Note that the number of colors of light emitted by the light-emitting devices included in the pixel may be four or more.

The pixel may include five or more subpixels. Specifically, one pixel can include four kinds of light-emitting devices of red (R), green (G), blue (B), and white (W) and a light-receiving device. Alternatively, one pixel can include four kinds of light-emitting devices of red (R), green (G), blue (B), and infrared (IR) and a light-receiving device. Note that the light-receiving device may be provided in all the pixels or may be provided in some of the pixels. Note that one pixel may include a plurality of light-receiving devices. For example, one pixel can include three kinds of light-emitting devices of red (R), green (G), and blue (B), a light-receiving device that has sensitivity in the wavelength range of visible light, and a light-receiving device that has sensitivity in the wavelength range of infrared light.

The display apparatus of one embodiment of the present invention can have a function of detecting a target in contact with the display apparatus. The target is not particularly limited and can be a living body or an object. In the case where the target is a living body, the display apparatus can have a function of detecting a finger or a palm, for example. As illustrated in FIG. 1B, a finger 52 in contact with the display apparatus 100 reflects light emitted by the light-emitting devices included in the layer 57, and the light-receiving devices included in the layer 53 detect the reflected light. Thus, the contact of the finger 52 with the display apparatus 100 can be detected. In other words, the display apparatus of one embodiment of the present invention can have a function as, for example, a touch sensor (also referred to as a direct-touch sensor). As illustrated in FIG. 1C, the finger 52 approaching the display apparatus 100 reflects light emitted by the light-emitting devices included in the layer 57, and the light-receiving devices included in the layer 53 detect the reflected light. Thus, the approach of the finger 52 to the display apparatus 100 can be detected. In other words, the display apparatus of one embodiment of the present invention can have a function of a near-touch sensor (also referred to as a hover sensor, a hover touch sensor, a contactless sensor, or a touchless sensor).

In the case where the display apparatus 100 has a function of a near-touch sensor, even when the finger 52 is not in contact with the display apparatus 100, the finger 52 can be detected when the finger 52 approaches the display apparatus 100. For example, a structure is preferable in which the display apparatus 100 can detect the finger 52 when a distance between the display apparatus 100 and the finger 52 is more than or equal to 0.1 mm and less than or equal to 300 mm, preferably more than or equal to 3 mm and less than or equal to 50 mm. With this structure, the display apparatus 100 can be operated without a direct contact of the finger 52 with the display apparatus 100; in other words, the display apparatus 100 can be operated in a contactless (touchless) manner. With the above structure, the display apparatus 100 can be operated with a reduced risk of making the display apparatus 100 dirty or damaging the display apparatus 100 or without the finger 52 being in direct contact with a dirt (e.g., dust, bacteria, or a virus) that can be attached to the display apparatus 100.

The display apparatus of one embodiment of the present invention can have a function of capturing an image of a target in contact with the display apparatus. The display apparatus can have a function of detecting the fingerprint of the finger 52, for example. FIG. 1D schematically illustrates an enlarged view of a contact portion in a state where the finger 52 touches the substrate 59. Furthermore, FIG. 1D illustrates a state where the layers 57 including light-emitting devices and the layers 53 including light-receiving devices are alternately arranged.

The fingerprint of the finger 52 is formed of depressions and projections. Therefore, as illustrated in FIG. 1D, the projections of the fingerprint touch the substrate 59.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 52. Meanwhile, regular reflection components are dominant in the light reflected from the interface between the substrate 59 and the air.

The intensity of light that is reflected on a contact surface or a non-contact surface between the finger 52 and the substrate 59 and is incident on the layer 53 positioned directly below the contact surface or the non-contact surface is the sum of intensities of regularly reflected light and diffusely reflected light. As described above, regularly reflected light (indicated by solid arrows) is dominant in the depressions of the finger 52 where the finger 52 does not touch the substrate 59, whereas diffusely reflected light (indicated by dashed arrows) from the finger 52 is dominant in the projections where the finger 52 touches the substrate 59. Thus, the intensity of light received by the light-receiving device of the layer 53 positioned directly below the depression is higher than the intensity of light received by the light-receiving device of the layer 53 positioned directly below the projection. Accordingly, an image of the fingerprint of the finger 52 can be captured using the light-receiving devices.

In the case where an arrangement interval between the light-receiving devices of the layers 53 is smaller than a distance between two projections of a fingerprint, preferably a distance between a depression and a projection adjacent to each other, a clear fingerprint image can be obtained. A distance between a depression and a projection of a human's fingerprint is generally within a range from 150 μm to 250 μm; thus, the arrangement interval between the light-receiving devices is, for example, less than or equal to 400 μm, preferably less than or equal to 200 μm, further preferably less than or equal to 150 μm, still further preferably less than or equal to 120 μm, yet further preferably less than or equal to 100 μm, yet still further preferably less than or equal to 50 μm. The arrangement interval is preferably as small as possible, and can be more than or equal to 1 μm, more than or equal to 10 μm, or more than or equal to 20 μm, for example.

FIG. 1E is an example of a fingerprint image captured by the display apparatus of one embodiment of the present invention. In FIG. 1E, the outline of the finger 52 is indicated by a dashed line and the outline of a contact portion 69 is indicated by a dashed-dotted line in a region 65. In the region 65, a high-contrast image of a fingerprint 67 can be captured owing to a difference in the amount of light incident on the light-receiving devices. Furthermore, fingerprint authentication can be performed using the obtained fingerprint image. Note that the example of capturing the fingerprint image with the finger regarded as a target is described here; however, one embodiment of the present invention is not limited thereto. For example, the display apparatus can detect a palm in contact with or approaching the display portion. In addition, the display apparatus can capture a palm print image and can perform palm print authentication using the obtained palm print image.

As described above, in the display apparatus of one embodiment of the present invention, the light-receiving device can detect light that is emitted from the light-emitting device to be delivered on the target and is reflected by the target. Accordingly, the target in contact with or approaching the display portion can be detected even in a dark place. Furthermore, the display apparatus can perform authentication such as fingerprint authentication and palm print authentication.

Providing the light-receiving devices in the display portion eliminates the need for attachment of an external sensor to the display apparatus. Thus, the number of components can be reduced, whereby a small and lightweight display apparatus can be achieved.

As the substrate 50, a substrate having heat resistance high enough to withstand the formation of the light-emitting device and the light-receiving device can be used. In the case where an insulating substrate is used as the substrate 50, a glass substrate, a quartz substrate, a sapphire substrate, a ceramics substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium or the like, or a semiconductor substrate such as an SOI substrate can be used.

As the substrate 50, it is particularly preferable to use the above-described insulating substrate or semiconductor substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### Structure Example 2

### Structure Example 2-1

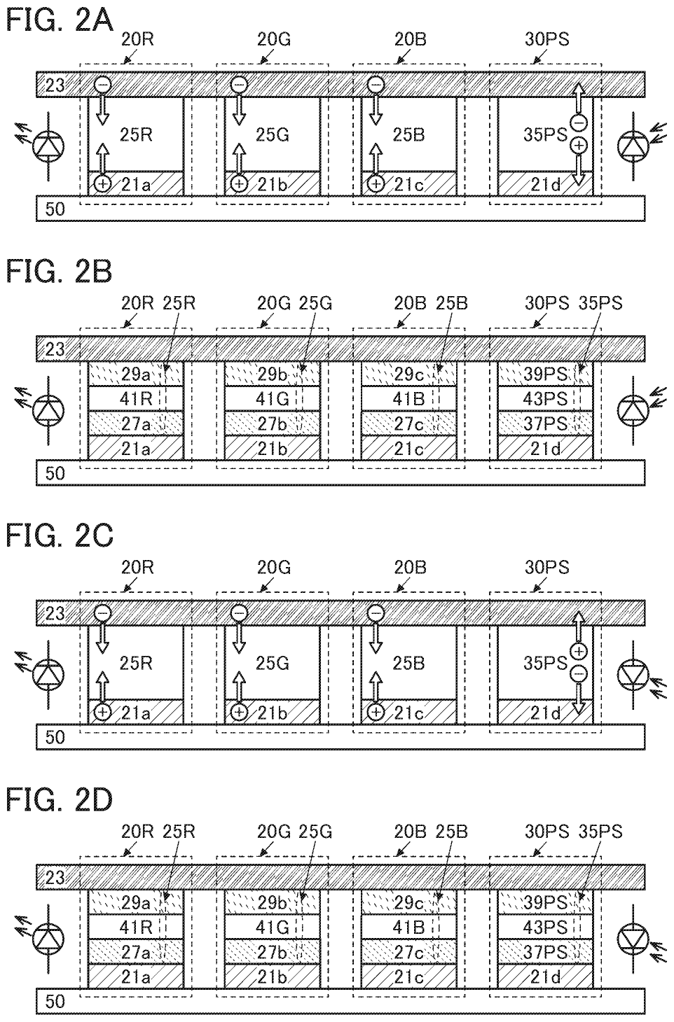

Structures of light-emitting devices and a light-receiving device that can be used in a display apparatus of one embodiment of the present invention are described. FIG. 2A is a schematic cross-sectional view of the display apparatus of one embodiment of the present invention. FIG. 2A illustrates structures of a light-emitting device 20R, a light-emitting device 20G, a light-emitting device 20B, and a light-receiving device 30PS that can be used in the display apparatus.

The light-emitting device 20R, the light-emitting device 20G, and the light-emitting device 20B each have a function of emitting light (hereinafter, also referred to as a light-emitting function). As the light-emitting device 20R, the light-emitting device 20G, and the light-emitting device 20B, EL elements such as OLEDs (Organic Light Emitting Diodes) or QLEDs (Quantum-dot Light Emitting Diodes) are preferably used. Examples of a light-emitting substance contained in the EL element include a substance exhibiting fluorescence (a fluorescent material), a substance exhibiting phosphorescence (a phosphorescent material), an inorganic compound (such as a quantum dot material), and a substance exhibiting thermally activated delayed fluorescence (TADF (Thermally Activated Delayed Fluorescence) material). Note that as a TADF material, a material that is in a thermal equilibrium state between a singlet excited state and a triplet excited state may be used. Since such a TADF material enables a short emission lifetime (excitation lifetime), an efficiency decrease of a light-emitting device in a high-luminance region can be inhibited.

The light-emitting device 20R includes an electrode 21a, an EL layer 25R, and an electrode 23. The light-emitting device 20G includes an electrode 21b, an EL layer 25G, and the electrode 23. The light-emitting device 20B includes an electrode 21c, an EL layer 25B, and the electrode 23. In the light-emitting device 20R, the EL layer 25R sandwiched between the electrode 21a and the electrode 23 includes at least a light-emitting layer. The light-emitting layer includes a light-emitting substance emitting light, and a voltage is applied between the electrode 21b and the electrode 23, whereby the EL layer 25R emits light. Similarly, the EL layer 25G includes at least a light-emitting layer. The light-emitting layer includes a light-emitting substance emitting light, and a voltage is applied between the electrode 21a and the electrode 23, whereby the EL layer 25G emits light. The EL layer 25B includes at least a light-emitting layer. The light-emitting layer includes a light-emitting substance emitting light, and a voltage is applied between the electrode 21c and the electrode 23, whereby the EL layer 25B emits light.

Each of the EL layer 25R, the EL layer 25G, and the EL layer 25B may include one or more of a layer containing a substance having a high hole-injection property (hereinafter, referred to as a hole-injection layer), a layer containing a substance having a high hole-transport property (hereinafter, referred to as a hole-transport layer), a layer containing a substance having a high electron-transport property (hereinafter, referred to as an electron-transport layer), a layer containing a substance having a high electron-injection property (hereinafter, referred to as an electron-injection layer), a carrier-blocking layer, an exciton-blocking layer, and a charge-generation layer. The hole-injection layer, the hole-transport layer, the electron-transport layer, the electron-injection layer, the carrier-blocking layer, the exciton-blocking layer, and the charge-generation layer can also be referred to as functional layers.

Note that in this specification and the like, in the case where a matter common to the light-emitting device 20R, the light-emitting device 20G, and the light-emitting device 20B is described or the case where the light-emitting device 20R, the light-emitting device 20G, and the light-emitting device 20B need not be distinguished from one another, they are simply referred to as light-emitting devices 20 in some cases. In the same manner, in the description common to the components that are distinguished by alphabets, such as the EL layer 25R, the EL layer 25G, and the EL layer 25B, reference numerals without alphabets are sometimes used.

The light-receiving device 30PS has a function of detecting light (hereinafter, also referred to as a light-receiving function). The light-receiving device 30PS has a function of detecting visible light. The light-receiving device 30PS has sensitivity to visible light. The light-receiving device 30PS further preferably has a function of detecting visible light and infrared light. The light-receiving device 30PS preferably has sensitivity to visible light and infrared light. For example, a pn or pin photodiode can be used as the light-receiving device 30PS.

The light-receiving device 30PS includes an electrode 21d, a light-receiving layer 35PS, and the electrode 23. The light-receiving layer 35PS sandwiched between the electrode 21d and the electrode 23 includes at least an active layer. The light-receiving device 30PS functions as a photoelectric conversion device; charge can be generated by light incident on the light-receiving layer 35PS and extracted as a current. At this time, voltage may be applied between the electrode 21d and the electrode 23. The amount of generated charge is determined depending on the amount of light incident on the light-receiving layer 35PS.

The light-receiving layer 35PS may further include one or more of a hole-transport layer, an electron-transport layer, a layer containing a bipolar substance (a substance having a high electron-transport property and a high hole-transport property), and a carrier-blocking layer. The light-receiving layer 35PS may include a layer containing a substance that can be used for a hole-injection layer. The layer can function as a hole-transport layer in the light-receiving device 30PS. In addition, the light-receiving layer 35PS may include a layer containing a substance that can be used for an electron-injection layer. The layer can function as an electron-transport layer in the light-receiving device 30PS. Note that a substance having a hole-injection property can also be regarded as having a hole-transport property. The substance having an electron-injection property can also regarded as having an electron-transport property. Therefore, in this specification and the like, a substance having a hole-injection property is referred to as a substance having a hole-transport property in some cases. Similarly, a substance having an electron-injection property is referred to as a substance having an electron-transport property in some cases.

The active layer contains a semiconductor. Examples of the semiconductor include an inorganic semiconductor such as silicon, and an organic semiconductor including an organic compound. It is particularly preferable to use an organic photodiode including a layer containing an organic semiconductor, as the light-receiving device 30PS. An organic photodiode, which is easily made thin, lightweight, and large in area and has a high degree of freedom for shape and design, can be used in a variety of display apparatuses. It is preferable to use an organic semiconductor, in which case the EL layer included in the light-emitting device 20 and the light-receiving layer included in the light-receiving device 30PS can be formed by the same method (e.g., a vacuum evaporation method) with the same manufacturing apparatus.

In the display apparatus of one embodiment of the present invention, organic EL devices can be used as the light-emitting device 20R, the light-emitting device 20G, and the light-emitting device 20B, and an organic photodiode can be suitably used as the light-receiving device 30PS. The organic EL devices and the organic photodiode can be formed over the same substrate. Thus, the organic photodiode can be incorporated in the display apparatus including the organic EL devices. The display apparatus of one embodiment of the present invention has one or both of an image capturing function and a sensing function in addition to an image displaying function.

The electrode 21a, the electrode 21b, the electrode 21c, and the electrode 21d are provided on the same plane. In the structure illustrated in FIG. 2A, the electrode 21a, the electrode 21b, the electrode 21c, and the electrode 21d are provided over the substrate 50. The same material can be used for the electrode 21a, the electrode 21b, the electrode 21c, and the electrode 21d. Furthermore, the electrode 21a, the electrode 21b, the electrode 21c, and the electrode 21d can be formed through the same processes. For example, the electrode 21a, the electrode 21b, the electrode 21c, and the electrode 21d can be formed through processing a conductive film formed over the substrate 50 into island-like shapes. When the electrode 21a, the electrode 21b, the electrode 21c, and the electrode 21d are formed through the same processes, the productivity of the display apparatus can be increased.

Note that the electrode 21a, the electrode 21b, the electrode 21c, and the electrode 21d may be formed in different steps. The thicknesses of the electrode 21a, the electrode 21b, the electrode 21c, and the electrode 21d may differ from one another. Having different thicknesses, the electrode 21a, the electrode 21b, the electrode 21c, and the electrode 21d can be used as optical adjustment layers.

Each of the electrode 21a, the electrode 21b, the electrode 21c, and the electrode 21d can be referred to as a pixel electrode. The electrode 23 is a layer shared by the light-emitting device 20R, the light-emitting device 20G, the light-emitting device 20B, and the light-receiving device 30PS and can be referred to as a common electrode. A conductive film transmitting visible light and infrared light is used as the pixel electrode or the common electrode through which light exits or enters. A conductive film reflecting visible light and infrared light is preferably used as the electrode through which light neither exits nor enters.

FIG. 2A schematically shows that the electrode 21a, the electrode 21b, the electrode 21c, and the electrode 21d function as anodes and the electrode 23 functions as a cathode in the light-emitting device 20R, the light-emitting device 20G, the light-emitting device 20B, and the light-receiving device 30PS. For easy understanding of the direction of the anode and the cathode, a circuit symbol of a light-emitting diode is shown on the left of the light-emitting device 20R and a circuit symbol of a photodiode is shown on the right of the light-receiving device 30PS in FIG. 2A. In addition, an electron is indicated by a circle with a sign of −(minus), a hole is indicated by a circle with a sign of +(plus), and flow directions of electrons and holes are schematically indicated by arrows.

The electrode 21a, the electrode 21b, and the electrode 21c, which function as anodes in the light-emitting device 20R, the light-emitting device 20G, and the light-emitting device 20B, are electrically connected to a first wiring that supplies a first potential. The electrode 23, which functions as a cathode in the light-emitting device 20R, the light-emitting device 20G, the light-emitting device 20B, and the light-receiving device 30PS, is electrically connected to a second wiring that supplies a second potential. The second potential is a potential lower than the first potential. The electrode 21d, which functions as an anode in the light-receiving device 30PS, is electrically connected to a third wiring that supplies a third potential. Here, a reverse bias voltage is applied to the light-receiving device 30PS. That is, the third potential is a potential lower than the second potential.

FIG. 2B illustrates a specific example of the structure illustrated in FIG. 2A. In the light-emitting device 20R, the EL layer 25R includes a first functional layer 27a, a light-emitting layer 41R, and a second functional layer 29a that are stacked in this order. In the light-emitting device 20G, the EL layer 25G includes a first functional layer 27b, a light-emitting layer 41G, and a second functional layer 29b that are stacked in this order. In the light-emitting device 20B, the EL layer 25B includes a first functional layer 27c, a light-emitting layer 41B, and a second functional layer 29c that are stacked in this order.

Note that in the light-emitting device 20R, a structure including the first functional layer 27a, the light-emitting layer 41R, and the second functional layer 29a provided between the pair of electrodes (the electrode 21a and the electrode 23) can function as a single light-emitting unit; the structure of the light-emitting device 20R is referred to as a single structure in some cases in this specification and the like. The same applies to the light-emitting device 20G and the light-emitting device 20B.

The first functional layer 27a, the first functional layer 27b, and the first functional layer 27c are positioned on the side of the electrode 21a, the electrode 21b, and the electrode 21c functioning as anodes in the light-emitting device 20R, the light-emitting device 20G, and the light-emitting device 20B. The first functional layer 27a, the first functional layer 27b, and the first functional layer 27c can each be a hole-transport layer or a hole-injection layer. Alternatively, the first functional layer 27a, the first functional layer 27b, and the first functional layer 27c may each have a stacked-layer structure of a hole-injection layer and a hole-transport layer over the hole-injection layer. Furthermore, the hole-injection layer may have a stacked-layer structure, and the hole-transport layer may have a stacked-layer structure. Alternatively, the first functional layer 27a, the first functional layer 27b, and the first functional layer 27c may each contain a substance having a hole-transport property and a substance having a hole-injection property.

The same material can be used for the first functional layer 27a, the first functional layer 27b, and the first functional layer 27c. Furthermore, the first functional layer 27a, the first functional layer 27b, and the first functional layer 27c can be formed through the same processes. For example, the first functional layer 27a, the first functional layer 27b, and the first functional layer 27c can be formed through processing a film that is to be the first functional layer 27a, the first functional layer 27b, and the first functional layer 27c. When the first functional layer 27a, the first functional layer 27b, and the first functional layer 27c are formed through the same processes, the productivity of the display apparatus can be increased.

The second functional layer 29a, the second functional layer 29b, and the second functional layer 29c are positioned on the side of the electrode 23 functioning as a cathode in the light-emitting device 20R, the light-emitting device 20G, and the light-emitting device 20B. The second functional layer 29a, the second functional layer 29b, and the second functional layer 29c can each be an electron-transport layer or an electron-injection layer. Alternatively, the second functional layer 29a, the second functional layer 29b, and the second functional layer 29c may each have a stacked-layer structure of an electron-transport layer and an electron-injection layer over the electron-transport layer. Furthermore, the electron-injection layer may have a stacked-layer structure, and the electron-transport layer may have a stacked-layer structure. Alternatively, the second functional layer 29a, the second functional layer 29b, and the second functional layer 29c may each contain a substance having an electron-transport property and a substance having an electron-injection property.

The same material can be used for the second functional layer 29a, the second functional layer 29b, and the second functional layer 29c. Furthermore, the second functional layer 29a, the second functional layer 29b, and the second functional layer 29c can be formed through the same processes. For example, the second functional layer 29a, the second functional layer 29b, and the second functional layer 29c can be formed through processing a film that is to be the second functional layer 29a, the second functional layer 29b, and the second functional layer 29c. When the second functional layer 29a, the second functional layer 29b, and the second functional layer 29c are formed through the same processes, the productivity of the display apparatus can be increased.

As illustrated in FIG. 2B, the light-receiving layer 35PS in the light-receiving device 30PS includes a third functional layer 37PS, an active layer 43PS, and a fourth functional layer 39PS that are stacked in this order.

The third functional layer 37PS that is positioned on the side of the electrode 21d side functioning as the anode of the light-receiving device 30PS can be a hole-transport layer. The substance having a hole-transport property contained in the third functional layer 37PS may differ from the substance having a hole-transport property contained in the first functional layer 27a, the first functional layer 27b, and the first functional layer 27c. The third functional layer 37PS included in the light-receiving device 30PS is preferably formed through a process different from processes for layers constituting the light-emitting devices 20 (e.g., the first functional layer 27a, the first functional layer 27b, and the first functional layer 27c). When the third functional layer 37PS is formed through a different process, a material more suitable for the light-receiving device 30PS can be used for the third functional layer 37PS. Similarly, a material more suitable for the light-emitting device 20 can be used for the first functional layer 27.

A material usable for the first functional layer 27a, the first functional layer 27b, and the first functional layer 27c can be used for the third functional layer 37PS. The substance having a hole-transport property contained in the third functional layer 37PS may be either different from or the same as the substance having a hole-transport property contained in the first functional layer 27a, the first functional layer 27b, and the first functional layer 27c. The third functional layer 37PS may have a stacked-layer structure.

The substance having a hole-transport property contained in the third functional layer 37PS is different from the substance having a hole-transport property contained in the first functional layer 27a, the first functional layer 27b, and the first functional layer 27c, which is preferable in terms of being able to select substances having a hole-transport property optimal for the respective devices. Meanwhile, the substance having a hole-transport property contained in the third functional layer 37PS is the same as the substance having a hole-transport property contained in the first functional layer 27a, the first functional layer 27b, and the first functional layer 27c, which is preferable in terms of being able to form these functional layers using the same apparatus (e.g., one evaporation apparatus is shared by the functional layers), resulting in a low manufacturing cost.

The fourth functional layer 39PS that is positioned on the side of the electrode 23 functioning as the cathode of the light-receiving device 30PS can be an electron-transport layer. The substance having an electron-transport property contained in the fourth functional layer 39PS may differ from the substance having an electron-transport property contained in the second functional layer 29a, the second functional layer 29b, and the second functional layer 29c. The fourth functional layer 39PS included in the light-receiving device 30PS is preferably formed through a process different from processes for layers constituting the light-emitting device 20 (e.g., the second functional layer 29a, the second functional layer 29b, and the second functional layer 29c). When the fourth functional layer 39PS is formed through a different process, a material more suitable for the light-receiving device 30PS can be used for the fourth functional layer 39PS. Similarly, a material more suitable for the light-emitting device 20 can be used for the second functional layer 29a, the second functional layer 29b, and the second functional layer 29c.

A material usable for the second functional layer 29a, the second functional layer 29b, and the second functional layer 29c can be used for the fourth functional layer 39PS. The substance having an electron-transport property contained in the fourth functional layer 39PS may be either different from or the same as the substance having an electron-transport property contained in the second functional layer 29a, the second functional layer 29b, and the second functional layer 29c. The fourth functional layer 39PS may have a stacked-layer structure.

The substance having an electron-transport property contained in the fourth functional layer 39PS is different from the substance having an electron-transport property contained in the second functional layer 29a, the second functional layer 29b, and the second functional layer 29c, which is preferable in terms of the fact that substances having an electron-transport property optimal for the respective devices can be selected. Meanwhile, the substance having an electron-transport property contained in the fourth functional layer 39PS is the same as the substance having an electron-transport property contained in the second functional layer 29a, the second functional layer 29b, and the second functional layer 29c, which is preferable in terms of the fact that these functional layers can be formed using the same apparatus (e.g., one evaporation apparatus is shared by the functional layers), resulting in a low manufacturing cost.

Note that the third functional layer 37PS may include a layer that functions as a hole-injection layer in a light-emitting device, i.e., a layer that contains a substance having a high hole-injection property. A hole-injection layer can function as a hole-transport layer in a light-receiving device. The fourth functional layer 39PS may include a layer that functions as an electron-injection layer in a light-emitting device, i.e., a layer that contains a substance having a high electron-injection property. An electron-injection layer can function as an electron-transport layer in a light-receiving device.

As illustrated in FIG. 2B and the like, it is preferable that the EL layer 25R, the EL layer 25G, the EL layer 25B, and the light-receiving layer 35PS not include a layer shared by them. In addition, it is preferable that the EL layer 25R, the EL layer 25G, the EL layer 25B, and the light-receiving layer 35PS not include regions in contact with one another. That is, it is preferable that the EL layer 25R, the EL layer 25G, the EL layer 25B, and the light-receiving layer 35PS be separated from one another.

Separation of the EL layers 25 of two adjacent light-emitting devices 20 can inhibit generation of a leakage current between the light-emitting devices 20. That is, a phenomenon in which a light-emitting device other than a desired light-emitting device emits light (also referred to as crosstalk) can be inhibited; thus, a display apparatus with high display quality can be achieved.

Separation of the light-receiving layer 35PS of the light-receiving device 30PS from the EL layer 25 of the adjacent light-emitting device 20 can inhibit a leakage current from flowing from the light-emitting device 20 to the light-receiving device 30PS (also referred to as a side leakage). Thus, the light-receiving device 30PS can have a high SN ratio (Signal to Noise Ratio) and high accuracy.

In the display apparatus of one embodiment of the present invention, the side leakage between the light-emitting device 20 and the light-receiving device 30PS can be inhibited, which allows a short distance between the light-emitting device 20 and the light-receiving device 30PS. That is, the proportions of the light-emitting devices 20 and the light-receiving device 30PS in a pixel (hereinafter, also referred to as an aperture ratio) can be each increased. In addition, the size of a pixel can be reduced, so that the resolution of the display apparatus can be increased. Thus, a display apparatus having a light detection function and a high aperture ratio can be achieved. In addition, a display apparatus having a light detection function and a high resolution can be achieved.

Note that the light-receiving devices 30PS can be arranged at a resolution higher than or equal to 100 ppi, preferably higher than or equal to 200 ppi, further preferably higher than or equal to 300 ppi, further preferably higher than or equal to 400 ppi, still further preferably higher than or equal to 500 ppi and lower than or equal to 2000 ppi, lower than or equal to 1000 ppi, or lower than or equal to 600 ppi, for example. In particular, when the light-receiving devices 30PS are arranged at a resolution higher than or equal to 200 ppi and lower than or equal to 600 ppi, preferably higher than or equal to 300 ppi and lower than or equal to 600 ppi, the light-receiving devices 30PS can be suitably used for capturing a fingerprint image.

In the case where fingerprint authentication is performed with the display apparatus of one embodiment of the present invention, the increased resolution of the light-receiving devices 30PS enables, for example, highly accurate extraction of the minutiae of fingerprints; thus, the accuracy of the fingerprint authentication can be increased. The resolution is preferably higher than or equal to 500 ppi, in which case the authentication conforms to the standard by the National Institute of Standards and Technology (NIST) or the like. On the assumption that the resolution at which the light-receiving devices are arranged is 500 ppi, the size of each pixel is 50.8 μm, which indicates that the resolution is adequate for image capturing of a fingerprint ridge distance (typically, greater than or equal to 300 μm and less than or equal to 500 μm).

### Structure Example 2-2

FIG. 2C illustrates a structure different from the structures illustrated in FIG. 2A and FIG. 2B. The display apparatus illustrated in FIG. 2C schematically shows that the electrode 21a, the electrode 21b, and the electrode 21c function as anodes and the electrode 23 function as a cathode in the light-emitting device 20R, the light-emitting device 20G, and the light-emitting device 20B; the electrode 21d functions as a cathode and the electrode 23 functions as an anode in the light-receiving device 30PS.

The electrode 21a, the electrode 21b, and the electrode 21c, which function as anodes in the light-emitting device 20R, the light-emitting device 20G, and the light-emitting device 20B, are electrically connected to a first wiring that supplies a first potential. The electrode 23, which functions as a cathode in the light-emitting device 20R, the light-emitting device 20G, and the light-emitting device 20B and functions as an anode in the light-receiving device 30PS, is electrically connected to a second wiring that supplies a second potential. The second potential is a potential lower than the first potential. The electrode 21d, which functions as a cathode in the light-receiving device 30PS, is electrically connected to a third wiring that supplies a third potential. The third potential is a potential higher than the second potential.

As illustrated in FIG. 2C, the electrode 23 functioning as a common electrode can function as one of the anode and the cathode in the light-emitting device 20R, the light-emitting device 20G, and the light-emitting device 20B and functions as the other of the anode and the cathode in the light-receiving device 30PS. Such a structure can reduce a potential difference between the pixel electrodes (the electrode 21a, the electrode 21b, and the electrode 21c) of the light-emitting devices 20 and the pixel electrode (the electrode 21d) of the light-receiving device 30PS, thereby inhibiting a leakage between the pixel electrodes (hereinafter, referred to as a side leakage). Therefore, the light-receiving device 30PS can have a high SN ratio and high accuracy.

For example, the first potential (a potential supplied to the electrode 21a, the electrode 21b, and the electrode 21c) can be 12 V, the second potential (a potential supplied to the electrode 23) can be 0 V, and the third potential (a potential supplied to the electrode 21d) can be 4 V. Such a structure can reduce a potential difference between the pixel electrodes (the electrode 21a, the electrode 21b, and the electrode 21c) of the light-emitting devices 20 and the pixel electrode (the electrode 21d) of the light-receiving device 30PS, thereby inhibiting a side leakage between the light-emitting devices 20 and the light-receiving device 30PS.

Furthermore, the difference between the highest one and the lowest one of the first potential, the second potential, and the third potential can be small, whereby a display apparatus with low power consumption can be achieved.

FIG. 2D illustrates a specific example of the structure illustrated in FIG. 2C. For the light-emitting device 20R, the light-emitting device 20G, and the light-emitting device 20B, the above description can be referred to and detailed description is omitted.

The third functional layer 37PS positioned on the side of the electrode 21d functioning as the cathode of the light-receiving device 30PS can be an electron-transport layer. The substance having an electron-transport property contained in the third functional layer 37PS may differ from the substance having an electron-transport property contained in the second functional layer 29a, the second functional layer 29b, and the second functional layer 29c. A material usable for the second functional layer 29a, the second functional layer 29b, and the second functional layer 29c can be used for the third functional layer 37PS. The substance having an electron-transport property contained in the third functional layer 37PS may be the same as the substance having an electron-transport property contained in the second functional layer 29a, the second functional layer 29b, and the second functional layer 29c.

The fourth functional layer 39PS positioned on the side of the electrode 23 functioning as the anode of the light-receiving device 30PS can be a hole-transport layer. The substance having a hole-transport property contained in the fourth functional layer 39PS may differ from the substance having a hole-transport property contained in the first functional layer 27a, the first functional layer 27b, and the first functional layer 27c. A materials usable for the first functional layer 27a, the first functional layer 27b, and the first functional layer 27c can be used for the fourth functional layer 39PS. The substance having a hole-transport property contained in the fourth functional layer 39PS may be the same as the substance having a hole-transport property contained in the first functional layer 27a, the first functional layer 27b, and the first functional layer 27c.

Note that the third functional layer 37PS may include a layer that functions as an electron-injection layer in a light-emitting device, i.e., a layer containing a substance having a high electron-injection property. The fourth functional layer 39PS may include a layer that functions as a hole-injection layer in a light-emitting device, i.e., a layer containing a substance having a hole-injection property.

Although the electrode 21a, the electrode 21b, and the electrode 21c function as anodes and the electrode 23 functions as a cathode in the light-emitting devices 20 in the structure described in this embodiment, one embodiment of the present invention is not limited thereto. A structure in which the electrode 21a, the electrode 21b, and the electrode 21c function as cathodes and the electrode 23 functions as an anode in the light-emitting devices 20 may be employed. In this case, the first functional layer 27a, the first functional layer 27b, and the first functional layer 27c can be one or both of an electron-transport layer and an electron-injection layer. In this case, the second functional layer 29a, the second functional layer 29b, and the second functional layer 29c can be one or both of a hole-transport layer and a hole-injection layer.

### Structure Example 2-3

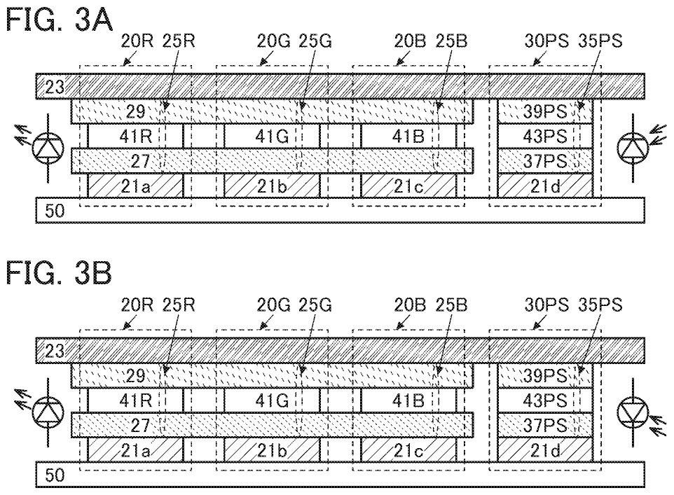

FIG. 3A illustrates a structure different from the structures illustrated in FIG. 2B. The light-emitting device 20R, the light-emitting device 20G, and the light-emitting device 20B illustrated in FIG. 3A include a first functional layer 27 instead of the first functional layer 27a, the first functional layer 27b, and the first functional layer 27c and include a second functional layer 29 instead of the second functional layer 29a, the second functional layer 29b, and the second functional layer 29c. The first functional layer 27 is a layer shared by the light-emitting device 20R, the light-emitting device 20G, and the light-emitting device 20B and can be referred to as a first common layer. Similarly, the second functional layer 29 is a layer shared by the light-emitting device 20R, the light-emitting device 20G, and the light-emitting device 20B and can be referred to as a second common layer.

As illustrated in FIG. 3A, the first functional layer 27 positioned on the side of the electrode 21a, the electrode 21b, and the electrode 21c functioning as the anodes of the light-emitting device 20R, the light-emitting device 20G, and the light-emitting device 20B can be a hole-transport layer or a hole-injection layer. Alternatively, the first functional layer 27 may have a stacked-layer structure of a hole-injection layer and a hole-transport layer over the hole-injection layer. For the first functional layer 27, the description of the first functional layer 27a, the first functional layer 27b, and the first functional layer 27c can be referred to, and thus detailed description is omitted.

The second functional layer 29 positioned on the side of the electrode 23 functioning as the cathode of the light-emitting device 20R, the light-emitting device 20G, and the light-emitting device 20B can be an electron-transport layer or an electron-injection layer. Alternatively, the second functional layer 29 may have a stacked-layer structure of an electron-transport layer and an electron-injection layer over the electron-transport layer. For the second functional layer 29, the description of the second functional layer 29a, the second functional layer 29b, and the second functional layer 29c can be referred to, and detailed description is omitted.

Note that a third common layer may be provided between the electrode 23 and the second functional layer 29 and between the electrode 23 and the fourth functional layer 39PS. The third common layer includes an electron-injection layer, for example. Alternatively, the third common layer may have a stacked-layer structure of an electron-transport layer and an electron-injection layer over the electron-transport layer. The third common layer is a layer shared by the light-emitting device 20R, the light-emitting device 20G, the light-emitting device 20B, and the light-receiving device 30PS. Note that in the case where an electron-injection layer is used as the third common layer, the electron-injection layer functions as an electron-transport layer in the light-receiving device 30PS.

Note that as illustrated in FIG. 3B, the electrode 21d may function as a cathode and the electrode 23 may function as an anode in the light-receiving device 30PS.

Note that a third common layer may be provided between the electrode 23 and the second functional layer 29 and between the electrode 23 and the fourth functional layer 39PS. For the third common layer, the above description can be referred to, and thus detailed description is omitted. Note that in the case where an electron-injection layer is used as the third common layer, the electron-injection layer does not necessarily have a specific function in the light-receiving device 30PS.

The hole-injection layer is a layer injecting holes from an anode to a hole-transport layer, and a layer containing a material with a high hole-injection property. Examples of the material having a high hole-injection property include an aromatic amine compound and a composite material containing a hole-transport material and an acceptor material (electron-accepting material).

In the light-emitting device, the hole-transport layer transports holes injected from the anode by the hole-injection layer, to the light-emitting layer. In the light-receiving device, the hole-transport layer is a layer that transports holes generated in the active layer on the basis of incident light, to the anode. The hole-transport layer is a layer containing a hole-transport material. As the hole-transport material, a substance having a hole mobility greater than or equal to 10⁻⁶ cm²/Vs is preferable. Note that other substances can also be used as long as the substances have a hole-transport property higher than an electron-transport property. As the hole-transport material, materials with a high hole-transport property, such as a T-electron rich heteroaromatic compound (e.g., a carbazole derivative, a thiophene derivative, and a furan derivative) and an aromatic amine (a compound having an aromatic amine skeleton), are preferred.

In the light-emitting device, the electron-transport layer transports electrons injected from the cathode by the electron-injection layer, to the light-emitting layer. In the light-receiving device, the electron-transport layer is a layer that transports electrons generated in the active layer on the basis of incident light, to the cathode. The electron-transport layer is a layer containing an electron-transport material. As the electron-transport material, a substance having an electron mobility greater than or equal to 10⁻⁶ cm²/Vs is preferable. Note that other substances can also be used as long as the substances have an electron-transport property higher than a hole-transport property. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a T-electron deficient heteroaromatic compound such as a nitrogen-containing heteroaromatic compound.

The electron-injection layer is a layer that injects electrons from the cathode to the electron-transport layer and contains a material with a high electron-injection property. As the material having a high electron-injection property, an alkali metal, an alkaline earth metal, or a compound thereof can be used. As the material having a high electron-injection property, a composite material containing an electron-transport material and a donor material (electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. The electron-injection layer may have a stacked-layer structure of two or more layers. The stacked-layer structure can be, for example, a structure where lithium fluoride is used for the first layer and ytterbium is provided for the second layer.

Alternatively, an electron-transport material may be used for the electron-injection layer. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

For the charge-generation layer, for example, a material that can be used for an electron-injection layer, such as lithium, can be suitably used. For the charge-generation layer, for example, a material that can be used for a hole-injection layer can be suitably used. For the charge-generation layer, a layer containing a hole-transport material and an acceptor material (electron-accepting material) can be used. For the charge-generation layer, a layer containing an electron-transport material and a donor material can be used. Forming the charge-generation layer including such a layer can inhibit an increase in the driving voltage that would be caused by stacking light-emitting units.

The active layer contains a semiconductor. Examples of the semiconductor include an inorganic semiconductor such as silicon, and an organic semiconductor including an organic compound. This embodiment shows an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material contained in the active layer include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When I-electron conjugation (resonance) spreads in a plane as in benzene, an electron-donating property (donor property) usually increases; however, having a spherical shape, fullerene has a high electron-accepting property even when π-electron conjugation widely spreads therein. The high electron-accepting property efficiently causes rapid charge separation and is useful for the light-receiving device. Both C₆₀ and C₇₀ have a wide absorption band in the visible light region, and C₇₀ is especially preferable because of having a larger π-electron conjugation system and a wider absorption band in the long wavelength region than C₆₀. Other examples of the fullerene derivative include [6,6]-phenyl-C71-butyric acid methyl ester (abbreviation: PC70BM), [6,6]-phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C60 (abbreviation: ICBA).

Another example of an n-type semiconductor material is a perylenetetracarboxylic derivative such as N,N-dimethyl-3,4,9,10-perylenetetracarboxylic diimide (abbreviation: Me-PTCDI).

Another example of an n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Examples of a p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer is preferably formed by co-evaporation of an n-type semiconductor and a p-type semiconductor. Alternatively, the active layer may be formed by stacking an n-type semiconductor and a p-type semiconductor.

Either a low molecular compound or a high molecular compound can be used for the light-emitting devices and the light-receiving device, and an inorganic compound may also be included. Each of the layers included in the light-emitting devices and the light-receiving device can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/poly(styrenesulfonic acid) (PEDOT/PSS), or an inorganic compound such as a molybdenum oxide or copper iodide (CuI) can be used, for example. As the electron-transport material or the hole-blocking material, an inorganic compound such as zinc oxide (ZnO) or an organic compound such as polyethylenimine ethoxylated (PEIE) can be used. The light-receiving device may include a mixed film of PEIE and ZnO, for example.

For the active layer, a high molecular compound such as poly[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]]polymer (abbreviation: PBDB-T) or a PBDB-T derivative, which functions as a donor, can be used. For example, a method in which an acceptor material is dispersed to PBDB-T or a PBDB-T derivative can be used.

A more specific structure example of the display apparatus of one embodiment of the present invention will be described below.

### Structure Example 3

### Structure Example 3-1

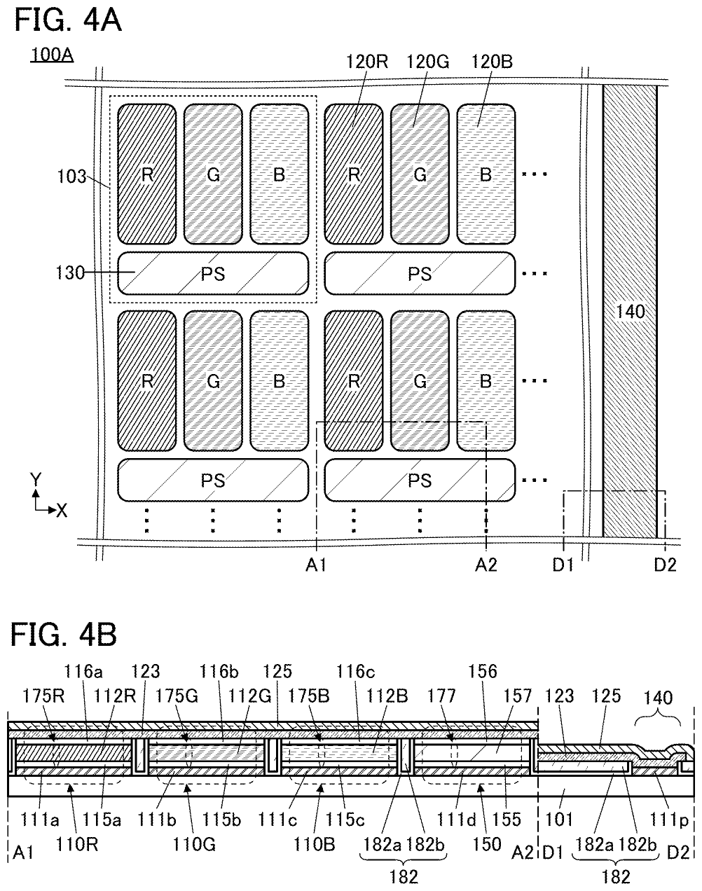

FIG. 4A is a schematic top view illustrating a structure example of a display apparatus 100A of one embodiment of the present invention. The display apparatus 100A includes a display portion where a plurality of pixels 103 are arranged in a matrix, and a connection portion 140 outside the display portion.

Each of the pixels 103 includes a plurality of subpixels. In the example illustrated FIG. 4A, the pixel 103 includes a subpixel 120R, a subpixel 120G, a subpixel 120B, and a subpixel 130. The subpixel 120R includes a light-emitting device 110R that emits red light. The subpixel 120G includes a light-emitting device 110G that emits green light. The subpixel 120B includes a light-emitting device 110B that emits blue light. The subpixel 130 includes a light-receiving device 150. In FIG. 4A, light-emitting regions of the light-emitting devices 110 are denoted by R, G, and B to easily differentiate the devices. In addition, light-receiving regions of the light-receiving devices 150 are denoted by PS.

FIG. 4B is a cross-sectional view taken along a dashed-dotted line A1-A2 and a dashed-dotted line D1-D2 in FIG. 4A. The light-emitting device 110R, the light-emitting device 110G, the light-emitting device 110B, and the light-receiving device 150 are provided over a substrate 101.

Note that in the case where the expression “B over A” or “B under A” is used in this specification and the like, for example, A and B do not always need to include a region where they are in contact with each other.

The light-emitting device 110R includes an electrode 111a, a common electrode 123, and an EL layer 175R sandwiched between the electrode 111a and the common electrode 123. The EL layer 175R includes a first functional layer 115a, a second functional layer 116a, and a light-emitting layer 112R sandwiched between the first functional layer 115a and the second functional layer 116a.

The light-emitting device 110G includes an electrode 111b, the common electrode 123, and an EL layer 175G sandwiched between the electrode 111b and the common electrode 123. The EL layer 175G includes a first functional layer 115b, a second functional layer 116b, and a light-emitting layer 112G sandwiched between the first functional layer 115b and the second functional layer 116b.

The light-emitting device 110B includes an electrode 111c, the common electrode 123, and an EL layer 175B sandwiched between the electrode 111c and the common electrode 123. The EL layer 175B includes a first functional layer 115c, a second functional layer 116c, and a light-emitting layer 112B sandwiched between the first functional layer 115c and the second functional layer 116c.

The light-receiving device 150 includes an electrode 111d, the common electrode 123, and a light-receiving layer 177 sandwiched between the electrode 111d and the common electrode 123. The light-receiving layer 177 includes a third functional layer 155, a fourth functional layer 156, and an active layer 157 sandwiched between the third functional layer 155 and the fourth functional layer 156.

The electrode 111a, the electrode 111b, the electrode 111c, and the electrode 111d each function as a pixel electrode of the light-emitting device 110 or the light-receiving device 150.

The above-described structures of the light-emitting device 20R, the light-emitting device 20G, and the light-emitting device 20B can be used for the light-emitting device 110R, the light-emitting device 110G, and the light-emitting device 110B. The above-described structure of the light-receiving device 30PS can be used for the light-receiving device 150.

The common electrode 123 is provided to be shared by the light-emitting devices 110 and the light-receiving device 150. Components other than the common electrode 123 included in the light-emitting devices 110 and the light-receiving device 150 are not shared by the light-emitting devices 110 and the light-receiving device 150 and are provided separately.

Specifically, the electrode 111a, the electrode 111b, the electrode 111c, and the electrode 111d are not shared by the light-emitting devices 110 and the light-receiving device 150 and are provided separately. The first functional layer 115a, the first functional layer 115b, and the first functional layer 115c are not shared by the light-emitting devices 110 and are provided separately. Similarly, the light-emitting layer 112R, the light-emitting layer 112G, and the light-emitting layer 112B are not shared by the light-emitting devices 110 and are provided separately. Similarly, the second functional layer 116a, the second functional layer 116b, and the second functional layer 116c are not shared by the light-emitting devices 110 and are provided separately.

The third functional layer 155, the active layer 157, and the fourth functional layer 156 of the light-receiving device 150 are not shared with the light-emitting devices 110 and are provided separately. Since the third functional layer 155, the active layer 157, and the fourth functional layer 156 of the light-receiving device 150 are provided separately from the light-emitting devices 110, a leakage current can be inhibited from flowing from the light-emitting devices 110 to the light-receiving device 150. Therefore, the light-receiving device 150 can have a high SN ratio and high accuracy.

The third functional layer 155 of the light-receiving device 150 is preferably formed through a process different from processes for the functional layers (e.g., the first functional layer 115a, the first functional layer 115b, and the first functional layer 115c) of the light-emitting devices 110. When the third functional layer 155 is formed through a different process, a material more suitable for the light-receiving device 150 can be used for the third functional layer 155. In other words, the third functional layer 155 can contain an organic compound different from the organic compound contained in the functional layers of the light-emitting devices 110.

Similarly, the fourth functional layer 156 of the light-receiving device 150 is preferably formed through a process different from processes for the functional layers (e.g., the second functional layer 116a, the second functional layer 116b, and the second functional layer 116c) of the light-emitting devices 110. When the fourth functional layer 156 is formed through a different process, a material more suitable for the light-receiving device 150 can be used for the fourth functional layer 156. In other words, the fourth functional layer 156 can contain an organic compound different from the organic compound contained in the functional layers of the light-emitting devices 110.

The first functional layer 115a, the first functional layer 115b, the first functional layer 115c, and the third functional layer 155 each include a region in contact with the top surface of the electrode 111.

A conductive film having a property of transmitting visible light is used for either one of the electrodes 111 or the common electrode 123, and a conductive film with a property of reflecting visible light is used for the other. When the electrode 111 has a light-transmitting property and the common electrode 123 has a light-reflecting property, the display apparatus 100A can have a bottom emission structure. The display apparatus 100A can have a top emission structure when the electrode 111 has a light-reflecting property and the common electrode 123 has a light-transmitting property. Note that when both the pixel electrode 111 and the common electrode 123 have a light-transmitting property, the display apparatus 100A can have a dual emission structure.

Having different thicknesses, the electrode 111a, the electrode 111b, the electrode 111c, and the electrode 111d may be used as optical adjustment layers. With the optical adjustment layer, the light-emitting devices 110 and the light-receiving device 150 can have a microcavity structure. When the microcavity structure is employed, for example, the electrode 111 can have a stacked-layer structure of a conductive layer reflecting visible light and a light-transmitting conductive layer (also referred to as an optical adjustment layer) over the conductive layer. Having different thicknesses of the optical adjustment layers, the electrode 111a, the electrode 111b, the electrode 111c, and the electrode 111d can have optical path lengths different from one another. A conductive film having properties of reflecting light and transmitting light can be used for the common electrode 123.

With the microcavity structure, light of specific wavelengths is intensified, in which case the light-emitting device 110R, the light-emitting device 110G, and the light-emitting device 110B can each be a light-emitting device with high color purity. The light-receiving device 150 can be a light-receiving device with high sensitivity, in which light of a specific wavelength to be detected is intensified.

As illustrated in FIG. 4B, an insulating layer 182 is provided to be embedded between two adjacent light-emitting devices 110 and between the light-receiving device 150 and the light-emitting device 110 adjacent thereto. The same applies to the case where two light-receiving devices 150 are adjacent to each other; the insulating layer 182 can also be provided between the light-receiving devices. The insulating layer 182 preferably includes regions in contact with the side surface of the EL layer 175R, the side surface of the EL layer 175G, the side surface of the EL layer 175B, the side surface of the light-receiving layer 177, the side surface of the electrode 111a, the side surface of the electrode 111b, the side surface of the electrode 111c, and the side surface of the electrode 111d. With the insulating layer 182, entry of impurities from the side surfaces of the EL layer 175 and the light-receiving layer 177 into their insides can be prevented, and thus a highly reliable display apparatus can be obtained. It is particularly preferable that the insulating layer 182 include regions in contact with the side surfaces of the light-emitting layer 112 and the active layer 157. Examples of the impurities include oxygen and water. The common electrode 123 is provided over the insulating layer 182.

When the insulating layer 182 is provided between the adjacent light-emitting devices 110, the EL layer 175R, the EL layer 175G, and the EL layer 175G can be prevented from being in contact with one another. Thus, current can be prevented from flowing through two adjacent EL layers 175, resulting in prevention of unintentional light emission. Hence, a display apparatus with a high contrast and high display quality can be provided.

Similarly, when the insulating layer 182 is provided between the light-receiving device 150 and the light-emitting device 110 adjacent thereto, the EL layer 175 and the light-receiving layer 177 can be prevented from being in contact with each other. Thus, leakage current from the light-emitting device 110 can be prevented from flowing into the adjacent light-receiving device 150; side leakage can be prevented. Hence, the light-receiving device 150 can have a high SN ratio and high accuracy.

In the vicinity of the end portion of the EL layer 175, a step caused by a level difference between a region provided with the EL layer 175 and a region without the EL layer 175 is generated between the adjacent light-emitting devices 110. In the display apparatus of one embodiment of the present invention, the step is reduced by providing the insulating layer 182, so that the step coverage with the common electrode 123 provided over the insulating layer 182 can be enhanced. Consequently, it is possible to inhibit a connection defect due to disconnection of the common electrode 123. Alternatively, an increase in electric resistance due to local thinning of the thickness of the common electrode 123 caused by the step can be inhibited.

In one embodiment of the present invention, providing the insulating layer 182 between the adjacently positioned EL layers 175 can make the unevenness on the formation surface of the common electrode 123 smaller, whereby the step coverage with the common electrode 123 in the vicinity of the end portion of the EL layer 175 can be increased and favorable conductivity of the common electrode 123 can be achieved.

Similarly, steps caused by level differences between a region provided with the light-receiving layer 177 and a region without the light-receiving layer 177 are generated between the light-receiving device 150 and the light-emitting device 110 adjacent thereto and between adjacent light-receiving devices 150. The steps are reduced by providing the insulating layer 182, so that the step coverage with the common electrode 123 provided over the insulating layer 182 can be enhanced.

At the end portion of the EL layer 175, the level difference between the top surface of the EL layer 175 and the top surface of the insulating layer 182 is reduced, that is, the level of the top surface of the EL layer 175 and the level of the top surface of the insulating layer 182 are aligned or substantially aligned with each other, so that the step coverage with the common electrode 123 can be enhanced. Similarly, at the end portion of the light-receiving layer 177, the level difference between the top surface of the light-receiving layer 177 and the top surface of the insulating layer 182 is reduced, that is, the level of the top surface of the light-receiving layer 177 and the level of the top surface of the insulating layer 182 are aligned or substantially aligned with each other, so that the step coverage with the common electrode 123 can be enhanced.

Although FIG. 4B illustrates a structure where the level of the top surface of the insulating layer 182 is aligned or substantially aligned with the level of the top surface of the EL layer 175 and the level of the top surface of the light-receiving layer 177, one embodiment of the present invention is not limited to this structure. The level of the top surface of the insulating layer 182 is not necessarily aligned with the level of the top surface of the EL layer 175 or the level of the top surface of the light-receiving layer 177. It is acceptable that the level of the top surface of the insulating layer 182 is higher than or lower than the level of the top surface of the EL layer 175. It is acceptable that the level of the top surface of the insulating layer 182 is higher than or lower than the level of the top surface of the light-receiving layer 177. It is acceptable that the insulating layer 182 includes a region in contact with the top surface of the EL layer 175 and a region in contact with the top surface of the light-receiving layer 177.

Note that the levels of the top surfaces of the EL layer 175R, the EL layer 175G, the EL layer 175B, and the light-receiving layer 177 may be different from one another. The insulating layer 182 may have different top-surface levels at the end portion of the EL layer 175R, the end portion of the EL layer 175G, the end portion of the EL layer 175B, and the end portion of the light-receiving layer 177. For example, at the end portion of the EL layer 175R, the level of the top surface of the EL layer 175R may be higher than that of the insulating layer 182; at the end portion of the EL layer 175G, the level of the top surface of the EL layer 175G may be higher than that of the insulating layer 182; at the end portion of the EL layer 175B, the level of the top surface of the EL layer 175B may be aligned or substantially aligned with that of the insulating layer 182; and at the end portion of the light-receiving layer 177, the level of the top surface of the light-receiving layer 177 may be lower than that of the insulating layer 182.

The insulating layer 182 can have a stacked-layer structure of an insulating layer 182a and an insulating layer 182b over the insulating layer 182a. The insulating layer 182a preferably includes regions in contact with the side surface of the EL layer 175 and the side surface of the light-receiving layer 177. The insulating layer 182a preferably includes a region in contact with the side surface of the electrode 111. The insulating layer 182b is provided over the insulating layer 182a. In a cross-sectional view, the insulating layer 182b is provided over and in contact with the insulating layer 182a so that a recessed portion formed along the insulating layer 182a is filled.

The insulating layer 182a functions as a protective insulating layer for the EL layer 175 and the light-receiving layer 177. It is preferable that the insulating layer 182a have a barrier property against at least one of oxygen and water. Provision of the insulating layer 182a can inhibit oxygen, water, or constituent elements thereof from entering the inside of the EL layer 175 and the light-receiving layer 177 through the side surface thereof, whereby a highly reliable display apparatus can be provided. It is particularly preferable that the insulating layer 182a cover the side surfaces of the light-emitting layer 112 and the active layer 157.

If the width (thickness) of the insulating layer 182a in the regions in contact with the side surfaces of the EL layer 175 and the light-receiving layer 177 is large in a cross-sectional view, the distance between the EL layer 175 and the light-receiving layer 177 is increased and the aperture ratio is lowered in some cases. If the width (thickness) of the insulating layer 182a is small, the effect of inhibiting the entry of oxygen, water, or constituent elements thereof from the side surfaces of the EL layer 175 and the light-receiving layer 177 into the insides thereof becomes small in some cases. The width (thickness) of the insulating layer 182a in the regions in contact with the side surfaces of the EL layer 175 and the light-receiving layer 177 is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, yet further preferably greater than or equal to 10 nm and less than or equal to 50 nm. When the width (thickness) of the insulating layer 182a is within the above range, the display apparatus can have both a high aperture ratio and high reliability.

The insulating layer 182a can be an insulating layer containing an inorganic material. As the insulating layer 182a, a single layer or stacked layers of aluminum oxide, magnesium oxide, hafnium oxide, gallium oxide, indium gallium zinc oxide, silicon oxide, silicon oxynitride, silicon nitride, silicon nitride oxide, or the like can be used, for example. In particular, aluminum oxide is preferable because it has high selectivity with respect to the EL layer 175 in etching and has a function of protecting the EL layer 175 in forming the insulating layer 182a described later. In particular, with use of an inorganic insulating material such as aluminum oxide, hafnium oxide, or silicon oxide formed by an ALD method for the insulating layer 182a, the insulating layer 182a can be a film with few pinholes and can have an excellent function of protecting the EL layer 175 and the light-receiving layer 177.

Note that in this specification, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 182a, a sputtering method, a chemical vapor deposition (CVD) method, a molecular beam epitaxy (MBE) method, a pulsed laser deposition (PLD) method, an atomic layer deposition (ALD) method, or the like can be used. An ALD method achieving favorable coverage can be suitably used for forming the insulating layer 182a.

The insulating layer 182b provided over the insulating layer 182a has a function of filling a recessed portion formed along the insulating layer 182a to improve the planarity of the insulating layer 182. An improvement in the planarity of the insulating layer 182 enables the step coverage with the common electrode 123 formed over the insulating layer 182 to be enhanced. An insulating layer containing an organic material can be suitably used as the insulating layer 182b. As the insulating layer 182b, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. Moreover, for the insulating layer 182b, a photosensitive resin can be used. As the photosensitive resin, a positive photosensitive material or a negative photosensitive material can be used. A photoresist may be used for the photosensitive resin.

A photosensitive resin is used for the insulating layer 182b, whereby the insulating layer 182b can be formed only by light exposure and development processes. The insulating layer 182b may be formed using a negative photosensitive resin (e.g., a resist material). In the case where an insulating layer containing an organic material is used as the insulating layer 182b, a material absorbing visible light is suitably used. When a material absorbing visible light is used for the insulating layer 182b, light emission from the EL layer 175 can be absorbed by the insulating layer 182b, whereby light that might leak to the adjacent EL layer 175 (stray light) can be inhibited. Thus, a display apparatus having high display quality can be provided. Similarly, light that might leak from the EL layer 175 to the adjacent light-receiving layer 177 (stray light) can be inhibited. Therefore, a display apparatus including the light-receiving device 150 with a high SN ratio and high accuracy can be provided.

A colored material (e.g., a material containing a black pigment) may be used for the insulating layer 182b so that the insulating layer 182b has a function of blocking stray light from an adjacent pixel and inhibiting color mixture. A reflective film (e.g., a metal film containing one or more selected from silver, palladium, copper, titanium, and aluminum) may be provided between the insulating layer 182a and the insulating layer 182b so that light emitted from the light-emitting layer is reflected by the reflective film; thus, the function of improving the light extraction efficiency may be added.

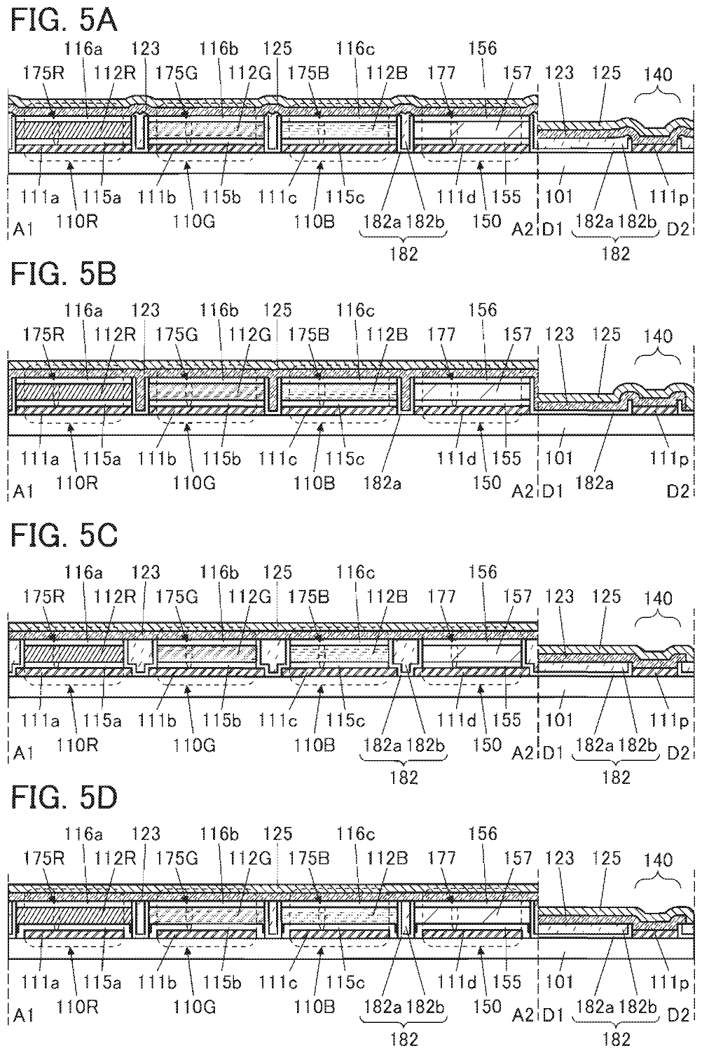

The top surface of the insulating layer 182b is preferably as flat as possible but is gently curved in some cases. The top surface of the insulating layer 182b may be, for example, convex, concave or flat. Alternatively, the top surface of the insulating layer 182b may have a wave shape having a convex portion and a concave portion, for example, as illustrated in FIG. 5A.

The insulating layer 182a is provided between the insulating layer 182b and each of the EL layer 175 and the light-receiving layer 177 so as to form a structure where the insulating layer 182b is not in contact with the EL layer 175 and the light-receiving layer 177. When the EL layer 175 and the light-receiving layer 177 are in contact with the insulating layer 182b, the EL layer 175 and the light-receiving layer 177 might be dissolved owing to a component (e.g., an organic solvent) contained in the insulating layer 182b. Providing the insulating layer 182a can protect the side surface of the EL layer 175 and the side surface of the light-receiving layer 177. Note that a structure where either the insulating layer 182a or the insulating layer 182b is not provided, i.e., a structure where only one of the insulating layer 182a and the insulating layer 182b is provided may be employed. For example, a structure in which the insulating layer 182b is not provided as illustrated in FIG. 5B may be employed.

A protective layer 125 is provided over the common electrode 123. The protective layer 125 has a function of preventing diffusion of impurities such as water into the light-emitting devices from above.

The protective layer 125 can have a single-layer structure or a stacked-layer structure including at least an inorganic insulating film. For the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 125.

As the protective layer 125, a stacked-layer film of an inorganic insulating film and an organic insulating film can be used. For example, a structure in which an organic insulating film is sandwiched between a pair of inorganic insulating films is preferable. Furthermore, it is preferable that the organic insulating film function as a planarization film. With this structure, a top surface of the organic insulating film can be flat, and accordingly, coverage with the inorganic insulating film over the organic insulating film is improved, leading to an improvement in barrier properties. Moreover, the top surface of the protective layer 125 is flat, which is preferable because the influence of an uneven shape due to a lower structure can be reduced in the case where a component (e.g., a color filter, an electrode of a touch sensor, a lens array, or the like) is provided above the protective layer 125.

The connection portion 140 includes the common electrode 123 and an electrode 111p electrically connected to the common electrode 123. The connection portion 140 can be referred to as a cathode contact portion. The same material as the electrode 111a, the electrode 111b, the electrode 111c, and the electrode 111d can be used for the electrode 111p. The electrode 111p can be formed through the same process as the electrode 111a, the electrode 111b, the electrode 111c, and the electrode 111d. The protective layer 125 is provided to cover the common electrode 123.

As illustrated in FIG. 4B, the insulating layer 182 may be provided so as to surround the connection portion 140. The insulating layer 182 preferably includes a region in contact with the side surface of the electrode 111p. The common electrode 123 is provided over the insulating layer 182.

Although the connection portion 140 is positioned on the right side of the display portion in the top view in the example illustrated in FIG. 4A, there is no particular limitation on the position of the connection portion 140. The connection portion 140 only needs to be provided on at least one of the top, right, left, and bottom sides of the display portion in the top view and may be provided to surround the four sides of the display portion. The number of connection portions 140 can be one or more.

The connection portion 140 can be provided along the outer periphery of the display portion. For example, the connection portion 140 may be provided along one side of the outer periphery of the display portion or two or more sides of the outer periphery of the display portion. Note that there is no particular limitation on the top surface shape of the connection portion 140. In the case where the top surface shape of the display portion is a rectangle, the top surface shape of the connection portion 140 can be a band shape, an L shape, a square bracket shape, or a quadrangle, for example.

FIG. 4B, FIG. 5A, and FIG. 5B each illustrate an example where the end portions of the EL layers 175 and the end portion of the light-receiving layer 177 are aligned or substantially aligned with the end portion of the electrodes 111; however, one embodiment of the present invention is not limited thereto. The end portions of the EL layers 175 and the end portion of the light-receiving layer 177 are not necessarily aligned with the end portions of the electrodes 111. As illustrated in FIG. 5C, the end portions of the EL layers 175 and the end portion of the light-receiving layer 177 may be positioned more inwardly than the end portions of the electrodes 111. As illustrated in FIG. 5D, the end portions of the EL layers 175 and the end portion of the light-receiving layer 177 may be positioned more outwardly than the end portions of the electrodes 111.

Note that in this specification and the like, the expression “end portions are aligned or substantially aligned” means that at least outlines of stacked layers partly overlap with each other. For example, the case of processing the upper layer and the lower layer with use of the same mask pattern or mask patterns that are partly the same is included. However, in some cases, the outlines do not exactly overlap with each other and the outline of the upper layer is located inward from the outline of the lower layer or the outline of the upper layer is located outward from the outline of the lower layer; such a case is also represented by the expression “end portions are aligned or substantially aligned”.

### Structure Example 3-2

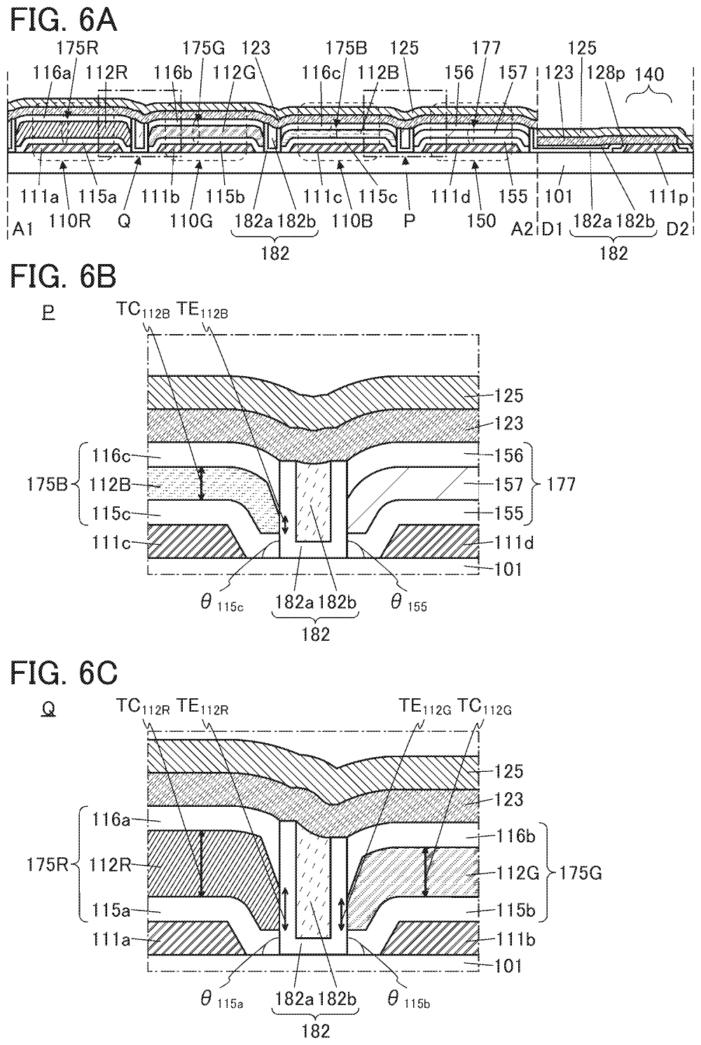

FIG. 6A illustrates a structure different from that in FIG. 5D. Structures of the light-emitting device 110R, the light-emitting device 110G, the light-emitting device 110B, and the light-receiving device 150 illustrated in FIG. 6A are different from those in FIG. 5D mainly in that the side surfaces of the electrode 111a, the electrode 111b, the electrode 111c, the electrode 111d, and the electrode 111p each have a tapered shape.

In this specification and the like, a tapered shape indicates a shape in which at least part of the side surface of a structure is inclined to a substrate surface. For example, a region where the angle between the inclined side surface and the substrate surface (also referred to as a taper angle) is less than 90° is preferably included.

FIG. 6B is an enlarged view of a region P indicated by a dashed-dotted line in FIG. 6A, and FIG. 6C is an enlarged view of a region Q. The light-emitting device 110B and the light-receiving device 150 are shown on the left side and the right side in FIG. 6B, respectively. The light-emitting device 110R and the light-emitting device 110G are shown on the left side and the right side in FIG. 6C, respectively.

Each of the side surfaces of the electrode 111a, the electrode 111b, the electrode 111c, the electrode 111d, and the electrode 111p preferably has a tapered shape. Each of the taper angles of the electrode 111a, the electrode 111b, the electrode 111c, the electrode 111d, and the electrode 111p is preferably less than 90°, further preferably less than or equal to 80°, still further preferably less than or equal to 70°, yet still further preferably 50°. When each of the side surfaces of the electrode 111a, the electrode 111b, the electrode 111c, the electrode 111d, and the electrode 111p has a tapered shape, the step coverage with the layers (for example, the first functional layer 115 and the third functional layer 155) formed over the electrodes is improved; as a result, the generation of defects such as disconnection or voids in the layers can be inhibited.

As illustrated in FIG. 6B, the end portion of the first functional layer 115c, the end portion of the light-emitting layer 112B, and the end portion of the second functional layer 116c are aligned or substantially aligned with one another in the light-emitting device 110B. In other words, the first functional layer 115c, the light-emitting layer 112B, and the second functional layer 116c have the same or substantially the same top surface shape. For example, a film to be the first functional layer 115c, a film to be the light-emitting layer 112B, and a film to be the second functional layer 116c are processed with the same mask, whereby the first functional layer 115c, the light-emitting layer 112B, and the second functional layer 116c can be formed. Such a structure can increase the area of the light-emitting layer 112B, thereby increasing the areas of the light-emitting regions of the light-emitting device 110B. That is, the display apparatus can have a high aperture ratio.

As illustrated in FIG. 6C, the end portion of the first functional layer 115a, the end portion of the light-emitting layer 112R, and the end portion of the second functional layer 116a are aligned or substantially aligned with one another in the light-emitting device 110R. In other words, the first functional layer 115a, the light-emitting layer 112R, and the second functional layer 116a have the same or substantially the same top surface shape. For example, a film to be the first functional layer 115, a film to be the light-emitting layer 112, and a film to be the second functional layer 116 are proceed with the same mask, whereby the first functional layer 115, the light-emitting layer 112, and the second functional layer 116 can be formed. The same applies to the light-emitting device 110G.

As illustrated in FIG. 6B, the end portion of the third functional layer 155, the end portion of the active layer 157, and the end portion of the fourth functional layer 156 are aligned or substantially aligned with one another in the light-receiving device 150. In other words, the third functional layer 155, the active layer 157, and the fourth functional layer 156 have the same or substantially the same top surface shape. For example, a film to be the third functional layer 155, a film to be the active layer 157, and a film to be the fourth functional layer 156 are processed with the same mask, whereby the third functional layer 155, the active layer 157, and the fourth functional layer 156 can be formed. Such a structure can increase the areas of the active layer 157, thereby increasing the areas of the light-receiving region of the light-receiving device 150. In other words, a display apparatus having a highly sensitive light-receiving function can be provided.

Note that in this specification and the like, the expression “having the same or substantially the same top surface shape” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “having the same or substantially the same top surface shape”.

It is preferable that the light-receiving layer 177 of the light-receiving device 150 not include a layer shared with the EL layer 175B of the light-emitting device 110B and not include a region in contact with the EL layer 175B as illustrated in FIG. 6B. That is, it is preferable that the light-receiving layer 177 be separated from the EL layer 175B. Note that the light-emitting device 110B is illustrated as the light-emitting device adjacent to the light-receiving device 150 in FIG. 6B; however, one embodiment of the present invention is not limited thereto. A light-receiving layer included in a light-receiving device is preferably separated from an EL layer included in a light-emitting device adjacent to the light-receiving device. Note that the same applies to the case where two light-receiving devices are adjacent to each other; a light-receiving layer included in one of the light-receiving devices is preferably separated from a light-receiving layer included in the other of the light-receiving devices.

It is preferable that an EL layer 175G of the light-emitting device 110G not include a layer shared with the EL layer 175R of the light-emitting device 110R and not include a region in contact with the EL layer 175R as illustrated in FIG. 6C. That is, it is preferable that the EL layer 175G be separated from the EL layer 175R. Note that the light-emitting device 110R is illustrated as the light-emitting device adjacent to the light-emitting device 110G in FIG. 6C; however, one embodiment of the present invention is not limited thereto. An EL layer included in a light-emitting device is preferably separated from an EL layer included in a light-emitting device adjacent to the light-emitting device.

As illustrated in FIG. 6B, the side surfaces of the third functional layer 155 is preferably perpendicular or substantially perpendicular to the formation surface in the light-receiving device 150. For example, an angle θ₁₅₅ formed by the side surface of the third functional layer 155 and the formation surface (here, the substrate 101) is preferably greater than or equal to 60° and less than or equal to 90°.

As illustrated in FIG. 6B, the side surface of the first functional layer 115c is preferably perpendicular or substantially perpendicular to the formation surfaces in the light-emitting device 110B. For example, the angle θ_{115c} formed by the side surface of the first functional layer 115c and the formation surface (here, the substrate 101) is preferably greater than or equal to 60° and less than or equal to 90°.

Similarly, as illustrated in FIG. 6C, the side surface of the first functional layer 115a is preferably perpendicular or substantially perpendicular to the formation surface in the light-emitting device 110R. For example, an angle θ₁₁₅ₐ formed by the side surface of the first functional layer 115a and the formation surface (here, the substrate 101) is preferably greater than or equal to 60° and less than or equal to 90°. The side surface of the first functional layer 115b is preferably perpendicular or substantially perpendicular to the formation surface in the light-emitting device 110G. For example, an angle θ_{115b} formed by the side surface of the first functional layer 115b and the formation surface (here, the substrate 101) is preferably greater than or equal to 60° and less than or equal to 90°.

Each of the light-emitting layer 112R, the light-emitting layer 112G, and the light-emitting layer 112B can be formed using an FMM. When the light-emitting layer 112 is formed using an FMM, its thickness becomes smaller as closer to its end portion in some cases. As illustrated in FIG. 6B, a thickness TE_{112B} of the light-emitting layer 112B at the end portion in the light-emitting device 110B is sometimes smaller than a thickness TC_{112B} in a region inward from the end portion. Similarly, as illustrated in FIG. 6C, a thickness TE_{112R} of the light-emitting layer 112R at the end portion in the light-emitting device 110R is sometimes smaller than a thickness TC_{112R} in a region inward from the end portion. A thickness TE_{112G} of the light-emitting layer 112G at the end portion in the light-emitting device 110G is sometimes smaller than a thickness TC_{112G} in a region inward from the end portion. Note that the thickness TE_{112R}, the thickness TE_{112G}, and the thickness TE_{112B} at the end portions of the light-emitting layers 112 can be each referred to as a thickness of the light-emitting layer 112 in a region where the light-emitting layer 112 and the insulating layer 182 are in contact with each other. Meanwhile, the thickness TC_{112R}, the thickness TC_{112G}, and the thickness TC_{112B} of the light-emitting layer 112 can be each referred to as a thickness of the light-emitting layer 112 in a region where the light-emitting layer 112 and the insulating layer 182 are not in contact with each other.

The thicknesses of the light-emitting layer 112R, the light-emitting layer 112G, and the light-emitting layer 112B may be different from one another. The example shown in FIG. 6A and the like is such that the light-emitting layer 112R has a large thickness and the light-emitting layer 112B has a small thickness; however, the relation of the thickness size between the light-emitting layer 112R, the light-emitting layer 112G, and the light-emitting layer 112B is not limited thereto. Similarly, the relation of the thickness size of the active layer 157 with the light-emitting layer 112R, the light-emitting layer 112G, and the light-emitting layer 112B has no particular limitation.

The insulating layer 182 preferably includes a region in contact with the side surface of the EL layer 175 and a region in contact with the side surface of the light-receiving layer 177. The insulating layer 182 provided to be in contact with the EL layer 175 and the light-receiving layer 177 brings an effect of fixing or bonding the island shaped EL layer 175 and the island-shaped light-receiving layer 177 with/to the insulating layer 182. Accordingly, peeling of the EL layer 175 and the light-transmitting layer 177 can be prevented. Thus, the reliability of the light-emitting device 110 and the light-receiving device 150 can be increased. In addition, the manufacturing yield of the light-emitting device 110 and the light-receiving device 150 can be increased.

It is preferable that the level of the top surface of the insulating layer 182 be aligned or substantially aligned with the level of the top surface at the end portion of the EL layer 175 and the level of the top surface of at the end portion the light-receiving layer 177. With such a structure, the formation surface of the common electrode 123 can be more planarized, and a connection defect caused by disconnection of the common electrode 123 can be inhibited. Alternatively, an increase in electric resistance due to local thinning of the common electrode 123 by the level difference can be inhibited. The top surface of the insulating layer 182 preferably has a flat shape and may have a protruding portion, a convex curved surface, a concave curved surface, or a depressed portion.

The level of the top surface of the insulating layer 182 may be higher or lower than the level of the top surface at the end portion of the EL layer 175 and the level of the top surface at the end portion of the light-receiving layer 177. The insulating layer 182 preferably covers at least the side surface of the light-emitting layer 112R and the side surface of the active layer 157. In other words, the level of the top surface of the insulating layer 182 is preferably higher than the level of the top surface at the end portion of the light-emitting layer 112 and the level of the top surface at the end portion of the active layer 157. The insulating layer 182 covers the side surface of the light-emitting layer 112R and the side surface of the active layer 157, whereby diffusion of impurities into the light-emitting layer 112R and the active layer 157 can be inhibited.

The structure of the light-emitting device 110 shown in FIG. 6A and the like is such that the end portion of the EL layer 175 is positioned more outwardly than the end portion of the electrode 111; however, one embodiment of the present invention is not limited thereto. The end portion of the EL layer 175 may be positioned more inwardly than the end portion of the electrode 111 and may be aligned or substantially aligned with the end portion of the electrode 111. In addition, the structure of the EL layer 175 where the end portion of the light-emitting layer 112 is aligned or substantially aligned with the end portion of the first functional layer 115 and the end portion of the second functional layer 116 is shown; however, one embodiment of the present invention is not limited thereto. The end portion of the light-emitting layer 112 may be positioned more inwardly than the end portion of the first functional layer 115 and the end portion of the second functional layer 116. When the end portion of the light-emitting layer 112 is positioned more inwardly than the end portion of the first functional layer 115 and the end portion of the second functional layer 116, the end portion of the light-emitting layer 112 may be positioned more inwardly than the end portion of the electrode 111, positioned more outwardly than the end portion of the electrode 111, or aligned or substantially aligned with the end portion of the electrode 111.

The structure of the light-receiving device 150 shown in FIG. 6A and the like is such that the end portion of the light-receiving layer 177 is positioned more outwardly than the end portion of the electrode 111; however, one embodiment of the present invention is not limited thereto. The end portion of the light-receiving layer 177 may be positioned more inwardly than the end portion of the electrode 111 or aligned or substantially aligned with the end portion of the electrode 111.

FIG. 6(A) illustrates a sacrificial layer 128p including a region in contact with the electrode 111p in the connection portion 140. The sacrificial layer 128p is a remaining part of the layer provided in manufacturing a display apparatus. Detailed description of the sacrificial layer 128p will be made later.

### Structure Example 3-3

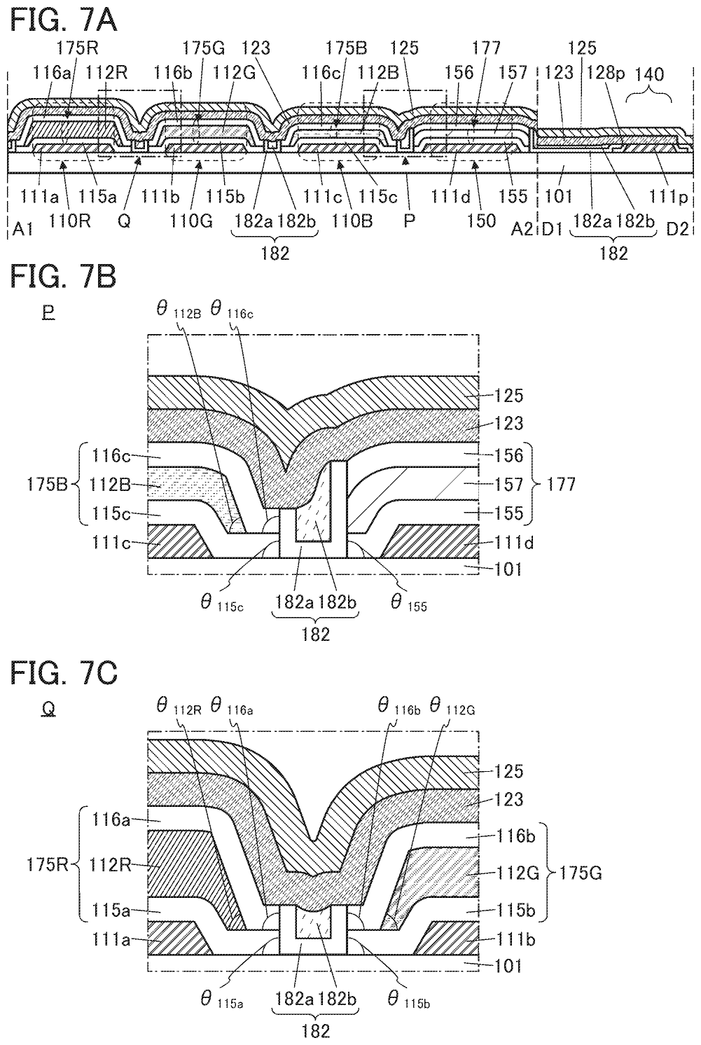

FIG. 7A illustrates a structure different from that in FIG. 6A. The light-emitting device 110R, the light-emitting device 110G, and the light-emitting device 110B illustrated in FIG. 7A are each different from the structure in FIG. 6A mainly in that the end portion of the light-emitting layer 112 is positioned more inwardly than the end portions of the first functional layer 115 and the second functional layer 116.

FIG. 7B is an enlarged view of a region P indicated by a dashed-dotted line in FIG. 7A, and FIG. 7C is an enlarged view of a region Q. The light-emitting device 110B and the light-receiving device 150 are shown on the left side and the right side in FIG. 7B, respectively. The light-emitting device 110R and the light-emitting device 110G are shown on the left side and the right side in FIG. 7C, respectively.

As illustrated in FIG. 6B, the end portion of the light-emitting layer 112B is positioned more inwardly than the end portion of the first functional layer 115c in the light-emitting device 110B. In addition, the end portion of the light-emitting layer 112B is positioned more inwardly than the end portion of the second functional layer 116c. The top surface and side surface of the light-emitting layer 112B are in contact with the second layer 116c. That is, the top surface and side surface of the light-emitting layer 112B are covered with the second layer 116c. Since the top surface and side surface of the light-emitting layer 112B are covered with the second functional layer 116c, impurities can be inhibited from diffusing to the light-emitting layer 112B. Therefore, the reliability of the light-emitting device 110B can be increased. Examples of the impurities include a metal component included in the common electrode 123.

The side surface of the light-emitting layer 112B is preferably tapered. An angle θ_{112B} formed by the side surface of the light-emitting layer 112B and a formation surface (here, the first functional layer 115c) is preferably small. Specifically, the angle θ_{112B} is preferably greater than 0° and less than 90°, further preferably greater than 0° and less than 60°, still further preferably greater than 0° and less than 50°, yet still further preferably greater than 0° and less than 40°, yet still further preferably greater than 0° and less than 30°. Such a small angle θ_{112B} can improve the step coverage with the layer (e.g., the second functional layer 116c) formed over the light-emitting layer 112B and the first functional layer 115c, thereby inhibiting generation of defects such as disconnection and a void in the layer. The angle θ_{112B} is preferably smaller than the angle θ_{115c}.

Note that the light-emitting layer 112B can be formed using an FMM. When the light-emitting layer 112B is formed using an FMM, its thickness becomes smaller as closer to its end portion and the angle θ_{112B} becomes extremely small in some cases. For example, the angle θ_{112B} is sometimes greater than 0° and less than 30°. Therefore, the side surface and top surface of the light-emitting layer 112B are connected continuously and difficult to clearly distinguish from each other in some cases.

The end portion of the second functional layer 116c is aligned or substantially aligned with the end portion of the first functional layer 115c. In other words, the second functional layer 116c has the same or substantially the same top surface shape as the first functional layer 115c. For example, a first film to be the first functional layer 115c and a second film to be the second functional layer 116c are processed with the same mask, whereby the first functional layer 115c and the second functional layer 116c can be formed.

Note that the side surfaces of the first functional layer 115c and the second functional layer 116c are preferably perpendicular or substantially perpendicular to their formation surfaces. For example, the angle θ_{115c} formed by the side surface of the first functional layer 115c and the formation surface (here, the substrate 101) is preferably greater than or equal to 60° and less than or equal to 90°. An angle θ_{116c} formed by the side surface of the second functional layer 116c and the formation surface (here, the first functional layer 115c) is preferably greater than or equal to 60° and less than or equal to 90°.

Note that although the light-emitting device 110B is described as an example here, the same applies to the light-emitting device 110R and the light-emitting device 110B. The description of the angle θ_{112B} can be referred to for an angle θ_{112R} formed by the side surface of the light-emitting layer 112R and the formation surface (here, the first functional layer 115a) and an angle θ_{112G} formed by the side surface of the light-emitting layer 112G and the formation surface (here, the first functional layer 115b); thus, detailed description is omitted here. The description of the angle θ_{116c} can be referred to for an angle θ₁₁₆ₐ formed by the side surface of the second functional layer 116a and the formation surface (here, the first functional layer 115a), and an angle θ_{116b} formed by the side surface of the second functional layer 116b and the formation surface (here, the first functional layer 115b); thus, detailed description is omitted here.

As illustrated in FIG. 7B, the end portion of the third functional layer 155, the end portion of the active layer 157, and the end portion of the fourth functional layer 156 are aligned or substantially aligned with one another in the light-receiving device 150. In other words, the third functional layer 155, the active layer 157, and the fourth functional layer 156 have the same or substantially the same top surface shape. For example, a film to be the third functional layer 155, a film to be the active layer 157, and a film to be the fourth functional layer 156 are processed with the same mask, whereby the third functional layer 155, the active layer 157, and the fourth functional layer 156 can be formed.

The side surface of the third functional layer 155 is preferably perpendicular or substantially perpendicular to the formation surface. For example, an angle θ₁₅₅ formed by the side surface of the third functional layer 155 and the formation surface (here, the substrate 101) is preferably greater than or equal to 60° and less than or equal to 90°.

### Structure Example 3-4

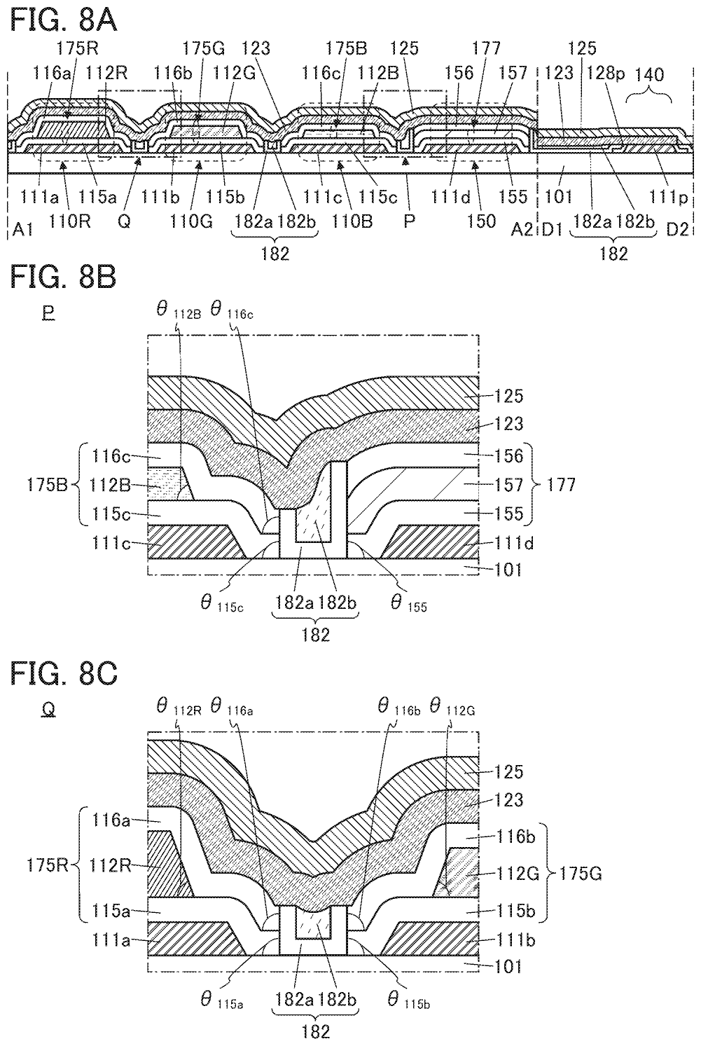

FIG. 8A illustrates a structure different from that in FIG. 7A. The light-emitting device 110R, the light-emitting device 110G, and the light-emitting device 110B illustrated in FIG. 8A are each different from the structure in FIG. 7A mainly in that the end portion of the light-emitting layer 112 is positioned more inwardly than the end portion of the electrode 111.

FIG. 8B is an enlarged view of a region P indicated by a dashed-dotted line in FIG. 8A, and FIG. 8C is an enlarged view of a region Q. The light-emitting device 110B and the light-receiving device 150 are shown on the left side and the right side in FIG. 8B, respectively. The light-emitting device 110R and the light-emitting device 110G are shown on the left side and the right side in FIG. 8C, respectively.

As illustrated in FIG. 8B, the end portions of the third functional layer 155, the active layer 157, and the fourth functional layer 156 are aligned or substantially aligned with one another in the light-receiving device 150. The end portions of the third functional layer 155, the active layer 157, and the fourth functional layer 156 are positioned more outwardly than the end portion of the electrode 111d.

As illustrated in FIG. 8B and FIG. 8C, the end portions of the first functional layer 115 and the second functional layer 116 are aligned or substantially aligned with each other in the light-emitting device 110. The end portions of the first functional layer 115 and the second functional layer 116 are positioned more outwardly than the end portion of the electrode 111. The end portion of the electrode 111 is positioned more outwardly than the end portion of the light-emitting layer 112.

### Structure Example 3-5

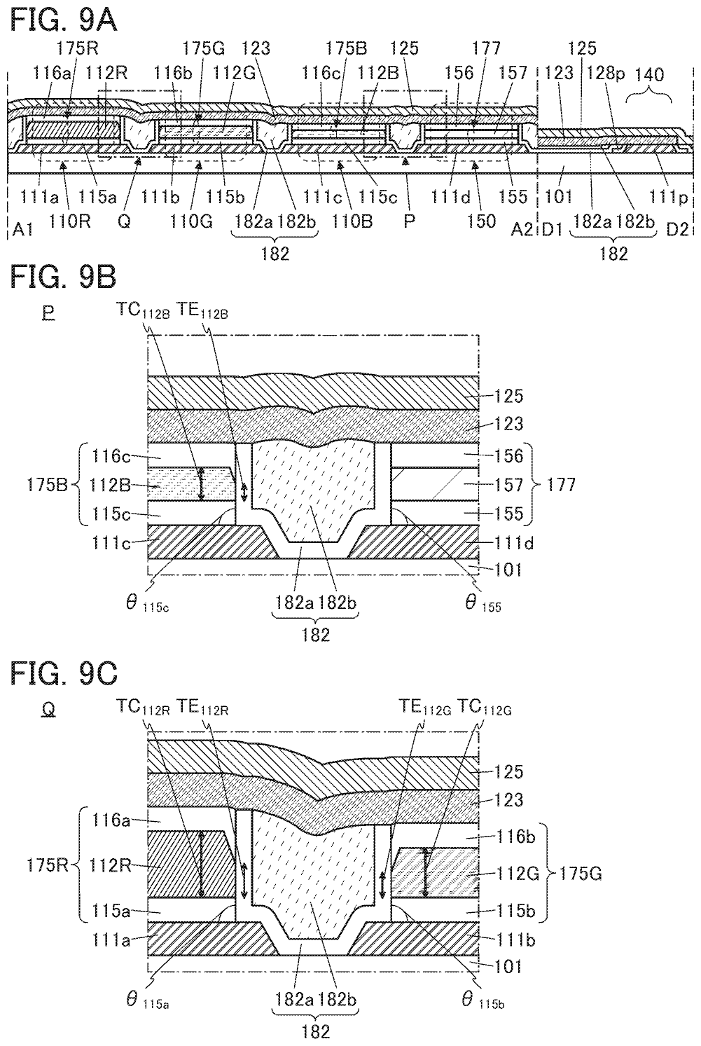

FIG. 9A illustrates a structure different from that in FIG. 6A. The light-emitting device 110R, the light-emitting device 110G, and the light-emitting device 110B illustrated in FIG. 9A are each different from the structure in FIG. 6A mainly in that the end portion of the EL layer 175 is positioned more inwardly than the end portion of the electrode 111. The light-receiving device 150 in FIG. 9A is different from the structure in FIG. 6A mainly in that the end portion of the light-receiving layer 177 is positioned more inwardly than the end portion of the electrode 111d.

FIG. 9B is an enlarged view of a region P indicated by a dashed-dotted line in FIG. 9A, and FIG. 9C is an enlarged view of a region Q. The light-emitting device 110B and the light-receiving device 150 are shown on the left side and the right side in FIG. 9B, respectively. The light-emitting device 110R and the light-emitting device 110G are shown on the left side and the right side in FIG. 9C, respectively.

As illustrated in FIG. 9B, the end portion of the light-receiving layer 177 is positioned over the electrode 111d. The end portion of the EL layer 175B is positioned over the electrode 111c. As illustrated in FIG. 9C, the end portion of the EL layer 175R is positioned over the electrode 111a. The end portion of the EL layer 175G is positioned over the electrode 111b.

The insulating layer 182 preferably includes regions in contact with the side surface of the EL layer 175, the side surface of the light-receiving layer 177, and the top and side surfaces of the electrode 111. In particular, the insulating layer 182 provided between the electrode 111 and the common electrode 123 can inhibit a short-circuit caused by contact between the electrode 111 and the common electrode 123.

### Structure Example 3-6

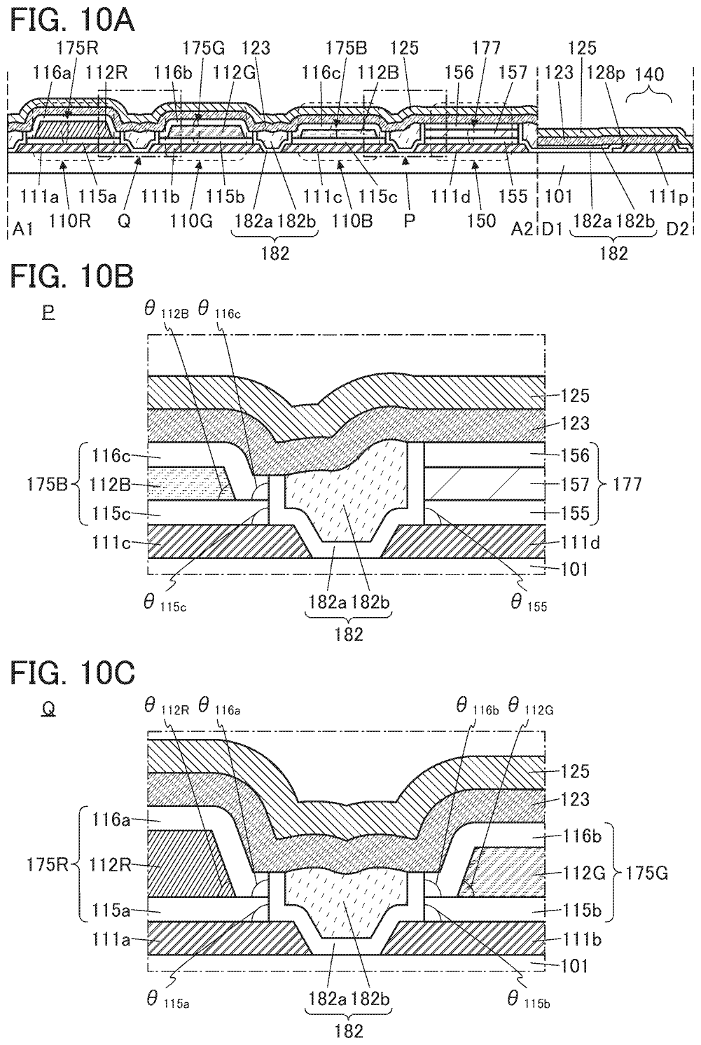

FIG. 10A illustrates a structure different from that in FIG. 9A. The light-emitting device 110R, the light-emitting device 110G, and the light-emitting device 110B illustrated in FIG. 10A are each different from the structure in FIG. 9A mainly in that the end portion of the light-emitting layer 112 is positioned more inwardly than the end portions of the first functional layer 115 and the second functional layer 116.

FIG. 10B is an enlarged view of a region P indicated by a dashed-dotted line in FIG. 10A, and FIG. 10C is an enlarged view of a region Q. The light-emitting device 110B and the light-receiving device 150 are shown on the left side and the right side in FIG. 10B, respectively. The light-emitting device 110R and the light-emitting device 110G are shown on the left side and the right side in FIG. 10C, respectively.

As illustrated in FIG. 10B, the end portions of the third functional layer 155, the active layer 157, and the fourth functional layer 156 are aligned or substantially aligned with one another in the light-receiving device 150. The end portions of the third functional layer 155, the active layer 157, and the fourth functional layer 156 are positioned more inwardly than the end portion of the electrode 111d.

As illustrated in FIG. 10B and FIG. 10C, the end portions of the first functional layer 115 and the second functional layer 116 are aligned or substantially aligned with each other in the light-emitting device 110. The end portions of the first functional layer 115 and the second functional layer 116 are positioned more inwardly than the end portion of the electrode 111. The end portions of the first functional layer 115 and the second functional layer 116 are positioned more outwardly than the end portion of the light-emitting layer 112.

### Structure Example 3-7

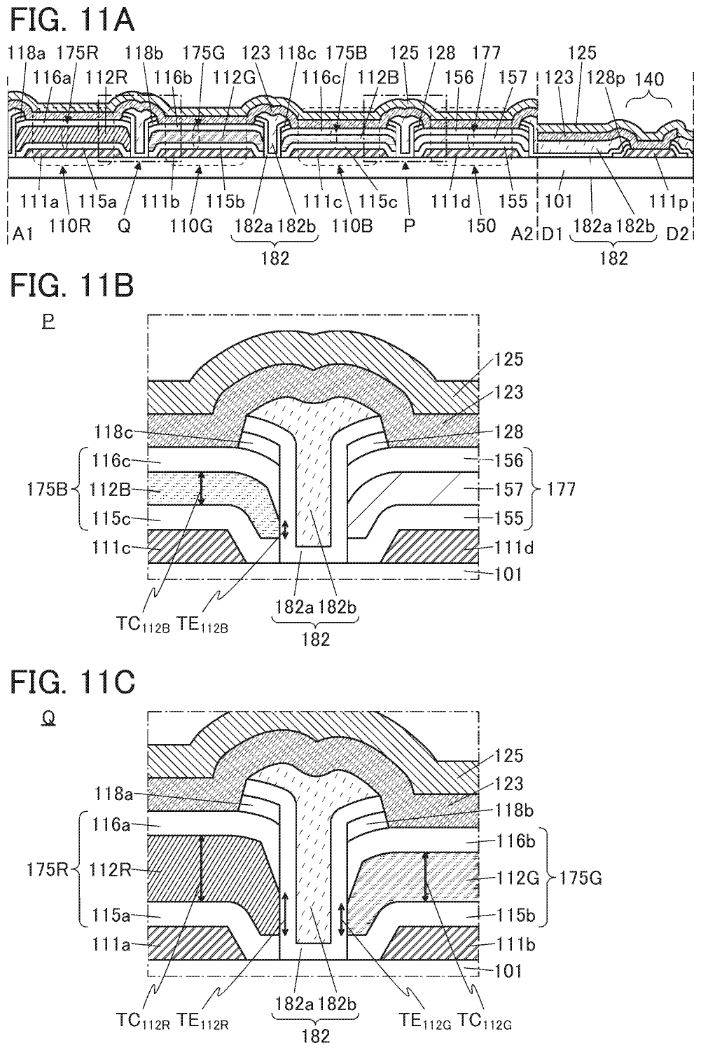

FIG. 11A illustrates a structure different from that in FIG. 6A. The structure illustrated in FIG. 11A is different from the structure in FIG. 6A mainly in that the insulating layer 182 includes regions overlapping with the top surface of the EL layer 175R, the top surface of the EL layer 175G, the top surface of the EL layer 175B, and the top surface of the light-receiving layer 177.

FIG. 11B is an enlarged view of a region P indicated by a dashed-dotted line in FIG. 11A, and FIG. 11C is an enlarged view of a region Q. The light-emitting device 110B and the light-receiving device 150 are shown on the left side and the right side in FIG. 11B, respectively. The light-emitting device 110R and the light-emitting device 110G are shown on the left side and the right side in FIG. 11C, respectively.

As illustrated in FIG. 11B, the top surface of the insulating layer 182 includes a region whose level is higher than the level of the top surface of the light-receiving layer 177. A sacrificial layer 128 used for forming the light-receiving layer 177 may be left between the insulating layer 182 and the light-receiving layer 177. Details of the sacrificial layer 128 will be described later.

In the cross-sectional view, one of the end portions of the sacrificial layer 128 is aligned or substantially aligned with the end portion of the light-receiving layer 177. The other end portion of the sacrificial layer 128 is aligned or substantially aligned with the end portion of the insulating layer 182. For example, a first sacrificial layer to be the sacrificial layer 128 is formed over a film to be the light-receiving layer 177. Then, the film to be the light-receiving layer 177 is processed with the first sacrificial layer as a mask, so that the light-receiving layer 177 is formed. Next, films to be the insulating layer 182a and the insulating layer 182b are formed. Then, the film to be the insulating layer 182a and the first sacrificial layer are processed with the insulating layer 182b as a mask, so that the insulating layer 182a and the sacrificial layer 128 can be formed.

The top surface of the insulating layer 182 includes a region whose level is higher than the level of the top surface of the EL layer 175B. In addition, a sacrificial layer 118c used for forming the EL layer 175B may be left between the insulating layer 182 and the EL layer 175B.

One of the end portions of the sacrificial layer 118c is aligned or substantially aligned with the end portion of the EL layer 175B. The other end portion of the sacrificial layer 118c is aligned or substantially aligned with the end portion of the insulating layer 182. For example, a second sacrificial layer to be the sacrificial layer 118c is formed over a film to be the EL layer 175B. Then, the film to be the EL layer 175B is processed with the second sacrificial layer with a mask, so that the EL layer 175B is formed. Next, films to be the insulating layer 182a and the insulating layer 182b are formed. Then, the film to be the insulating layer 182a and the second sacrificial layer are processed with the insulating layer 182b as a mask, so that the insulating layer 182a and the sacrificial layer 118c are formed. Details of the sacrificial layer 118c will be detailed later.

As illustrated in FIG. 11C, the top surface of the insulating layer 182 includes a region whose level is higher than the level of the top surface of the EL layer 175R. In addition, a sacrificial layer 118a used for forming the EL layer 175R may be left between the insulating layer 182 and the EL layer 175R. Similarly, the top surface of the insulating layer 182 includes a region whose level is higher than the level of the top surface of the EL layer 175G. In addition, a sacrificial layer 118b used for forming the EL layer 175G may be left between the insulating layer 182 and the EL layer 175G. For the sacrificial layer 118a and the sacrificial layer 118b, the description of the sacrificial layer 118c can be referred to; thus, the detailed description is omitted.

### Structure Example 3-8

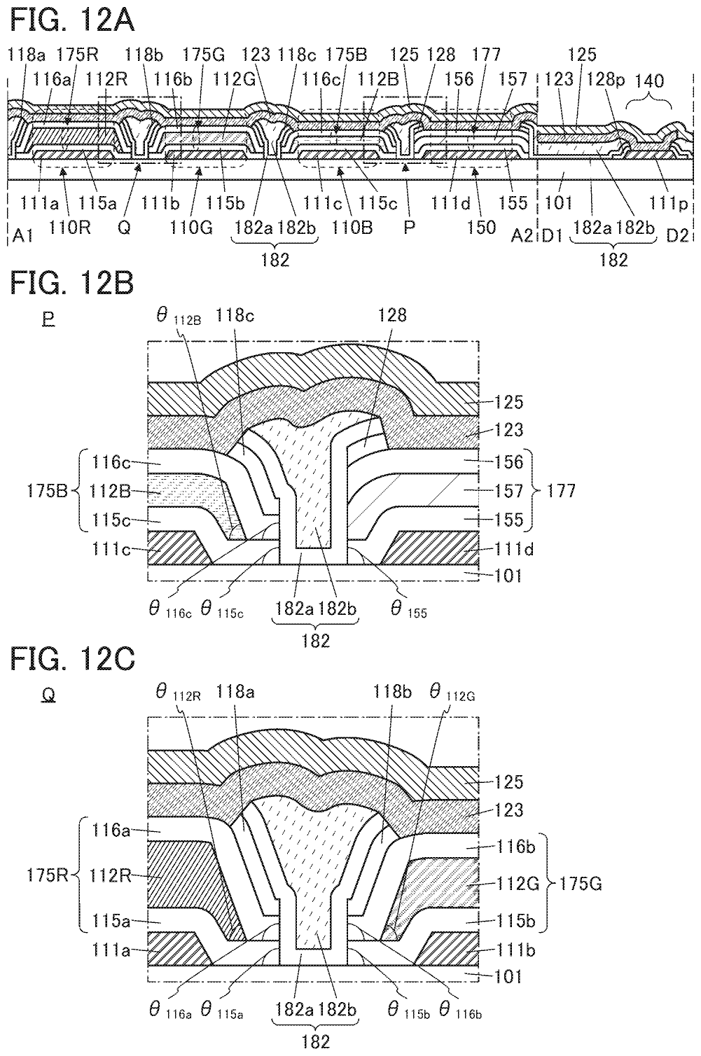

FIG. 12A illustrates a structure different from that in FIG. 7A. The structure illustrated in FIG. 12A is different from the structure in FIG. 7A mainly in that the insulating layer 182 includes regions overlapping with the top surface of the EL layer 175R, the top surface of the EL layer 175G, the top surface of the EL layer 175B, and the top surface of the light-receiving layer 177.

FIG. 12B is an enlarged view of a region P indicated by a dashed-dotted line in FIG. 12A, and FIG. 12C is an enlarged view of a region Q. The light-emitting device 110B and the light-receiving device 150 are shown on the left side and the right side in FIG. 12B, respectively. The light-emitting device 110R and the light-emitting device 110G are shown on the left side and the right side in FIG. 12C, respectively.

As illustrated in FIG. 12B, the top surface of the insulating layer 182 includes a region whose level is higher than the level of the top surface of the light-receiving layer 177. In addition, the sacrificial layer 128 used for forming the light-receiving layer 177 may be left between the insulating layer 182 and the light-receiving layer 177.

As illustrated in FIG. 12B and FIG. 12C, the top surface of the insulating layer 182 includes a region whose level is higher than the level of the top surface of the EL layer 175. In addition, the sacrificial layer 118a, the sacrificial layer 118b, and the sacrificial layer 118c used for forming the EL layer 175R, the EL layer 175G, and the EL layer 175B may be left between the insulating layer 182 and the EL layer 175R, the EL layer 175G, or the EL layer 175B.

### Structure Example 3-9

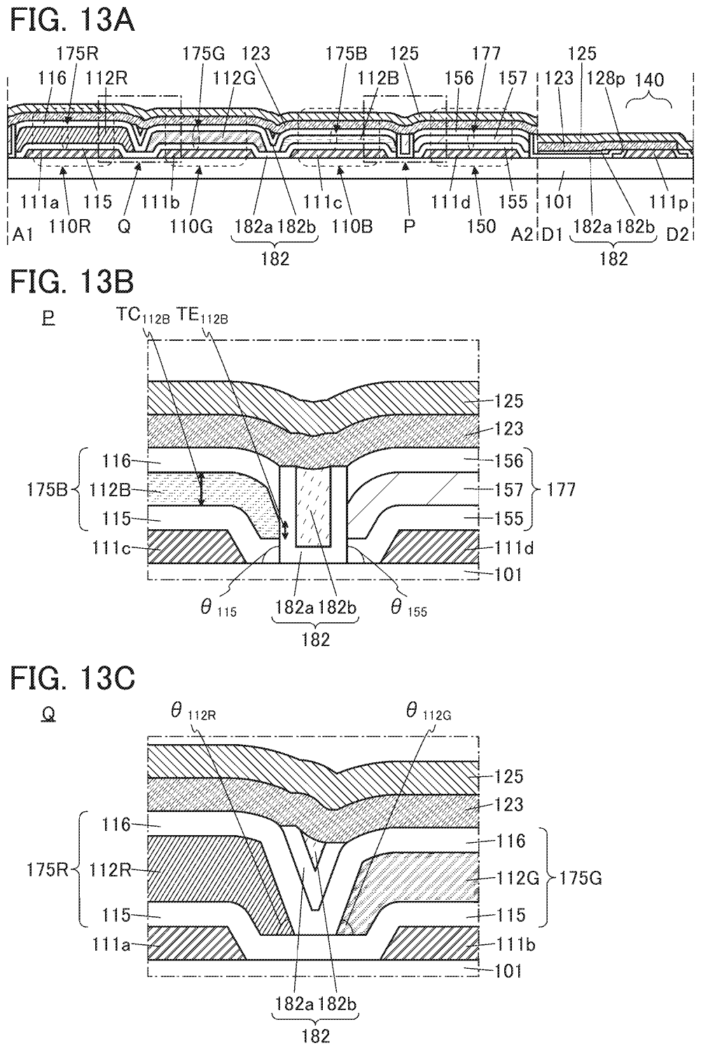

FIG. 13A illustrates a structure different from that in FIG. 6A. The light-emitting device 110R, the light-emitting device 110G, and the light-emitting device 110B illustrated in FIG. 13A are each different from the structure in FIG. 6A mainly in including the first functional layer 115 instead of the first functional layer 115a, the first functional layer 115b, and the first functional layer 115c, and in including the second functional layer 116 instead of the second functional layer 116a, the second functional layer 116b, and the second functional layer 116c.

Specifically, the light-emitting device 110R includes the first functional layer 115, the light-emitting layer 112R, and the second functional layer 116 that are stacked in this order, as an EL layer. The light-emitting device 110G includes the first functional layer 115, the light-emitting layer 112G, and the second functional layer 116 that are stacked in this order, as an EL layer. The light-emitting device 110B includes the first functional layer 115, the light-emitting layer 112B, and the second functional layer 116 that are stacked in this order, as an EL layer.

The first functional layer 115 is a layer shared by the light-emitting device 110R, the light-emitting device 110G, and the light-emitting device 110B and can be referred to as a first common layer. Similarly, the second functional layer 116 can be referred to as a second common layer. A material usable for the first functional layer 115a, the first functional layer 115b, and the first functional layer 115c can be used for the first functional layer 115. A material usable for the second functional layer 116a, the second functional layer 116b, the second functional layer 116c can be used for the second functional layer 116.

FIG. 13B is an enlarged view of a region P indicated by a dashed-dotted line in FIG. 13A, and FIG. 13C is an enlarged view of a region Q. The light-emitting device 110B and the light-receiving device 150 are shown on the left side and the right side in FIG. 13B, respectively. The light-emitting device 110R and the light-emitting device 110G are shown on the left side and the right side in FIG. 13C, respectively.

It is preferable that the light-receiving layer 177 in the light-receiving device 150 not include a layer shared with the EL layer 175B in the light-emitting device 110B and not include a region in contact with the EL layer 175B as illustrated in FIG. 13B. In other words, the light-receiving layer 177 in the light-receiving device 150 is preferably separated from the EL layer 175 in the light-emitting device 110 adjacent to the light-receiving device 150. Note that the same applies to the case where two light-receiving devices 150 are adjacent to each other; the light-receiving layer 177 in one of the light-receiving devices 150 is preferably separated from the light-receiving layer 177 in the other of the light-receiving devices 150.

The end portion of the second functional layer 116 is aligned or substantially aligned with the end portion of the first functional layer 115 as illustrated in FIG. 13B. In other words, the second functional layer 116 has the same or substantially the same top surface shape as the first functional layer 115. For example, a first film to be the first functional layer 115 and a second film to be the second functional layer 116 are processed with the same mask, the first functional layer 115 and the second functional layer 116 can be formed.

The side surface of the first functional layer 115 is preferably perpendicular or substantially perpendicular to the formation surfaces. For example, an angle θ115 formed by the side surface of the first functional layer 115 and the formation surface (here, the substrate 101) is preferably greater than or equal to 60° and less than or equal to 90°.

As illustrated in FIG. 13A, FIG. 13B, and FIG. 13C, the first functional layer 115 and the second functional layer 116 are shared by the adjacent light-emitting devices 110. Specifically, the first functional layer 115 and the second functional layer 116 are shared by the adjacent light-emitting layers 112 that are the light-emitting layer 112R, the light-emitting layer 112G, and the light-emitting layer 112B.

### Structure Example 3-10

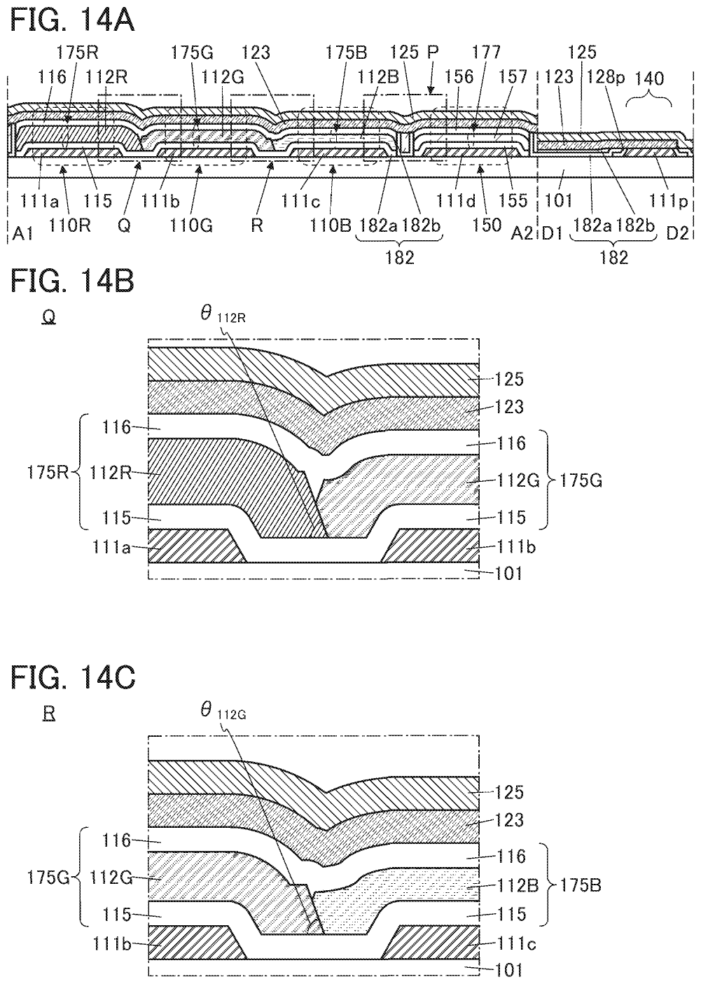

FIG. 14A illustrates a structure different from that in FIG. 13A. The light-emitting device 110R, the light-emitting device 110G, and the light-emitting device 110B illustrated in FIG. 14A are each different from the structure in FIG. 13A mainly in including a region where the adjacent light-emitting layers 112 overlap with each other.

FIG. 14B is an enlarged view of a region Q indicated by a dashed-dotted line in FIG. 14A, and FIG. 14C is an enlarged view of a region R. The light-emitting device 110R and the light-emitting device 110G are shown on the left side and the right side in FIG. 14B, respectively. The light-emitting device 110G and the light-emitting device 110B are shown on the left side and the right side in FIG. 14C, respectively. FIG. 13B can be referred to for the enlarged view of the region P.

As illustrated in FIG. 14B, the light-emitting layer 112G includes a region overlapping with the light-emitting layer 112R. Specifically, the light-emitting layer 112G is provided to cover the light-emitting layer 112R and includes a region in contact with the end portion of the light-emitting layer 112R. Similarly, as illustrated in FIG. 14C, the light-emitting layer 112B includes a region overlapping with the light-emitting layer 112G. Specifically, the light-emitting layer 112B is provided to cover the light-emitting layer 112G and includes a region in contact with the end portion of the light-emitting layer 112G.

The structure shown in FIG. 14A and the like is such that the light-emitting layer 112R, the light-emitting layer 112G, and the light-emitting layer 112B are formed in this order, the light-emitting layer 112B covers the light-emitting layer 112G, and the light-emitting layer 112G covers the light-emitting layer 112R; however, one embodiment of the present invention is not limited thereto. Without particular limitation of the order for forming the light-emitting layer 112R, the light-emitting layer 112G, and the light-emitting layer 112B, a structure where adjacent light-emitting layers 112 overlap with each other can be provided. Whether a region where two adjacent light-emitting layers 112 overlap with each other can be confirmed by, for example, a photoluminescence (PL) method.

It is preferable that the adjacent light-emitting layers 112 not overlap with each other in a region where any of the light-emitting layers 112 overlaps with the electrode 111. In other words, the region where the adjacent light-emitting layers 112 overlap with each other is preferably a region not overlapping with the electrode 111. Due to the region where the adjacent light-emitting layers 112 overlap with each other, the total thickness of the light-emitting layers 112 is increased, which causes an increase in driving voltages, in some cases. As a result, a contribution to light emission might be decreased. The region where the any of the light-emitting layers 112 overlaps with the electrode 111 is prevented from overlapping with the adjacent light-emitting layers 112, which can inhibit a reduction in areas of light-emitting regions.

In the vicinity of the end portion of the light-emitting layer 112, a step caused by a level difference between a region provided with the light-emitting layer 112 and a region without the light-emitting layer 112 is generated between the adjacent light-emitting devices 110. In the display apparatus of one embodiment of the present invention, the step is reduced by providing the region where the adjacent light-emitting layers 112 overlap with each other, so that the step coverage with the second functional layer 116 provided over the light-emitting layer 112 can be enhanced. Therefore, disconnection of the second functional layer 116 can be inhibited.

The structure shown in FIG. 14A and the like is such that the insulating layer 182 is provided between the light-receiving layer 177 and the EL layer 175 adjacent thereto and the insulating layer 182 is not provided between two adjacent EL layers 175; however, one embodiment of the present invention is not limited thereto. The insulating layer 182 may be provided also between two adjacent EL layers 175. In the case where the first functional layer 115 and the second functional layer 116 are separated between two adjacent light-emitting devices 110, a region where the adjacent light-emitting layers 112 are in contact with each other may be removed or part of the region may be removed.

### Structure Example 3-11

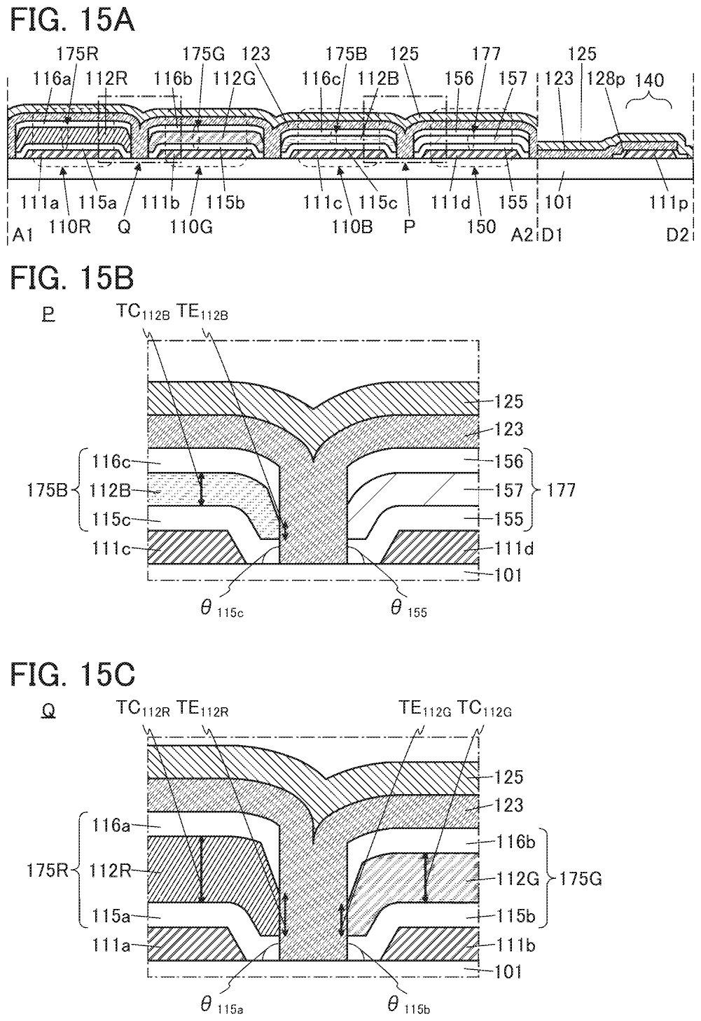

FIG. 15A illustrates a structure different from that in FIG. 6A. The structure in FIG. 15A is different from the structure in FIG. 6A mainly in not including the insulating layer 182.

FIG. 15B is an enlarged view of a region P indicated by a dashed-dotted line in FIG. 15A, and FIG. 15C is an enlarged view of a region Q. The light-emitting device 110B and the light-receiving device 150 are shown on the left side and the right side in FIG. 15B, respectively. The light-emitting device 110R and the light-emitting device 110G are shown on the left side and the right side in FIG. 15C, respectively.

As illustrated in FIG. 15B and FIG. 15C, each of the side surfaces of the electrode 111a, the electrode 111b, and the electrode 111c is preferably covered with at least one of the first functional layer 115, the light-emitting layer 112, and the second functional layer 116. In other words, each of the end portions of the electrode 111a, the electrode 111b, and the electrode 111c is preferably positioned more inwardly than at least one of the end portion of the first functional layer 115, the end portion of the light-emitting layer 112, and the end portion of the second functional layer 116. Similarly, the side surface of the electrode 111d is preferably covered with at least one of the third functional layer 155, the active layer 157, and the fourth functional layer 156. In other words, the end portion of the electrode 111d is preferably positioned more inwardly than at least one of the end portion of the third functional layer 155, the end portion of the active layer 157, and the end portion of the fourth functional layer 156. With such a structure, a short-circuit caused by contact between the electrode 111 and the common electrode 123 can be inhibited.

### Structure Example 3-12

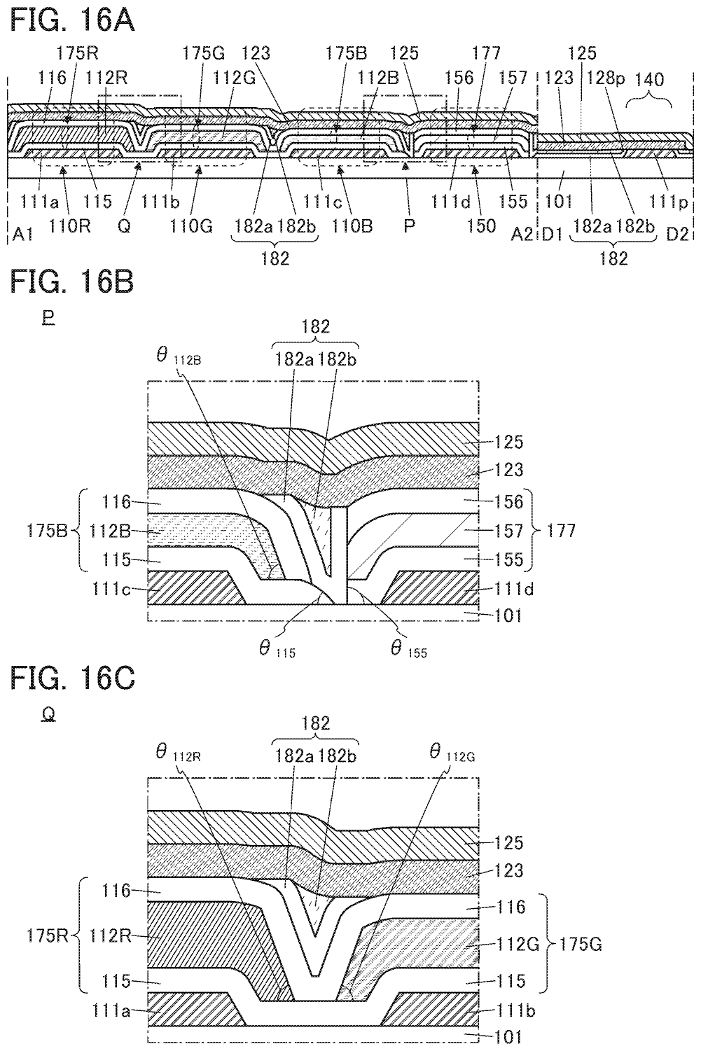

FIG. 16A illustrates a structure different from that in FIG. 13A. The light-emitting device 110R, the light-emitting device 110G, and the light-emitting device 110B illustrated in FIG. 16A are each different from the structure in FIG. 13A mainly in shapes of the side surface of the first functional layer 115 and the side surface of the second functional layer 116.

FIG. 16B is an enlarged view of a region P indicated by a dashed-dotted line in FIG. 16A, and FIG. 16C is an enlarged view of a region Q. The light-emitting device 110B and the light-receiving device 150 are shown on the left side and the right side in FIG. 16B, respectively. The light-emitting device 110R and the light-emitting device 110G are shown on the left side and the right side in FIG. 16C, respectively.

The side surface of the first functional layer 115 is preferably tapered. The angle θ₁₁₅ formed by the side surface of the first functional layer 115 and the formation surface (here, the substrate 101) is preferably small. Specifically, the angle θ₁₁₅ is preferably greater than 0° and less than 90°, further preferably greater than 0° and less than 60°, still further preferably greater than 0° and less than 50°, yet still further preferably greater than 0° and less than 40°, yet still further preferably greater than 0° and less than 30°. Such a small angle θ₁₁₅ can improve the step coverage with the layer (e.g., the insulating layer 182) formed over the substrate 101 and the first functional layer 115, thereby inhibiting generation of defects such as disconnection or a void. The side surfaces of the second functional layer 116 may be tapered. When the side surface of the second functional layer 116 has a tapered shape, the step coverage with the layer (e.g., the insulating layer 182) formed over the first functional layer 115 and the second functional layer 116, thereby inhibiting generation of defects such as disconnection or a void.

As illustrated in FIG. 16B, the end portion of the second functional layer 116 is positioned more inwardly than the end portion of the first functional layer 115. Alternatively, the end portion of the second functional layer 116 may be positioned more outwardly than the end portion of the first functional layer 115 or may be aligned or substantially aligned with the end portion of the first functional layer 115.

The structure shown in FIG. 16A and the like is such that the end portion of the light-emitting layer 112 is positioned more inwardly than the end portions of the first functional layer 115 and the second functional layer 116; however, one embodiment of the present invention is not limited thereto. The end portion of the light-emitting layer 112 may be positioned more outwardly than the end portion of the first functional layer 115. The end portion of the light-emitting layer 112 may be positioned more outwardly than the end portion of the second functional layer 116.

### Structure Example 3-13

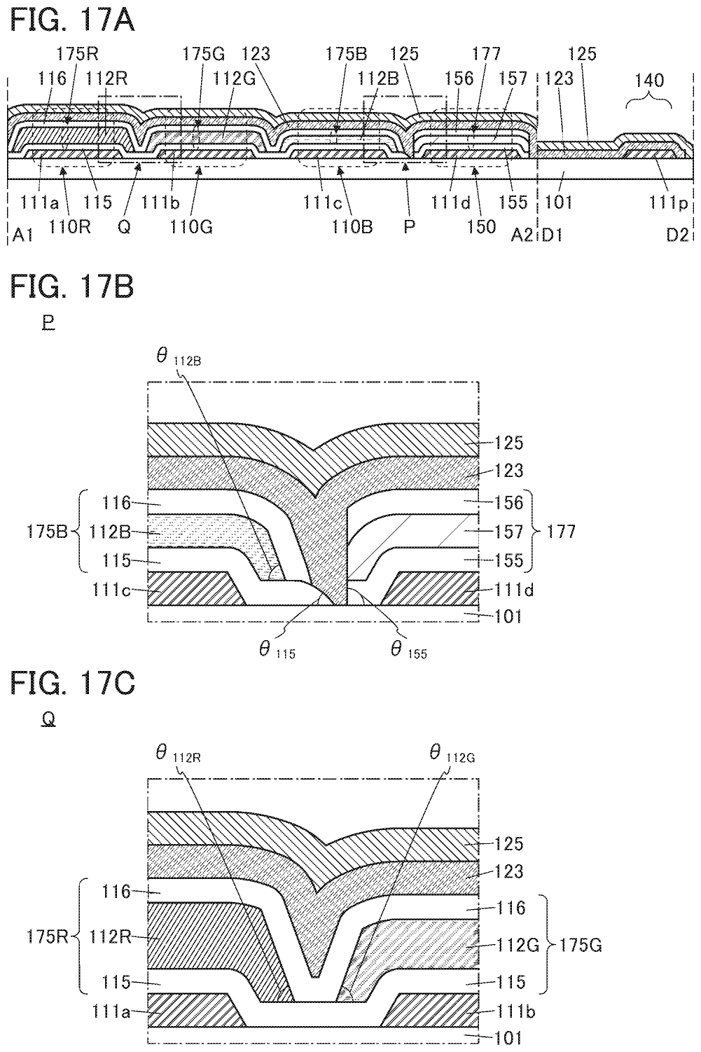

FIG. 17A illustrates a structure different from that in FIG. 16A. The structure in FIG. 17A is different from the structure in FIG. 16A mainly in not including the insulating layer 182.

FIG. 17B is an enlarged view of a region P indicated by a dashed-dotted line in FIG. 17A, and FIG. 17C is an enlarged view of a region Q. The light-emitting device 110B and the light-receiving device 150 are shown on the left side and the right side in FIG. 17B, respectively. The light-emitting device 110R and the light-emitting device 110G are shown on the left side and the right side in FIG. 17C, respectively.

As illustrated in FIG. 17B and FIG. 17C, each of the side surfaces of the electrode 111a, the electrode 111b, and the electrode 111c is preferably covered with at least one of the first functional layer 115, the light-emitting layer 112, and the second functional layer 116. In other words, each of the end portions of the electrode 111a, the electrode 111b, and the electrode 111c is preferably positioned more inwardly than at least one of the end portion of the first functional layer 115, the end portion of the light-emitting layer 112, and the end portion of the second functional layer 116. Similarly, the side surface of the electrode 111d is preferably covered with at least one of the third functional layer 155, the active layer 157, and the fourth functional layer 156. In other words, the end portion of the electrode 111d is preferably positioned more inwardly than at least one of the end portion of the third functional layer 155, the end portion of the active layer 157, and the end portion of the fourth functional layer 156. With such a structure, short-circuit caused by contact between the electrode 111 and the common electrode 123 can be inhibited.

### Manufacturing Method Example 1

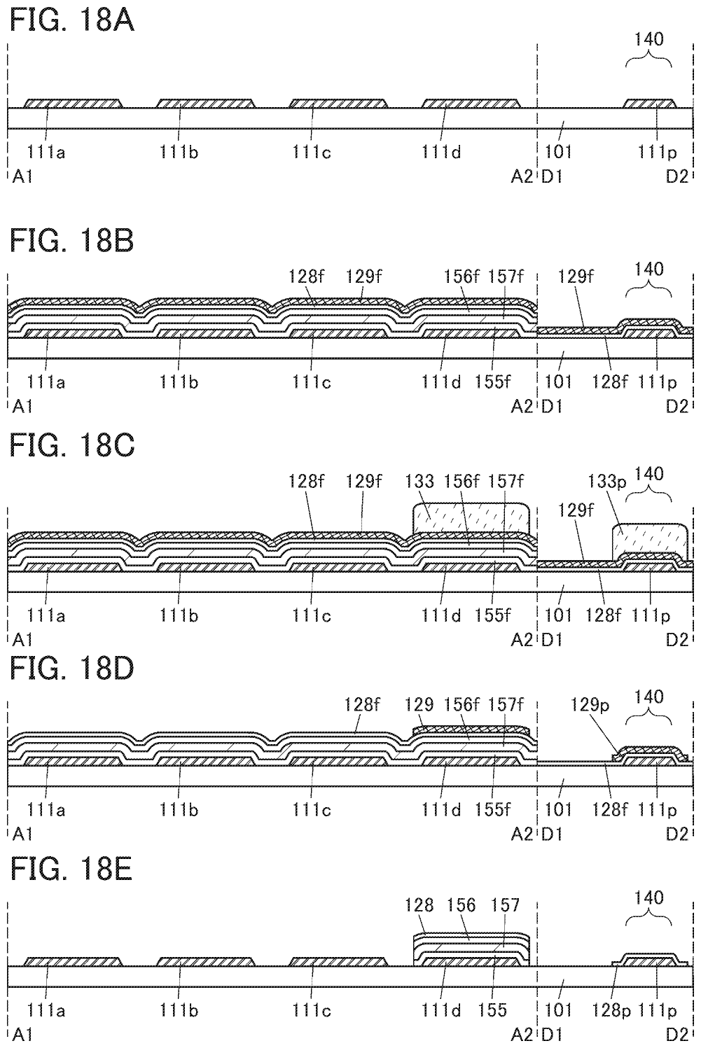

An example of a method for manufacturing the display apparatus of one embodiment of the present invention is described below with reference to drawings. Here, a method for manufacturing the display apparatus illustrated in FIG. 6A is described as an example. FIG. 18A to FIG. 21D are schematic cross-sectional views in processes of the method for manufacturing the display apparatus.

Note that thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method, a thermal CVD method, and the like. An example of the thermal CVD method is a metal organic chemical vapor deposition (MOCVD: Metal Organic CVD) method.

Thin films included in the display apparatus (insulating films, semiconductor films, conductive films, and the like) can be formed by a method such as spin coating, dipping, spray coating, ink-jetting, dispensing, screen printing, offset printing, a doctor knife method, slit coating, roll coating, curtain coating, or knife coating.

The thin films included in the display apparatus can be processed by a photolithography method or the like. Besides, the thin films may be processed by a nanoimprinting method, a sandblasting method, a lift-off method, or the like.

There are the following two typical examples of a photolithography method. In one of the methods, a resist mask is formed over a thin film that is to be processed, the thin film is processed by etching or the like, and the resist mask is removed. In the other method, a photosensitive thin film is deposited and then processed into a desired shape by light exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. Light exposure may be performed by liquid immersion light exposure technique. Alternatively, for the light used for the exposure, extreme ultraviolet (EUV) light, X-rays, or the like may be used. Furthermore, instead of the light used for the light exposure, an electron beam can also be used. Extreme ultraviolet light, X-rays, or an electron beam is preferably used, in which case extremely minute processing can be performed. Note that when light exposure is performed by scanning of a beam such as an electron beam, a photomask is not needed.

For etching of the thin films, a dry etching method, a wet etching method, a sandblast method, or the like can be used.

[Formation of Electrode 111a to Electrode 111d and Electrode 111p]

The electrode 111a, the electrode 111b, the electrode 111c, the electrode 111d, and the electrode 111p are formed over the substrate 101 (FIG. 18A). First, a conductive film is deposited, a resist mask is formed by a photolithography method, and an unnecessary portion of the conductive film is removed by etching. After that, the resist mask is removed, whereby the electrode 111a, the electrode 111b, the electrode 111c, the electrode 111d, and the electrode 111p can be formed.

In the case where a conductive film having a reflective property with respect to visible light is used for the pixel electrodes, it is preferable to use a material having reflectance as high as possible in the entire wavelength range of visible light (e.g., silver, aluminum, or the like). This can increase color reproducibility as well as light extraction efficiency of the light-emitting devices.

Each of the side surfaces of the electrode 111a, the electrode 111b, the electrode 111c, the electrode 111d, and the electrode 111p preferably has a tapered shape. A resist mask used for forming the electrode 111a, the electrode 111b, the electrode 111c, the electrode 111d, and the electrode 111p preferably has a side surface in a tapered shape. A wet etching method can be suitably used to form the conductive film.

[Formation of Functional Film 155f, Active Film 157f, and Functional Film 156f]

Next, a functional film 155f to be the third functional layer 155 later, an active film 157f to be the active layer 157, and a functional film 156f to be the fourth functional layer 156 are deposited in this order over the electrode 111a, the electrode 111b, the electrode 111c, and the electrode 111d. The functional film 155f, the active film 157f, and the functional film 156f can each be formed by, for example, an evaporation method, a sputtering method, a coating method, or an inkjet method. Without limitation to this, the above-described deposition method can be used as appropriate. Note that in this specification and the like, the functional film 155f, the active film 157f, and the functional film 156f are collectively referred to as a light-receiving film in some cases.

For example, in the case where a light-receiving device having a sensitivity in an infrared-light wavelength range is fabricated, at least one of the functional film 155f, the active film 157f, and the functional film 156f is formed using a high molecular compound by a coating method or an inkjet method, whereby the light-receiving device can have favorable characteristics.

It is preferable that the functional film 155f, the active film 157f, and the functional film 156f not be provided over the electrode 111p. For example, when the functional film 155f, the active film 157f, and the functional film 156f are each formed by an evaporation method or a sputtering method, a shielding mask may be used such that the functional film 155f, the active film 157f, and the functional film 156f are not deposited over the electrode 111p.

[Formation of Sacrificial Film 128f and Sacrificial Film 129f]

Next, a sacrificial film 128f and a sacrificial film 129f are formed in this order over the functional film 156f (FIG. 18B). The sacrificial film 128f is provided in contact with the top surface of the electrode 111p.

As the sacrificial film 128f, it is possible to favorably use a film highly resistant to etching treatment on the functional film 156f, the active film 157f, and the functional film 155f, i.e., a film having high etching selectivity. Furthermore, as the sacrificial film 128f, it is possible to favorably use a film having high etching selectivity with respect to the sacrificial film 129f described later. Furthermore, as the sacrificial film 128f, it is particularly preferable to use a film that can be removed by a wet etching method that causes less damage to the functional film 156f, the active film 157f, and the functional film 155f.

As the sacrificial film 128f, an inorganic film such as a metal film, an alloy film, a metal oxide film, a semiconductor film, or an inorganic insulating film can be used, for example. The sacrificial film 128f can be formed by any of a variety of deposition methods such as a sputtering method, an evaporation method, a CVD method, and an ALD method. In particular, an ALD method gives less deposition damage to a formation layer; thus, the sacrificial film 128f, which is directly formed on the functional film 156f, is preferably formed by an ALD method.

For the sacrificial film 128f, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

For the sacrificial film 128f, a metal oxide such as indium gallium zinc oxide (In—Ga—Zn oxide, also referred to as IGZO) can be used. It is also possible to use indium oxide, indium zinc oxide (In—Zn oxide), indium tin oxide (In—Sn oxide, also referred to as ITO), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, an indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be used instead of gallium. Specifically, the element M is preferably one or more kinds selected from gallium, aluminum, and yttrium.

For the sacrificial film 128f, oxide such as aluminum oxide, hafnium oxide, or silicon oxide, nitride such as silicon nitride or aluminum nitride, or oxynitride such as silicon oxynitride can be used. Such an inorganic insulating material can be formed by a sputtering method, a CVD method, an ALD method, or the like.

For the sacrificial film 128f, it is preferable to use a material that can be dissolved in a solvent chemically stable with respect to at least the functional film 156f. In particular, a material that is dissolved in water or alcohol can be favorably used for the sacrificial film 128f. In deposition of the sacrificial film 128f, it is preferable that application of such a material that has been dissolved in a solvent such as water or alcohol be performed by a wet deposition method and followed by heat treatment for evaporating the solvent. At this time, the heat treatment is preferably performed in a reduced-pressure atmosphere because the solvent can be removed at a low temperature in a short time and thermal damage to the functional film 156f, the active film 157f, and the functional film 155f can be reduced accordingly.

Examples of the wet deposition method that can be used for forming the sacrificial film 128f include spin coating, dipping, spray coating, ink-jetting, dispensing, screen printing, offset printing, a doctor knife method, slit coating, roll coating, curtain coating, and knife coating.

For the sacrificial film 128f, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

The sacrificial film 129f is used as a hard mask when the sacrificial film 128f is etched later. In a later process of processing the sacrificial film 129f, the sacrificial film 128f is exposed. Thus, the combination of films having high etching selectivity therebetween is selected for the sacrificial film 128f and the sacrificial film 129f. It is thus possible to select a film that can be used for the sacrificial film 129f depending on an etching condition of the sacrificial film 128f and an etching condition of the sacrificial film 129f.

For example, in the case where dry etching using a gas containing fluorine (also referred to as a fluorine-based gas) is used for the etching of the sacrificial film 129f, silicon, silicon nitride, silicon oxide, tungsten, titanium, molybdenum, tantalum, tantalum nitride, an alloy containing molybdenum and niobium, an alloy containing molybdenum and tungsten, or the like can be used for the sacrificial film 129f. Here, a film of metal oxide such as IGZO or ITO is given as a film having high etching selectivity (that is, enabling low etching rate) in dry etching using the fluorine-based gas, and such a film can be used for the sacrificial film 128f.

Without being limited to the above, a material for the sacrificial film 129f can be selected from a variety of materials depending on the etching condition of the sacrificial film 128f and the etching condition of the sacrificial film 129f. For example, any of the films that can be used for the sacrificial film 128f can also be used.

For example, for the sacrificial film 129f, an oxide film can be used. Typically, an oxide film or an oxynitride film such as silicon oxide, silicon oxynitride, aluminum oxide, aluminum oxynitride, hafnium oxide, or hafnium oxynitride can be used.

As the sacrificial film 129f, a nitride film can be used, for example. Specifically, it is also possible to use a nitride such as silicon nitride, aluminum nitride, hafnium nitride, titanium nitride, tantalum nitride, tungsten nitride, gallium nitride, or germanium nitride. Alternatively, for the sacrificial film 129f, a metal such as tungsten, molybdenum, copper, aluminum, titanium, or tantalum or an alloy containing the metal may be used.

For example, it is preferable that an inorganic insulating material such as aluminum oxide, hafnium oxide, or silicon oxide formed by an ALD method be used for the sacrificial film 128f, and a metal oxide containing indium, such as an indium gallium zinc oxide (an In—Ga—Zn oxide, also referred to as IGZO), formed by a sputtering method be used for the sacrificial film 129f.

For the sacrificial film 129f, it is possible to use a material usable for the functional film 155f, the active film 157f, or the functional film 156f, for example. The use of such a material is preferable because in that case the deposition apparatus can be used in common. Furthermore, the sacrificial film 129f can also be removed at the time of later etching of the functional film 155f, the active film 157f, and the functional film 156f with the sacrificial layer used as a mask, whereby the processes can be simplified.

### [Formation of Sacrificial Layer 129 and Sacrificial Layer 128]

Next, a resist mask 133 and a resist mask 133p are formed over the sacrificial film 129f in a region overlapping with the electrode 111d and over the sacrificial film 129f in a region overlapping with the connection portion 140 (FIG. 18C).

For the resist mask 133 and the resist mask 133p, a resist material containing a photosensitive resin, such as a positive type resist material or a negative type resist material can be used.

Here, in the case where the sacrificial film 129f is not formed and the resist mask 133 and the resist mask 133p are formed over the sacrificial film 128f, when a defect such as a pinhole exists in the sacrificial film 128f, there is a risk of dissolving the functional film 156f and the like due to a solvent of the resist material. Such a defect can be prevented by using the sacrificial film 129f.

Note that in the case where a film that is unlikely to cause a defect such as a pinhole is used as the sacrificial film 128f, the resist mask 133 and the resist mask 133p may be formed directly on the sacrificial film 128f without using the sacrificial film 129f.

Next, the sacrificial film 129f in a region covered with neither the resist mask 133 nor the resist mask 133p is removed by etching to form the sacrificial layer 129 and a sacrificial layer 129p.

In the etching of the sacrificial film 129f, an etching condition with high selectivity is preferably employed so that the sacrificial film 128f is not removed by the etching. Either wet etching or dry etching can be performed for the etching of the sacrificial film 129f; with use of dry etching, a reduction in areas of the sacrificial layer 129 and the sacrificial layer 129p can be inhibited.

Next, the resist mask 133 and the resist mask 133p are removed (FIG. 18D).

The resist mask 133 and the resist mask 133p can be removed by wet etching or dry etching. It is particularly preferable to perform dry etching (also referred to as plasma ashing) using an oxygen gas as an etching gas to remove the resist mask 133 and the resist mask 133p.

At this time, the removal of the resist mask 133 is performed in the state where the sacrificial film 128f is provided over the functional film 156f; thus, damage to the functional film 156f, the active film 157f, and the functional film 155f can be reduced. This is particularly preferable in the case where etching using an oxygen gas such as plasma ashing is performed because electrical characteristics of the light-receiving device might be adversely affected when the active film 157f is exposed to oxygen.

Subsequently, the sacrificial film 128f in a region covered with neither the sacrificial layer 129 nor the sacrificial layer 129p is removed by etching using the sacrificial layer 129 and the sacrificial layer 129p as masks, whereby the sacrificial layer 128 is formed in a region overlapping with the electrode 111d, and the sacrificial layer 128p in contact with the top surface of the electrode 111p is formed.

Either wet etching or dry etching can be performed for the etching of the sacrificial film 128f; the use of a dry etching method is preferable because a reduction in areas of the sacrificial layer 128 and the sacrificial layer 128p can be inhibited.

### [Formation of Third Functional Layer 155, Active Layer 157, and Fourth Functional Layer 156]

Next, the sacrificial layer 129 and the sacrificial layer 129p are removed by etching, and the functional film 156f, the active film 157f, and the functional film 155f in a region covered with neither the sacrificial layer 128 nor the sacrificial layer 128p are removed by etching, whereby the fourth functional layer 156, the active layer 157, and the third functional layer 155 are formed (FIG. 18E).

When the functional film 156f, the active film 157f, and the functional film 155f are etched through the same process as that for the sacrificial layer 129, the processes can be simplified, the productivity can be increased, and the manufacturing cost can be reduced.

In particular, for etching of the functional film 156f, the active film 157f, and the functional film 155f, it is preferable to use dry etching using an etching gas that does not contain an oxygen (O₂) gas as its main component. In this case, a change in qualities of the functional film 156f, the active film 157f, and the functional film 155f can be inhibited, whereby a highly reliable display apparatus can be achieved. Examples of the etching gas that can be suitably used include CF₄, C₄F₈, SF₆, CHF₃, Cl₂, H₂O, BCl₃, H₂, and a noble gas such as He. Alternatively, a mixed gas of the above gas and a gas other than an oxygen gas can be used as the etching gas.

Note that etching of the functional film 156f, the active film 157f, and the functional film 155f may be separately performed from etching of the sacrificial layer 129. For example, the functional film 156f, the active film 157f, and the functional film 155f may be etched, and then the sacrificial layer 129 may be etched.

[Formation of Functional Film 115f]

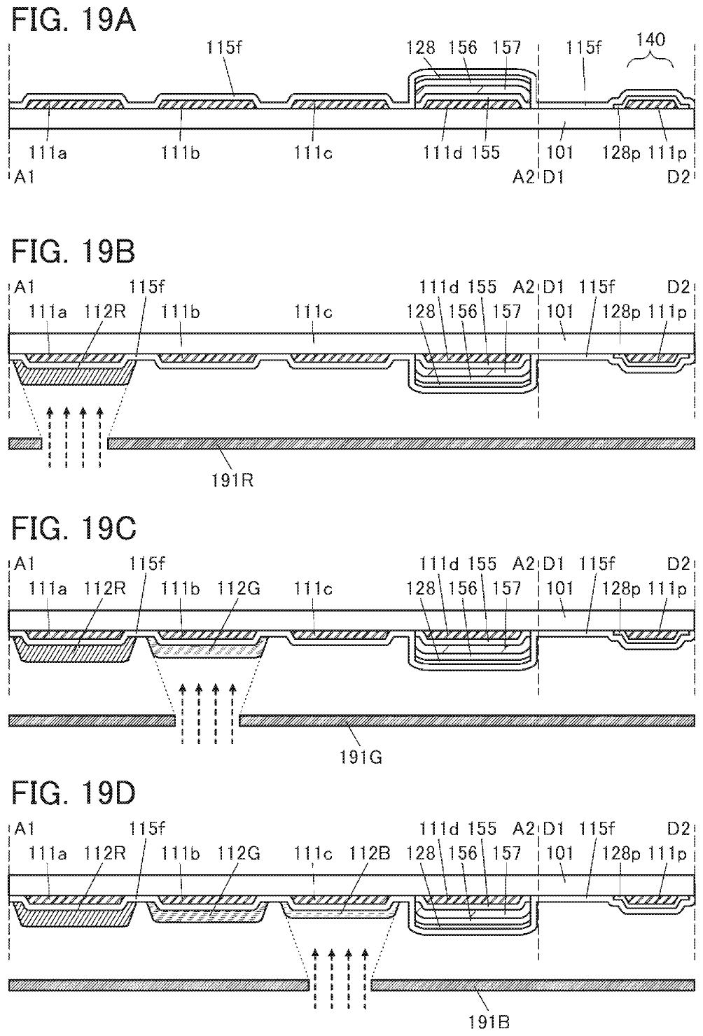

Next, a functional film 115f is deposited to cover the substrate 101, the electrode 111a, the electrode 111b, the electrode 111c, the third functional layer 155, the active layer 157, the fourth functional layer 156, the sacrificial layer 128, and the sacrificial layer 128p (FIG. 19A). The functional film 115f is to be the first functional layer 115a, the first functional layer 115b, and the first functional layer 115c later. The functional film 115f is preferably deposited without using an FMM.

For the deposition of the functional film 115f, a method usable for the above-described deposition of the functional film 155f, the active film 157f, and the functional film 156f can be used. Without limitation to this, the above-described deposition method can be used as appropriate.

### [Formation of Light-Emitting Layer 112R, Light-Emitting Layer 112G, and Light-Emitting Layer 112B]

Next, the light-emitting layer 112R having an island shape is formed over the functional film 115f in a region overlapping with the electrode 111a (FIG. 19B).

The light-emitting layer 112R is preferably formed by a vacuum evaporation method using an FMM. Note that a sputtering method using an FMM or an inkjet method may be used to form the light-emitting layer 112R having an island shape.

FIG. 19B illustrates a state in which the light-emitting layer 112R is formed through an FMM 191R. FIG. 19B illustrates a state of forming the light-emitting layer 112R by a so-called face-down method, in which deposition is performed with the substrate turned upside down so that the surface where the light-emitting layer 112R is formed faces downward.

In a vacuum evaporation method using a FMM, an area wider than an opening portion of the FMM is subjected to evaporation in many cases. As shown by dashed lines in FIG. 19B, the light-emitting layer 112R can be deposited in an area wider than the opening portion of the FMM 191R. In addition, the end portion of the light-emitting layer 112R is tapered.

In FIG. 19B, the FMM 191R is not in contact with the surface where the light-emitting layer 112R is formed; however, one embodiment of the present invention is not limited to this structure. The FMM 191R may be in contact with the surface where the light-emitting layer 112R is formed (here, the functional layer 115f). In that case, the FMM 191R is in contact with a region with the largest height from the substrate 101, where the light-receiving device 150 is to be formed, that is, a region overlapping with the electrode 111d. Such a region can have a function of holding the FMM 191R. Moreover, the region can have a function of a spacer for keeping a distance between the FMM 191R and the electrodes (the electrode 111a, the electrode 111b, and the electrode 111c). The same applies to the case of forming the light-emitting layer 112G and the light-emitting layer 112B.

Then, the light-emitting layer 112G is formed over the functional film 115f in a region overlapping with the electrode 111b with use of an FMM 191G (FIG. 19C). The end portion of the light-emitting layer 112G is tapered. The example of forming the light-emitting layer 112G shown in FIG. 19C is such that the light-emitting layer 112G does not have a region overlapping with the light-emitting layer 112R, that is, the light-emitting layer 112G is separated from the light-emitting layer 112R; however, one embodiment of the present invention is not limited to this structure. The light-emitting layer 112G may be formed so as to have a region overlapping with the light-emitting layer 112R, that is, so as to be in contact with the light-emitting layer 112R.

Subsequently, the light-emitting layer 112B is formed over the functional film 115f in a region overlapping with the electrode 111c with use of an FMM 191B (FIG. 19D). The end portion of the light-emitting layer 112B is tapered. The example of forming the light-emitting layer 112B is FIG. 19D is such that the light-emitting layer 112B does not have a region overlapping with the light-emitting layer 112G, that is, the light-emitting layer 112B is separated from the light-emitting layer 112G; however, one embodiment of the present invention is not limited to this structure. The light-emitting layer 112B may be formed so as to have a region overlapping with the light-emitting layer 112G, that is, so as to be in contact with the light-emitting layer 112G.

It is preferable that the light-emitting layer 112R, the light-emitting layer 112G, and the light-emitting layer 112B not be formed over the electrode 111p.

Although the light-emitting layer 112R, the light-emitting layer 112G, and the light-emitting layer 112B are formed in this order here, the formation order is not limited thereto.

[Formation of Functional Film 116f, Sacrificial Film 118f, and Sacrificial Film 119f]

Next, a functional film 116f is formed to cover the light-emitting layer 112R, the light-emitting layer 112G, the light-emitting layer 112B, and the functional film 115f. The functional film 116f is to be the second functional layer 116a, the second functional layer 116b, and the second functional layer 116c later. For the formation of the functional film 116f, a method usable for the above-described deposition of the functional film 155f, the active film 157f, and the functional film 156f can be used. Without limitation to this, the above-described deposition method can be used as appropriate.

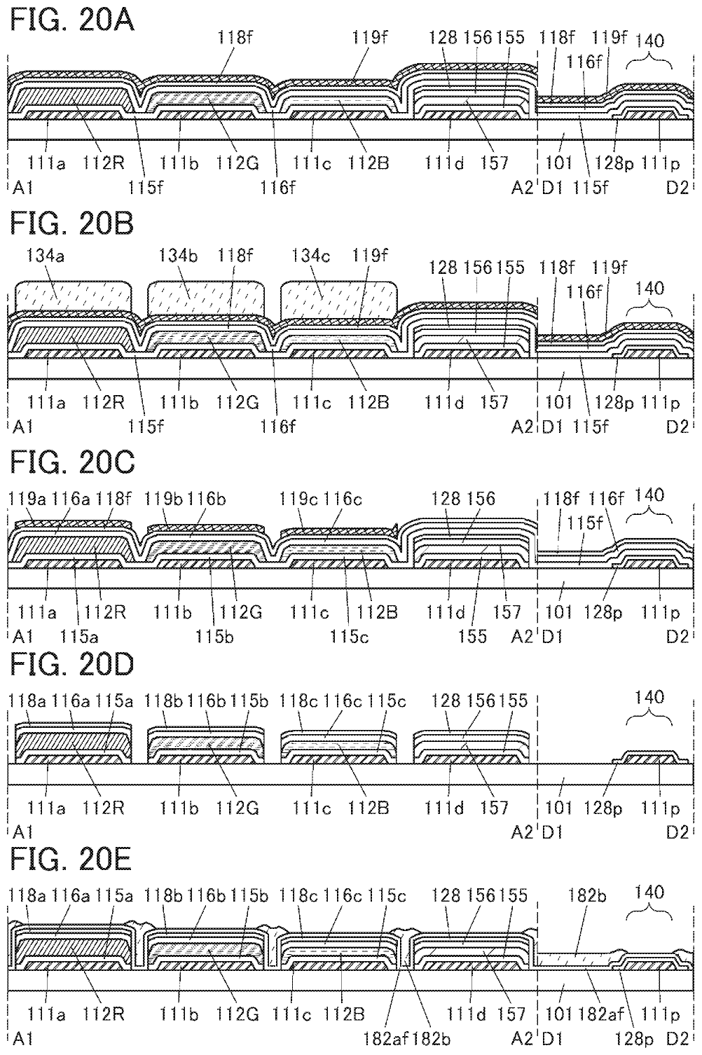

Then, a sacrificial film 118f and a sacrificial film 119f are formed in this order over the functional film 116f (FIG. 20A).

As the sacrificial film 118f, it is possible to favorably use a film highly resistant to etching treatment performed on the functional film 116f and the functional film 115f, i.e., a film having a high etching selectivity. Furthermore, as the sacrificial film 118f, it is possible to favorably use a film having high etching selectivity with respect to the sacrificial film 119f described later. Furthermore, as the sacrificial film 118f, it is particularly preferable to use a film that can be removed by a wet etching method that causes less damage to the functional film 156f and the functional film 155f.

For the sacrificial film 118f, it is possible to use a material usable for the sacrificial film 128f. In addition, for the formation of the sacrificial film 118f, it is possible to use a method usable for the formation of the sacrificial film 128f. Without limitation to this, the above-described deposition method can be used as appropriate.

For the sacrificial film 118f, the same material as the sacrificial film 128f is preferably used. Furthermore, it is preferable that the thickness of the sacrificial film 118f be approximately the same as the thickness of the sacrificial film 128f.

The sacrificial film 119f is used as a hard mask when the sacrificial film 118f is etched later. In a later process of processing the sacrificial film 119f, the sacrificial film 118f is exposed. Thus, the combination of films having high etching selectivity therebetween is selected for the sacrificial film 118f and the sacrificial film 119f. It is thus possible to select a film that can be used for the sacrificial film 119f depending on an etching condition of the sacrificial film 118f and an etching condition of the sacrificial film 119f.

For the sacrificial film 119f, it is possible to use a material usable for the sacrificial film 129f. In addition, for the formation of the sacrificial film 118f, it is possible to use a method usable for the formation of the sacrificial film 128f. Without limitation to this, the above-described deposition method can be used as appropriate. For the sacrificial film 119f, either the same material as the sacrificial film 129f or a different material may be used. The thickness of the sacrificial film 118f may be approximately the same as or different from the thickness of the sacrificial film 128f

For the etching of the sacrificial film 119f, the description of etching of the sacrificial film 129f can be referred to, and thus detailed description is omitted.

[Formation of Sacrificial Layers 119a to 119c and Sacrificial Layers 118a to 118c]

Next, a resist mask 134a, a resist mask 134b, and a resist mask 134c are formed over the sacrificial film 119f in a region overlapping with the electrode 111a, over the sacrificial film 119f in a region overlapping with the electrode 111b, and over the sacrificial film 119f in a region overlapping with the electrode 111c (FIG. 20B).

The resist mask 134a is made smaller than the light-emitting layer 112R. That is, the end portion of the resist mask 134a is positioned more inwardly than the end portion of the light-emitting layer 112R. Similarly, the resist mask 134b is made smaller than the light-emitting layer 112G. That is, the end portion of the resist mask 134b is positioned more inwardly than the end portion of the light-emitting layer 112G. The resist mask 134c is made smaller than the light-emitting layer 112B. That is, the end portion of the resist mask 134c is positioned more inwardly than the end portion of the light-emitting layer 112B.

For the resist mask 134a, the resist mask 134b, and the resist mask 134c, the description of the resist mask 133 can be referred to, and thus detailed description thereof is omitted.

In the case of manufacturing the display apparatus illustrated in FIG. 7A, the resist mask 134a is made lager than the light-emitting layer 112R. That is, the end portion of the resist mask 134a is positioned more outwardly than the end portion of the light-emitting layer 112R. Similarly, the resist mask 134b is made larger than the light-emitting layer 112G. That is, the end portion of the resist mask 134b is positioned more outwardly than the end portion of the light-emitting layer 112G. The resist mask 134c is made larger than the light-emitting layer 112B. That is, the end portion of the resist mask 134c is positioned more outwardly than the end portion of the light-emitting layer 112B.

Here, in the case where the sacrificial film 119f is not formed and the resist mask 134a, the resist mask 134b, and the resist mask 134c are formed over the sacrificial film 118f, when a defect such as a pinhole exists in the sacrificial film 118f, there is a risk of dissolving the functional film 116f and the like due to a solvent of the resist material. Such a defect can be prevented by using the sacrificial film 119f.

Note that in the case where a film that is unlikely to cause a defect such as a pinhole is used as the sacrificial film 118f, the resist mask 134a, the resist mask 134b, and the resist mask 134c may be formed directly on the sacrificial film 118f without using the sacrificial film 119f.

Next, the sacrificial film 119f in a region covered with none of the resist mask 134a, the resist mask 134b, and the resist mask 134c is removed by etching to form a sacrificial layer 119a, a sacrificial layer 119b, and a sacrificial layer 119c.

In the etching of the sacrificial film 119f, an etching condition with high selectivity is preferably employed so that the sacrificial film 118f is not removed by the etching. Either wet etching or dry etching can be performed for the etching of the sacrificial film 119f; with use of dry etching, a reduction in areas of the sacrificial layer 119a, the sacrificial layer 119b, and the sacrificial layer 119c can be inhibited.

Subsequently, the resist mask 134a, the resist mask 134b, and the resist mask 134c are removed (see FIG. 20C).

The same method as that for the removal of the resist mask 133 can be used for the removal of the resist mask 134a, the resist mask 134b, and the resist mask 134c.

At this time, since the removal of the resist mask 134a, the resist mask 134b, and the resist mask 134c is performed in the state where the sacrificial film 118f is provided over the functional film 116f; thus, damage to the functional film 156f, the light-emitting layer 112R, the light-emitting layer 112G, the light-emitting layer 112B, and the functional film 155f can be reduced. This is particularly preferable in the case where etching using an oxygen gas such as plasma ashing is performed because electrical characteristics of the light-emitting devices might be adversely affected when the light-emitting layer 112R, the light-emitting layer 112G, and the light-emitting layer 112B are exposed to oxygen.

Then, the sacrificial film 118f in a region covered with none of the sacrificial layer 119a, the sacrificial layer 119b, and the sacrificial layer 119c is removed by etching using the sacrificial layer 119a, the sacrificial layer 119b, and the sacrificial layer 119c as masks, whereby a sacrificial layer 118a, a sacrificial layer 118b, and a sacrificial layer 118c are formed.

For the etching of the sacrificial film 118f, the description of etching of the sacrificial film 128f can be referred to, and thus detailed description is omitted.

[Formation of First Functional Layers 115a to 115c and Second Functional Layers 116a to 116c]

Next, the sacrificial layer 119a, the sacrificial layer 119b, and the sacrificial layer 119c are removed by etching, and the functional film 116f and the functional film 115f in a region covered with none of the sacrificial layer 118a, the sacrificial layer 118b, and the sacrificial layer 118c are removed by etching, whereby the second functional layer 116a, the second functional layer 116b, the second functional layer 116c, the first functional layer 115a, the first functional layer 115b, and the first functional layer 115c are formed (FIG. 20D).

When the functional film 116f and the functional film 115f are etched through the same process as that for the sacrificial layer 119a, the sacrificial layer 119b, and the sacrificial layer 119c, the processes can be simplified, the productivity can be increased, and the manufacturing cost can be reduced.

In particular, for etching of the functional film 116f and the functional film 115f, it is preferable to use dry etching using an etching gas that does not contain oxygen as its main component. In this case, a change in qualities of the functional film 156f and the functional film 155f can be inhibited, whereby a highly reliable display apparatus can be achieved.

Note that etching of the functional film 116f and the functional film 115f may be separately performed from etching of the sacrificial layer 119a, the sacrificial layer 119b, and the sacrificial layer 119c. For example, the functional film 116f and the functional film 115f may be etched, and then the sacrificial layer 119a, the sacrificial layer 119b, and the sacrificial layer 119c may be etched.

[Formation of Insulating Film 182af and Insulating Layer 182b]

Next, an insulating film 182af is deposited to cover the sacrificial layer 118a, the sacrificial layer 118b, the sacrificial layer 118c, the sacrificial layer 128, the sacrificial layer 128p, and the substrate 101.

The insulating film 182af functions as a barrier layer that prevents diffusion of impurities into the EL layers and the light-receiving layer. Examples of the impurities include water. The insulating film 182af is preferably formed by an ALD method providing excellent step coverage because the insulating film 182af can favorably cover the side surfaces of the EL layers and the side surface of the light-receiving layer.

The same film as the sacrificial layer 118 is preferably used for the insulating film 182af because they can be etched at the same time in a later process. For example, an inorganic insulating material such as aluminum oxide, hafnium oxide, or silicon oxide formed by an ALD method is preferably used for the insulating film 182af and the sacrificial layer 118.

The material that can be used for the insulating film 182af is not limited to the above, and a material usable for the sacrificial layer 128 can be used as appropriate.

Next, the insulating layer 182b is formed between two adjacent light-emitting devices and between a light-emitting device and a light-receiving device that are adjacent to each other (FIG. 20E). FIG. 20E illustrates an example in which the insulating layer 182b is formed to have a width larger than the width of the space between the devices.

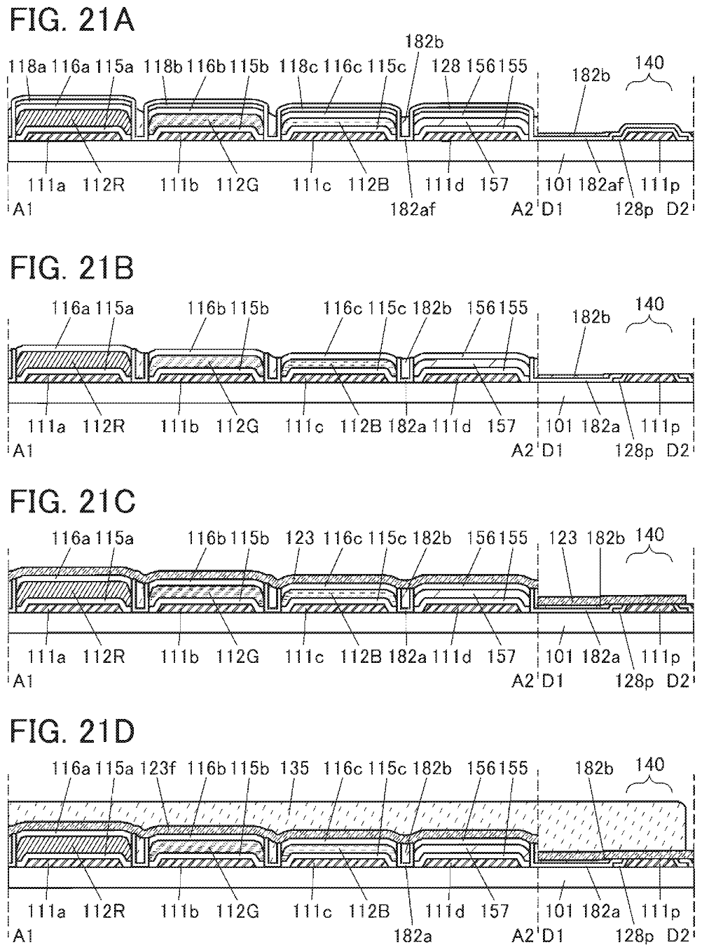

A photosensitive resin is preferably used for the insulating layer 182b. In this case, after a resin film is first deposited, the resin film is exposed to light through a photomask and then subjected to development treatment, whereby the insulating layer 182b can be formed. After that, an upper portion of the insulating layer 182b may be removed by ashing or the like, whereby the level of the top surface of the insulating layer 182b may be adjusted (FIG. 21A).

In the case where a nonphotosensitive resin is used for the insulating layer 182b, after a resin film is deposited, an upper portion of the resin film is removed by ashing until the film has an optimal thickness and the surfaces of the sacrificial layer 118 and the sacrificial layer 128 are exposed, whereby the insulating layer 182b can be formed.

### [Etching of Insulating Film 182af, Sacrificial Layer 118, and Sacrificial Layer 128]

Next, the insulating film 182af, the sacrificial layer 118a, the sacrificial layer 118b, the sacrificial layer 118c, the sacrificial layer 128, and the sacrificial layer 128p in a region not covered with the insulating layer 182b are removed by etching to expose the top surface of the second functional layer 116, the top surface of the fourth functional layer 156, and the top surface of the electrode 111p. In addition, the insulating layer 182a is formed in a region covered with the insulating layer 182b (FIG. 21B). At this time, an upper portion of the insulating layer 182b is removed and the level of the top surface of the insulating layer 182b is lowered in some cases.

It is preferable that the insulating film 182af, the sacrificial layer 118a, the sacrificial layer 118b, the sacrificial layer 118c, the sacrificial layer 128, and the sacrificial layer 128p be etched through the same process. In particular, wet etching that causes less etching damage to the second functional layer 116a, the second functional layer 116b, the second functional layer 116c, and the fourth functional layer 156 can be preferably used for the etching of the sacrificial layer 118a, the sacrificial layer 118b, the sacrificial layer 118c, the sacrificial layer 128, and the sacrificial layer 128p. For example, wet etching using a tetramethyl ammonium hydroxide (TMAH) aqueous solution, diluted hydrofluoric acid, oxalic acid, phosphoric acid, acetic acid, nitric acid, or a mixed solution of any of these acids is preferably performed.

Alternatively, one or both of the insulating film 182af and the sacrificial layer 118 are preferably removed by being dissolved in a solvent such as water or alcohol. For the alcohol in which the insulating film 182af and the sacrificial layer 118 can be dissolved, any of various alcohols such as ethyl alcohol, methyl alcohol, isopropyl alcohol (IPA), and glycerin can be used.

In order that the sacrificial layers 118a to 118c be removed at the same time as the sacrificial layer 128 and the sacrificial layer 128p, it is preferable that etching times required for removing them be substantially the same as one another. For example, the same material is preferably used for the sacrificial layers 118a to 118c, the sacrificial layer 128, and the sacrificial layer 128p. Furthermore, the sacrificial layers 118a to 118c preferably have substantially the same thicknesses as the sacrificial layer 128 and the sacrificial layer 128p.

After the sacrificial layer 118a, the sacrificial layer 118b, the sacrificial layer 118c, the sacrificial layer 128, and the sacrificial layer 128p are removed, drying treatment is preferably performed in order to remove water contained in the light-emitting layer 112, the active layer 157, the first functional layer 115, the second functional layer 116, the third functional layer 155, the fourth functional layer 156, and the electrode 111p and water adsorbed on their surfaces. For example, heat treatment is preferably performed in an inert gas atmosphere or a reduced-pressure atmosphere. The heat treatment can be performed with a substrate temperature higher than or equal to 50° C. and lower than or equal to 200° C., preferably higher than or equal to 60° C. and lower than or equal to 150° C., or further preferably higher than or equal to 70° C. and lower than or equal to 120° C. Employing a reduced-pressure atmosphere is preferable, in which case drying at a lower temperature is possible.

### [Formation of Common Electrode 123]

Next, the common electrode 123 is formed to cover the second functional layer 116a, the second functional layer 116b, the second functional layer 116c, the fourth functional layer 156, and the electrode 111p (FIG. 21C). The common electrode 123 is electrically connected to the electrode 111p in the connection portion 140.

The common electrode 123 can be formed by an evaporation method or a sputtering method. Alternatively, the common electrode 123 may be formed by stacking a film formed by an evaporation method and a film formed by a sputtering method. The common electrode 123 is preferably formed using a shielding mask. It is preferable that the shielding mask be provided such that the common electrode 123 is not exposed at the end portion of the display apparatus 100, that is, the end portion of the common electrode 123 is located more inwardly than the end portion of the display apparatus 100.

Note that the shielding mask is not necessarily used at the time of deposition of the common electrode 123. As illustrated in FIG. 21D, a conductive layer 123f to be the common electrode 123 is formed. Then, a resist mask 135 is formed over the conductive layer 123f, and the conductive layer 123f is processed, whereby the common electrode 123 can be formed. In this case, it is preferable that the processing be performed such that the common electrode 123 is not exposed at the end portion of the display apparatus, that is, the end portion of the common electrode 123 is positioned more inwardly than the end portion of the display apparatus.

### [Formation of Protective Layer 125]

Next, the protective layer 125 is formed over the common electrode 123. An inorganic insulating film used for the protective layer 125 is preferably deposited by a sputtering method, a PECVD method, or an ALD method. In particular, an ALD method is preferable because it provides excellent step coverage and is less likely to cause a defect such as a pinhole. In addition, an organic insulating film is preferably deposited by an inkjet method because a uniform film can be formed in a desired region.

Through the above-described processes, the display apparatus illustrated in FIG. 6A can be manufactured.

In the display apparatus of one embodiment of the present invention, the light-emitting layer of the light-emitting device can be used using an FMM and the active layer of the light-receiving device can be formed without using an FMM. With such a structure, a display apparatus having a light detection function with high accuracy can be provided.

### Manufacturing Method Example 2

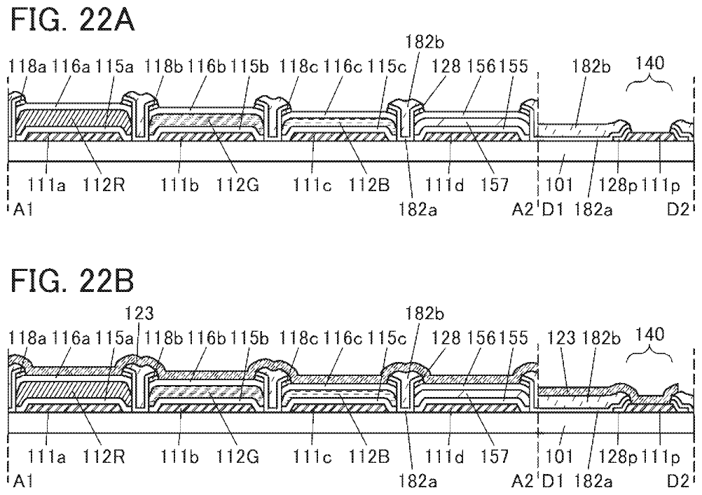

A method for manufacturing a display apparatus illustrated in FIG. 11A is described. FIG. 22A and FIG. 22B are schematic cross-sectional views in processes of the method for manufacturing the display apparatus. Note that description of the same portions as the manufacturing method example 1 described above is omitted and different portions are described.

First, as in Manufacturing method example 1, the steps up to the formation of the insulating layer 182b are performed (FIG. 20E).

### [Etching of Insulating Film 182af, Sacrificial Layer 118, and Sacrificial Layer 128]

Next, the insulating film 182af, the sacrificial layer 118a, the sacrificial layer 118b, the sacrificial layer 118c, the sacrificial layer 128, and the sacrificial layer 128p in a region not covered with the insulating layer 182b are removed by etching to expose the top surface of the second functional layer 116, the top surface of the fourth functional layer 156, and the top surface of the electrode 111p. In addition, the insulating layer 182a is formed in a region covered with the insulating layer 182b (FIG. 22A).

At this step, the sacrificial layer 118a may be left between the insulating layer 182a and the second functional layer 116a. Similarly, the sacrificial layer 118b may be left between the insulating layer 182a and the second functional layer 116b. The sacrificial layer 118c may be left between the insulating layer 182a and the second functional layer 116c. The sacrificial layer 128 may be left between the insulating layer 182a and the fourth functional layer 156. For the etching of insulating film 182af, the sacrificial layer 118, and the sacrificial layer 128, the above description can be referred to, and thus detailed description is omitted.

After the sacrificial layer 118a, the sacrificial layer 118b, the sacrificial layer 118c, the sacrificial layer 128, and the sacrificial layer 128p are removed, drying treatment is preferably performed in order to remove water contained in the light-emitting layer 112, the active layer 157, the first functional layer 115, the second functional layer 116, the third functional layer 155, and the fourth functional layer 156, and the electrode 111p and water adsorbed on their surfaces. The above description can be referred to for the drying treatment; thus, the detailed description thereof is omitted.

### [Formation of Common Electrode 123]

Next, the common electrode 123 is formed to cover the insulating layer 182a, the insulating layer 182b, the second functional layer 116, the fourth functional layer 156, and the electrode 111p (FIG. 22B). Since the above description can be referred to for formation of the common electrode 123, the detailed description thereof is omitted.

### [Formation of Protective Layer 125]

Next, the protective layer 125 is formed over the common electrode 123. The above description can be referred to for the formation of the protective layer 125; thus, the detailed description thereof is omitted.

Through the above-described processes, the display apparatus illustrated in FIG. 11A can be manufactured.

### Manufacturing Method Example 3

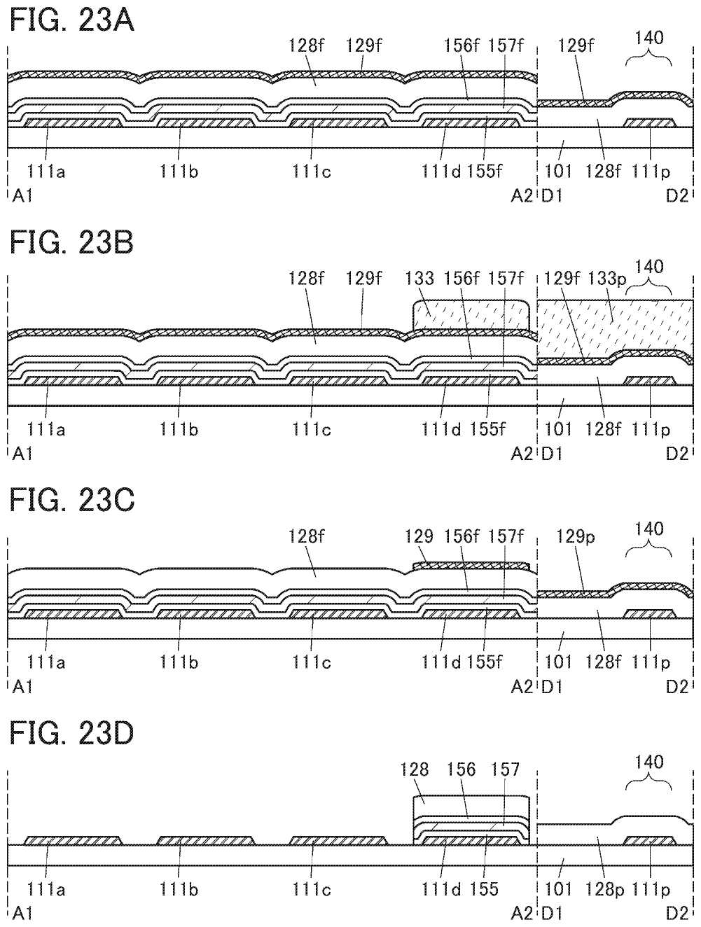

A method for manufacturing a display apparatus illustrated in FIG. 16A is described. FIG. 23A to FIG. 25E are schematic cross-sectional views in processes of the method for manufacturing the display apparatus. Note that description of the same portions as the manufacturing method example 1 described above is omitted and different portions are described.

The electrode 111a, the electrode 111b, the electrode 111c, the electrode 111d, and the electrode 111p are formed over the substrate 101 in a manner similar to Manufacturing method example 1 (FIG. 18A).

[Formation of Functional Film 155f, Active Film 157f, and Functional Film 156f]

Next, a functional film 155f to be the third functional layer 155 later, an active film 157f to be the active layer 157, and a functional film 156f to be the fourth functional layer 156 are deposited in this order over the electrode 111a, the electrode 111b, the electrode 111c, the electrode 111d, the electrode 111p and the substrate 101. For the formation of the functional film 155f, the active film 157f, and the functional film 156f, the above description can be referred to, and thus detailed description is omitted.

[Formation of Sacrificial Film 128f and Sacrificial Film 129f]

Next, the sacrificial film 128f and the sacrificial film 129f are formed in this order over the functional film 156f (FIG. 23A).

The thickness of the sacrificial film 128f is preferably greater than or equal to 10 nm and less than or equal to 3 μm, further preferably greater than or equal to 10 nm and less than or equal to 2 μm, still further preferably greater than or equal to 10 nm and less than or equal to 1 μm, yet still further preferably greater than or equal to 20 nm and less than or equal to 1 μm, yet still further preferably greater than or equal to 20 nm and less than or equal to 500 nm, yet still further preferably greater than or equal to 30 nm and less than or equal to 500 nm, yet still further preferably greater than or equal to 30 nm and less than or equal to 400 nm, yet still further preferably greater than or equal to 40 nm and less than or equal to 400 nm, yet still further preferably greater than or equal to 40 nm and less than or equal to 300 nm, yet still further preferably greater than or equal to 50 nm and less than or equal to 300 nm, yet still further preferably greater than or equal to 50 nm and less than or equal to 200 nm, and yet still further preferably greater than or equal to 50 nm and less than or equal to 100 nm. Furthermore, the thickness of the sacrificial film 128f is preferably larger than the thickness of the first functional layer 115.

For the sacrificial film 129f, the above description can be referred to, and thus the detailed description thereof is omitted.

### [Formation of Sacrificial Layer 129 and Sacrificial Layer 128]

Next, the resist mask 133 and a resist mask 133p are formed over the sacrificial film 129f in a region overlapping with the electrode 111d and over the sacrificial film 129f in a region overlapping with the connection portion 140 (FIG. 23B).

Next, the sacrificial film 129f in a region covered with neither the resist mask 133 nor the resist mask 133p is removed by etching to form the sacrificial layer 129 and a sacrificial layer 129p.

Then, the resist mask 133 is removed (FIG. 23C).

Subsequently, the sacrificial film 128f in a region covered with neither the sacrificial layer 129 nor the sacrificial layer 129p is removed by etching using the sacrificial layer 129 and the sacrificial layer 129p as masks, whereby the sacrificial layer 128 is formed in a region overlapping with the electrode 111d, and the sacrificial layer 128p in contact with the top surface of the electrode 111p is formed.

### [Formation of Third Functional Layer 155, Active Layer 157, and Fourth Functional Layer 156]

Next, the sacrificial layer 129 and the sacrificial layer 129p are removed by etching, and the functional film 156f, the active film 157f, and the functional film 155f in a region covered with neither the sacrificial layer 128 nor the sacrificial layer 128p are removed by etching, whereby the fourth functional layer 156, the active layer 157, and the third functional layer 155 are formed (FIG. 23D).

When the functional film 156f, the active film 157f, and the functional film 155f are etched through the same process as that for the sacrificial layer 129 and the sacrificial layer 129p, the processes can be simplified, the productivity can be increased, and the manufacturing cost can be reduced.

In particular, for the etching of the functional film 156f, the active film 157f, and the functional film 155f, the above description can be referred to, and thus detailed description is omitted.

### [Formation of First Functional Layer 115]

Next, the first functional layer 115, a first functional layer 115d, and a first functional layer 115p are formed to cover the substrate 101, the electrode 111a, the electrode 111b, the electrode 111c, the electrode 111p, the third functional layer 155, the active layer 157, the fourth functional layer 156, the sacrificial layer 128, and the sacrificial layer 128p.

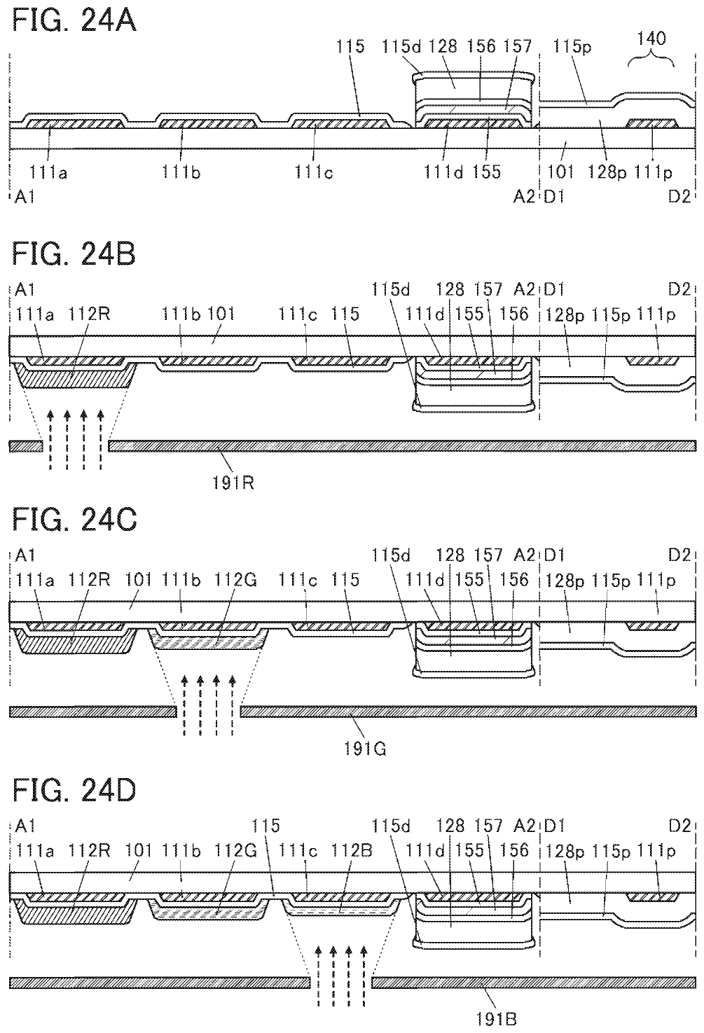

Here, a region where a first functional film is not deposited is formed between a region where the sacrificial layer 128 or the sacrificial layer 128p is provided and a region where neither the sacrificial layer 128 nor sacrificial layer 128p is provided. In other words, the first functional film is divided between the region where the sacrificial layer 128 or the sacrificial layer 128p is provided and the region where the sacrificial layer 128 or the sacrificial layer 128p is not provided. FIG. 24A illustrates, as the divided first functional films, the first functional layer 115d deposited over the sacrificial layer 128, the first functional layer 115p deposited over the sacrificial layer 128p, and the first functional layer 115 deposited in the region where neither the sacrificial layer 128 nor the sacrificial layer 128p is provided. Note that the first functional layer 115 is provided in contact with the top surfaces of the electrode 111a, the electrode 111b, and the electrode 111c.

The thickness of the sacrificial film 128f to be the sacrificial layer 128 or the sacrificial layer 128p is preferably within the above range. A small thickness of the sacrificial film 128f prevents the first functional layer 115, the first functional layer 115d, and the first functional layer 115p from being provided separately, in some cases. When the thickness of the sacrificial film 128f is large, the sacrificial film 128f is difficult to process in some cases. The thickness of the sacrificial film 128f falls within the above range, whereby the first functional layer 115, the first functional layer 115d, and the first functional layer 115p can be divided and processing of the sacrificial film 128f can be facilitated.

### [Formation of Light-Emitting Layer 112R, Light-Emitting Layer 112G, and Light-Emitting Layer 112B]

Next, the light-emitting layer 112R having an island shape is formed over the first functional layer 115 in a region overlapping with the electrode 111a (FIG. 24B). For formation of the light-emitting layer 112R, the FMM 191R is preferably used.

Then, the light-emitting layer 112G is formed over the first functional layer 115 in a region overlapping with the electrode 111b with use of an FMM 191G (FIG. 24C).

Subsequently, the light-emitting layer 112B is formed over the first functional layer 115 in a region overlapping with the electrode 111c with use of the FMM 191B (FIG. 24D).

For the formation of the light-emitting layer 112R, the light-emitting layer 112G, and the light-emitting layer 112B, the above description can be referred to, and thus detailed description is omitted.

Note that the formation order of the light-emitting layer 112R, the light-emitting layer 112G, and the light-emitting layer 112B is not particularly limited.

### [Formation of Second Functional Layer 116]

Next, the second functional layer 116, a second functional layer 116d, and a second functional layer 116p are formed to cover the light-emitting layer 112R, the light-emitting layer 112G, the light-emitting layer 112B, the first layer 115, the first functional layer 115d, and the first functional layer 115p.

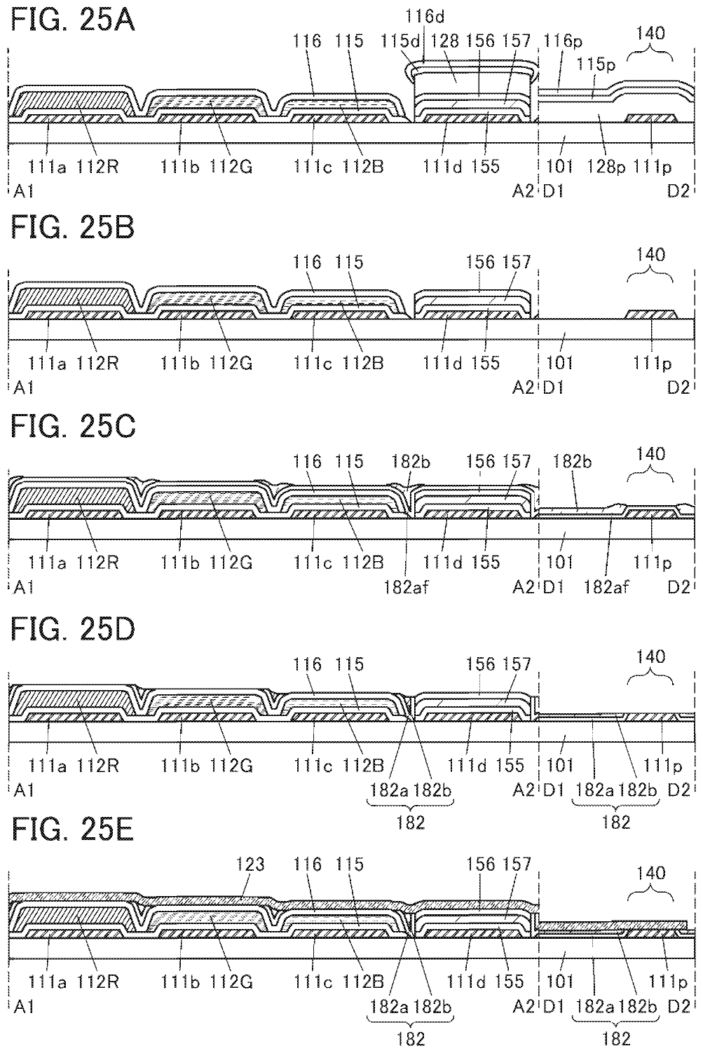

Here, a region where a second functional film is not deposited is formed between a region where the sacrificial layer 128 or the sacrificial layer 128p is provided and a region where neither the sacrificial layer 128 nor sacrificial layer 128p is provided. In other words, the second functional film is divided (also referred to as disconnected) between the region where the sacrificial layer 128 or the sacrificial layer 128p is provided and the region where the sacrificial layer 128 or the sacrificial layer 128p is not provided. FIG. 25A illustrates, as the divided second functional layers, the second functional layer 116d over the sacrificial layer 128, the second functional layer 116p deposited over the sacrificial layer 128p, and the second functional layer 116 deposited in the region where neither the sacrificial layer 128 nor the sacrificial layer 128p is provided. Note that the second functional layer 116d is provided in contact with the first functional layer 115d. The second functional layer 116p is provided in contact with the first functional layer 115p. The second functional layer 116 is provided in contact with the first functional layer 115. At this time, the end portion of the second functional layer 116 may be positioned more inwardly than the end portion of the first functional layer 115.

The thickness of the sacrificial film 128f to be the sacrificial layer 128 or the sacrificial layer 128p is preferably within the above range. A small thickness of the sacrificial film 128f prevents the second functional layer 116, the second functional layer 116d, and the second functional layer 116p from being provided separately, in some cases. The thickness of the sacrificial film 128f falls within the above range, whereby the second functional layer 116, the second functional layer 116d, and the second functional layer 116p can be separately provided.

[Removal of Sacrificial Layer 128 and Sacrificial Layer 128p]

Next, the sacrificial layer 128 and the sacrificial layer 128p are removed. In this step, the first functional layer 115d and the second functional layer 116d over the sacrificial layer 128 and the first functional layer 115p and the second functional layer 116p over the sacrificial layer 128p are also removed, so that the top surface of the fourth functional layer 156 and the top surface of the electrode 111p are exposed (FIG. 25B).

It is preferable that a method that causes as less damage to the first functional layer 115, the second functional layer 116, the third functional layer 155, the active layer 157, the fourth functional layer 156, and the electrode 111p as possible be used for the removal of the sacrificial layer 128 and the sacrificial layer 128p. Wet etching can be preferably used for the removal of the sacrificial layer 128 and the sacrificial layer 128p. When the sacrificial layer 128 is dissolved, both the first functional layer 115d and the second functional layer 116d over the sacrificial layer 128 are removed (also referred to as lifted off). Similarly, when the sacrificial layer 128p is dissolved, both the first functional layer 115p and the second functional layer 116p over the sacrificial layer 128p are removed (lifted off). The use of the lifting off makes it possible to remove the first functional layer 115d, the second functional layer 116d, the first functional layer 115p, and the second functional layer 116p without causing damage to the first functional layer 115 and the second functional layer 116.

After the sacrificial layer 128 and the sacrificial layer 128p are removed, drying treatment is preferably performed in order to remove water contained in the light-emitting layer 112, the active layer 157, the first functional layer 115, the second functional layer 116, the third functional layer 155, the fourth functional layer 156, and the electrode 111p and water adsorbed on their surfaces.

[Formation of Insulating Film 182af and Insulating Layer 182b]

Next, an insulating film 182af is formed to cover the second functional layer 116, the fourth functional layer 156, the electrode 111p, and the substrate 101. The above description can be referred to for the formation of the insulating film 182af; thus, the detailed description thereof is omitted.

Next, the insulating layer 182b is formed between two adjacent light-emitting devices and between a light-emitting device and a light-receiving device that are adjacent to each other (FIG. 25C). The above description can be referred to for the formation of the insulating layer 182b; thus, the detailed description thereof is omitted.

[Etching of Insulating Film 182af]

Next, the insulating film 182af in a region not covered with the insulating layer 182b is removed by etching, whereby the top surface of the second functional layer 116, the top surface of the fourth functional layer 156, and the top surface of the electrode 111p are exposed. In addition, the insulating layer 182a is formed in a region covered with the insulating layer 182b (FIG. 25D). For etching of the insulating film 182af, the above description can be referred to, and thus the detailed description thereof is omitted.

### [Formation of Common Electrode 123]

Next, the common electrode 123 is formed to cover the second functional layer 116, the fourth functional layer 156, and the electrode 111p (FIG. 25E). The common electrode 123 is electrically connected to the connection electrode 111p in the connection portion 140.

### [Formation of Protective Layer 125]

Next, the protective layer 125 is formed over the common electrode 123.

Through the above-described processes, the display apparatus illustrated in FIG. 16A can be manufactured.

The above is the description of the examples of the method for manufacturing a display apparatus.

As described above, it is possible to separately form the light-emitting devices and the light-receiving device over the same substrate by the method for manufacturing a display apparatus of one embodiment of the present invention. Furthermore, it is possible to obtain the structure in which the light-emitting devices and the light-receiving layer have no common component other than a common electrode. This can increase the SN ratio of the light-receiving device, whereby the display apparatus can have the light-receiving device with high accuracy. Furthermore, the display apparatus can have low power consumption.

### <Pixel Layout>

Pixel layouts are described below. There is no particular limitation on the arrangement of subpixels, and a variety of methods can be employed. Examples of the arrangement of subpixels include stripe arrangement, S stripe arrangement, matrix arrangement, delta arrangement, Bayer arrangement, and PenTile arrangement.

Examples of a top surface shape of the subpixel include polygons such as a triangle, a quadrangle (including a rectangle and a square), and a pentagon; polygons with rounded corners; an ellipse; and a circle. Here, the top surface shape of the subpixel corresponds to the top surface shape of a light-emitting region of a light-emitting device or a light-receiving region of a light-receiving device.

In the display apparatus 100A illustrated in FIG. 4A, one pixel 103 is composed of two rows and three columns. The pixel 103 includes three subpixels (the subpixels 120R, 120G, and 120B) in the upper row (first row) and one subpixel (the subpixel 130) in the lower row (second row). In other words, the pixel 103 includes the subpixel 120R in the left column (first column), the subpixel 120G in the center column (second column), the subpixel 120B in the right column (third column), and the subpixel 130 across these three columns.

In this embodiment and the like, for clear explanation of the pixel layout, the horizontal direction (X direction) in the drawing is the row direction and the vertical direction (Y direction) is the column direction; however, one embodiment of the present invention is not limited thereto and the row direction and the column direction can be replaced with each other. Thus, in this specification and the like, one of the row direction and the column direction is referred to as a first direction and the other of the row direction and the column direction is referred to as a second direction, in some cases. The second direction is orthogonal to the first direction. Note that in the case where the top surface shape of the display portion is a rectangular shape, each of the first direction and the second direction is not necessarily parallel to a straight line portion of the outline of the display portion. The top surface shape of the display portion is not limited to a rectangular shape, and may be a polygonal shape or a shape with curve (e.g., circle or ellipse). The first direction and the second direction may be a given direction with respect to the display portion.

In this specification and the like, for clear explanation of pixel layout, the subpixels are illustrated in the order from the left of a diagram; however, without limitation thereto, the order can be changed into the order from the right. Similarly, the subpixels are illustrated in the order from the top of a diagram; however, without limitation thereto, the order can be changed into the order from the bottom.

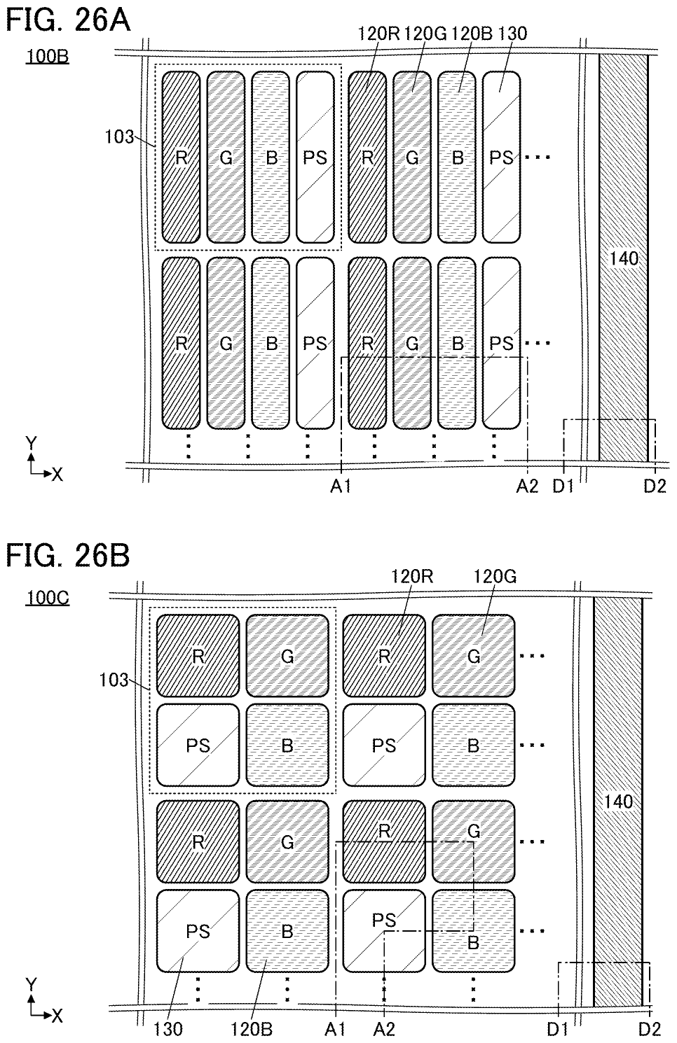

FIG. 26A and FIG. 26B each illustrate pixel arrangement different from FIG. 4A.

In a display apparatus 100B illustrated in FIG. 26A, the pixel 103 employs stripe arrangement. The pixel 103 includes the subpixel 120R, the subpixel 120G, the subpixel 120B, and the subpixel 130 in the row direction.

In a display apparatus 100C illustrated in FIG. 26B, the pixel 103 employs matrix arrangement. The pixel 103 is composed of two rows and two columns and includes two subpixels (the subpixels 120R and 120G) in the upper row (first row) and two subpixels (the subpixels 120B and 130) in the lower row (second row). In other words, the pixel 103 includes two subpixels (the subpixels 120R and 130) in the left column (the first column) and two subpixels (the subpixels 120G and 120B) in the right column (the second column).

Note that there is no particular limitation on the positions of the subpixels. For example, the positions of the subpixel 120R and the subpixel 130 may be interchanged.

The areas of the light-emitting regions of the light-emitting devices included in the subpixels may be the same as or different from one another. For example, the area of the light-emitting region can be determined depending on the lifetime of the light-emitting device. The area of the light-emitting region of the light-emitting device with a short lifetime is preferably made larger than the area of the light-emitting region of the other light-emitting devices. An increase in area of the light-emitting region lowers current density applied to the light-emitting device, whereby the lifetime of the light-emitting device can be longer. That is, the display apparatus can have high reliability.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 2

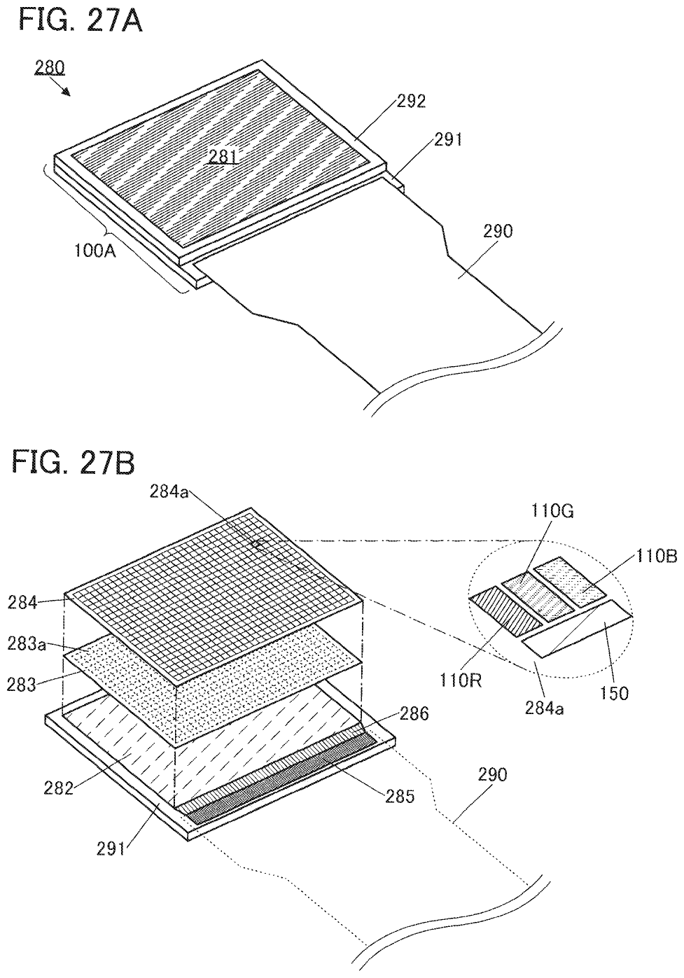

In this embodiment, display apparatuses of one embodiment of the present invention will be described with reference to FIG. 27 to FIG. 36.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display and a glasses-type AR device.

The display apparatus of this embodiment can be a high-definition display apparatus or large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### <Display Module>

FIG. 27A is a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed and is a region where light from pixels provided in a pixel portion 284 described later can be perceived.

FIG. 27B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged in a matrix. An enlarged view of one pixel 284a is illustrated on the right side of FIG. 27B. The pixel 284a includes the light-emitting device 110R that emits red light, the light-emitting device 110G that emits green light, the light-emitting device 110B that emits blue light, and the light-receiving device 150.

The pixel circuit portion 283 includes a plurality of pixel circuits 283a arranged in a matrix.

One pixel circuit 283a is a circuit that controls driving of a plurality of elements included in one pixel 284a. One pixel circuit 283a may be provided with five circuits each of which controls driving of an element. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. With such a structure, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, power supply potential, or the like to the circuit portion 282 from the outside. In addition, an IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high definition, and thus can be suitably used for a device for VR such as a head-mounted display or a glasses-type device for AR. For example, even in the case of a structure in which the display portion of the display module 280 is perceived through a lens, pixels of the extremely-high-resolution display portion 281 included in the display module 280 are not perceived when the display portion is enlarged by the lens, so that display providing a high sense of immersion can be performed. Without limitation to the above, the display module 280 can also be suitably used for an electronic device having a relatively small display portion. For example, the display module 280 can be suitably used for a display portion of a wearable electronic device such as a wrist watch.

### <Display Apparatus 100A>

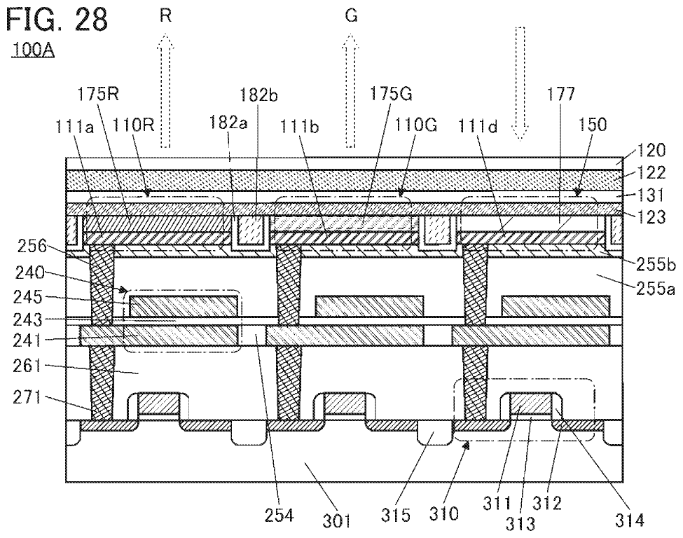

The display apparatus 100A illustrated in FIG. 28 includes a substrate 301, the light-emitting device 110R, the light-emitting device 110G, the light-receiving device 150, a capacitor 240, and a transistor 310.

The substrate 301 corresponds to the substrate 291 in FIG. 27A and FIG. 27B. A stacked-layer structure including the substrate 301 and the components thereover up to an insulating layer 255b corresponds to the substrate 101 in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, and the insulating layer 255b is provided over the insulating layer 255a.

As each of the insulating layer 255a and the insulating layer 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferred that a silicon oxide film be used as the insulating layer 255a and a silicon nitride film be used as the insulating layer 255b. The insulating layer 255b preferably has a function of an etching protective film. Alternatively, a nitride insulating film or a nitride oxide insulating film may be used as the insulating layer 255a, and an oxide insulating film or an oxynitride insulating film may be used as the insulating layer 255b. Although this embodiment illustrates an example in which a recessed portion is provided in the insulating layer 255b, a recessed portion is not necessarily provided in the insulating layer 255b.

The light-emitting device 110R, the light-emitting device 110G, and the light-receiving device 150 are provided over the insulating layer 255b. The structures of the light-emitting device and the light-receiving device described in Embodiment 1 can be employed for the light-emitting device 110R, the light-emitting device 110G, and the light-receiving device 150. An insulator is provided between the light-emitting devices adjacent to each other and between the light-emitting device and the light-receiving device adjacent thereto. In FIG. 28, the insulating layer 182a and the insulating layer 182b over the insulating layer 182a are provided in the region.

The electrode 111a, the electrode 111b, and the electrode 111d of the light-emitting devices are each electrically connected to one of the source and the drain of the transistor 310 through a plug 256 embedded in the insulating layers 255a and 255b, the conductive layer 241 embedded in the insulating layer 254, and the plug 271 embedded in the insulating layer 261. The level of the top surface of the insulating layer 255b and the level of the top surface of the plug 256 are equal to or substantially equal to each other. A variety of conductive materials can be used for the plugs.

A protective layer 131 is provided over the light-emitting device 110R, the light-emitting device 110G, and the light-receiving device 150. A substrate 120 is bonded to the protective layer 131 with a resin layer 122. Embodiment 1 can be referred to for details of the light-emitting devices and the components thereover up to the substrate 120. The substrate 120 corresponds to the substrate 292 in FIG. 27A.

End portions of the top surfaces of the electrode 111a, the electrode 111b, and the electrode 111d are not covered with an insulating layer. This allows the distance between adjacent light-emitting devices to be extremely narrowed. As a result, the display apparatus can have high resolution or high definition.

Although FIG. 4B or the like, the EL layer 175R, the EL layer 175G, and the EL layer 175B included in the light-emitting device 110R, the light-emitting device 110G, and the light-emitting device 110B, respectively, have different structures from each other, the EL layer 175R, the EL layer 175G, and the EL layer 175B may have the same structure.

For example, each of the light-emitting device 110R, the light-emitting device 110G, and the light-emitting device 110B can emit white light. In addition, coloring layers may be provided in regions overlapping with the light-emitting devices 110. A coloring layer transmitting red light is provided in a region overlapping with the light-emitting device 110R, whereby light emitted from the light-emitting device 110R is extracted as red light outside the display apparatus through the coloring layer. Similarly, a coloring layer transmitting green light is provided in a region overlapping with the light-emitting device 110G, whereby light emitted from the light-emitting device 110G is extracted as green light outside the display apparatus through the coloring layer. A coloring layer transmitting blue light is provided in a region overlapping with the light-emitting device 110B, whereby light emitted from the light-emitting device 110B is extracted as blue light outside the display apparatus through the coloring layer.

### <Display Apparatus 100B>

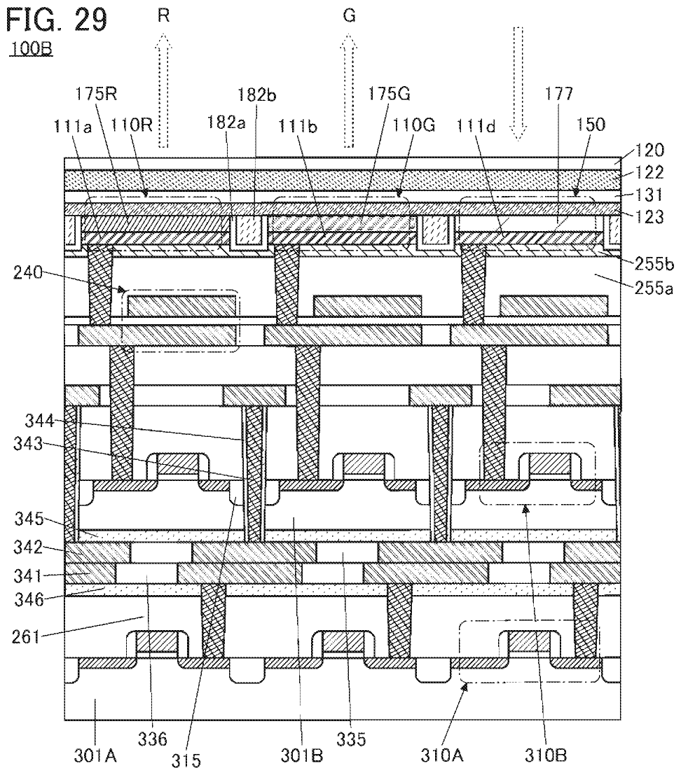

The display apparatus 100B illustrated in FIG. 29 has a structure in which a transistor 310A and a transistor 310B in each of which a channel is formed in a semiconductor substrate are stacked. Note that in the description of the display apparatus below, portions similar to those of the above-mentioned display apparatus are not described in some cases.

In the display apparatus 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 131 or an insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (a surface opposite to the substrate 120). The conductive layer 342 is preferably provided to be embedded in the insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-copper) direct bonding (a technique for achieving electrical continuity by connecting Cu (copper) pads).

### <Display Apparatus 100C>

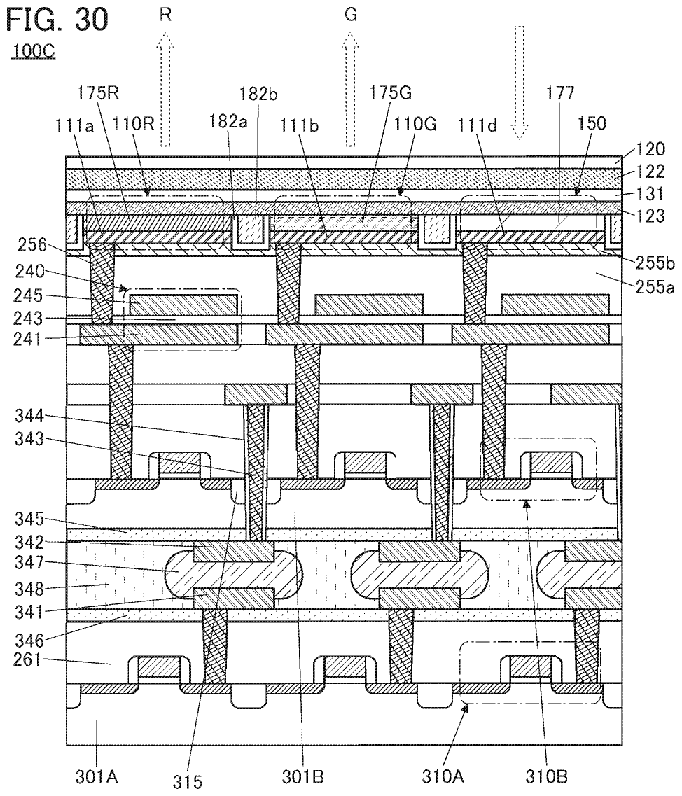

The display apparatus 100C illustrated in FIG. 30 has a structure where the conductive layer 341 and the conductive layer 342 are bonded to each other through a bump 347.

As illustrated in FIG. 30, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### <Display Apparatus 100D>

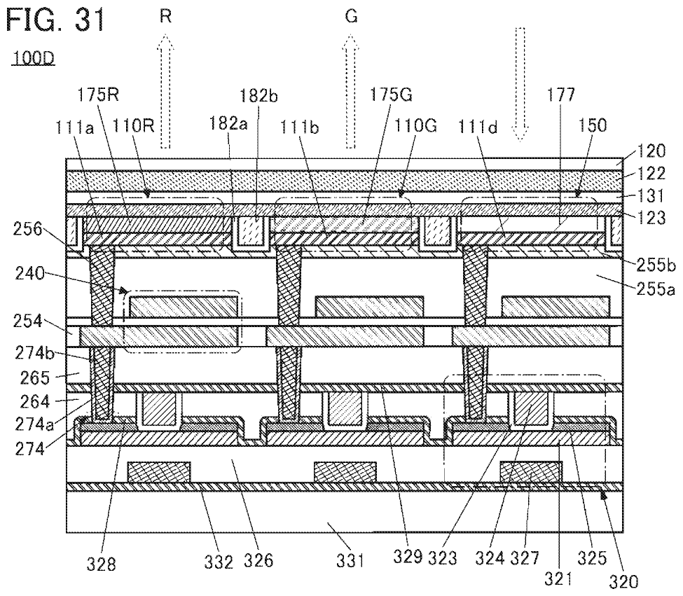

The display apparatus 100D illustrated in FIG. 31 differs from the display apparatus 100A mainly in a structure of a transistor.

A transistor 320 is a transistor in which a metal oxide (also referred to as an oxide semiconductor) is used in a semiconductor layer in which a channel is formed (hereinafter, the transistor is referred to as OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 27A and FIG. 27B. A stacked-layer structure including the substrate 331 and the components thereover up to the insulating layer 255b corresponds to the substrate 101 in Embodiment 1. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. For at least part of the insulating layer 326 that is in contact with the semiconductor layer 321, an oxide insulating film such as a silicon oxide film is preferably used. The top surface of the insulating layer 326 is preferably planarized.

The semiconductor layer 321 is provided over the insulating layer 326. The semiconductor layer 321 preferably includes a film of a metal oxide exhibiting semiconductor characteristics (an oxide semiconductor). The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that their levels are aligned to or substantially aligned to each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water or hydrogen from the insulating layer 265 or the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, the insulating layer 264, and the insulating layer 328. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material in which hydrogen and oxygen are unlikely to diffuse is preferably used for the conductive layer 274a.

### <Display Apparatus 100E>

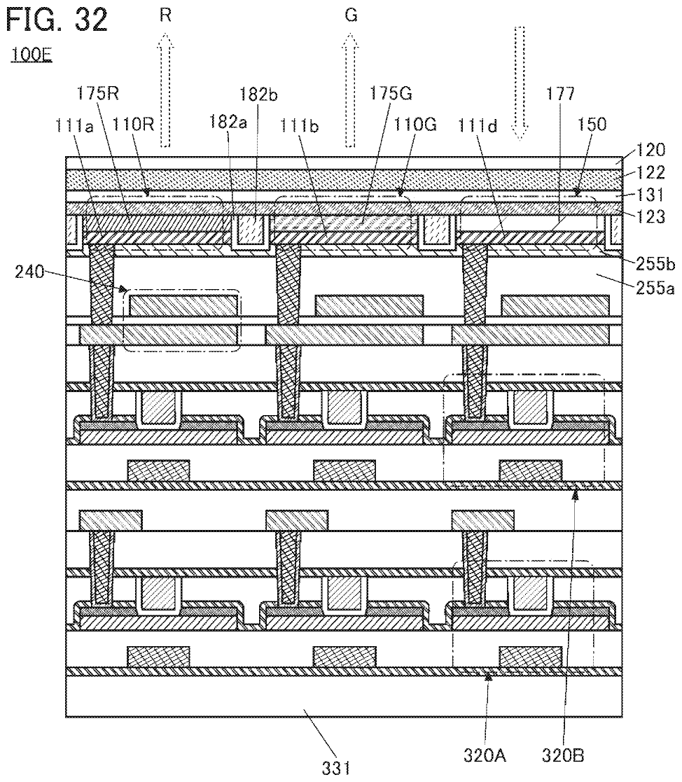

The display apparatus 100E illustrated in FIG. 32 has a structure in which a transistor 320A and a transistor 320B each including an oxide semiconductor in a semiconductor where a channel is formed are stacked.

The description of the display apparatus 100D can be referred to for the transistor 320A, the transistor 320B, and the components around them.

Although the structure where two transistors including an oxide semiconductor are stacked is described, the present invention is not limited thereto. For example, three or more transistors may be stacked.

### <Display Apparatus 100F>

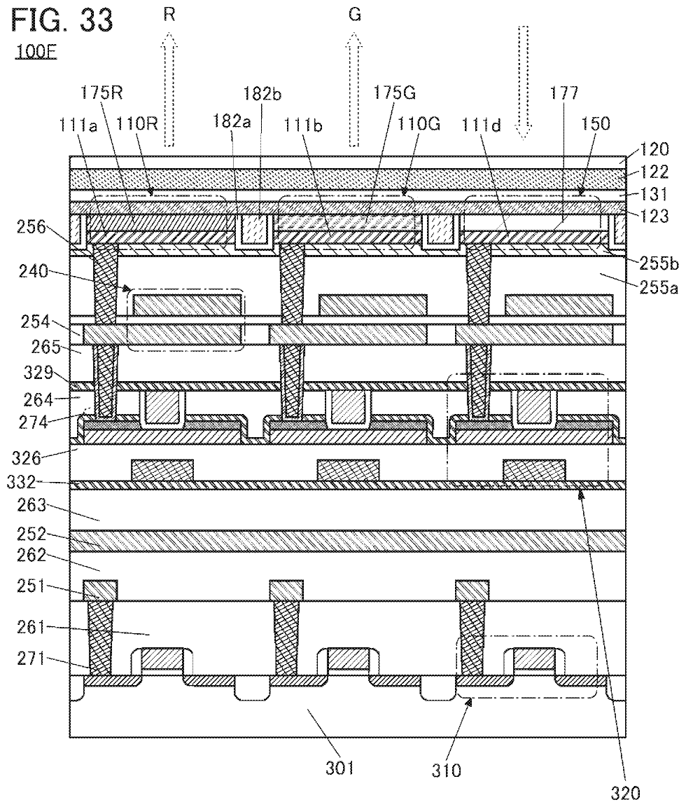

The display apparatus 100F illustrated in FIG. 33 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. The transistor 310 can also be used as a transistor included in a pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display apparatus can be downsized as compared with the case where the driver circuit is provided around a display region.

### <Display Apparatus 100G>

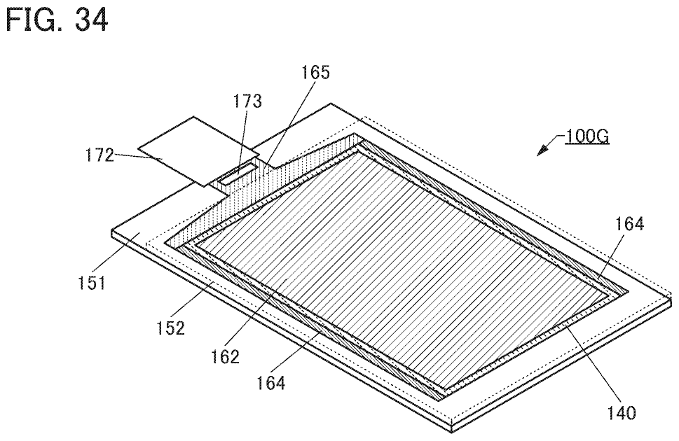

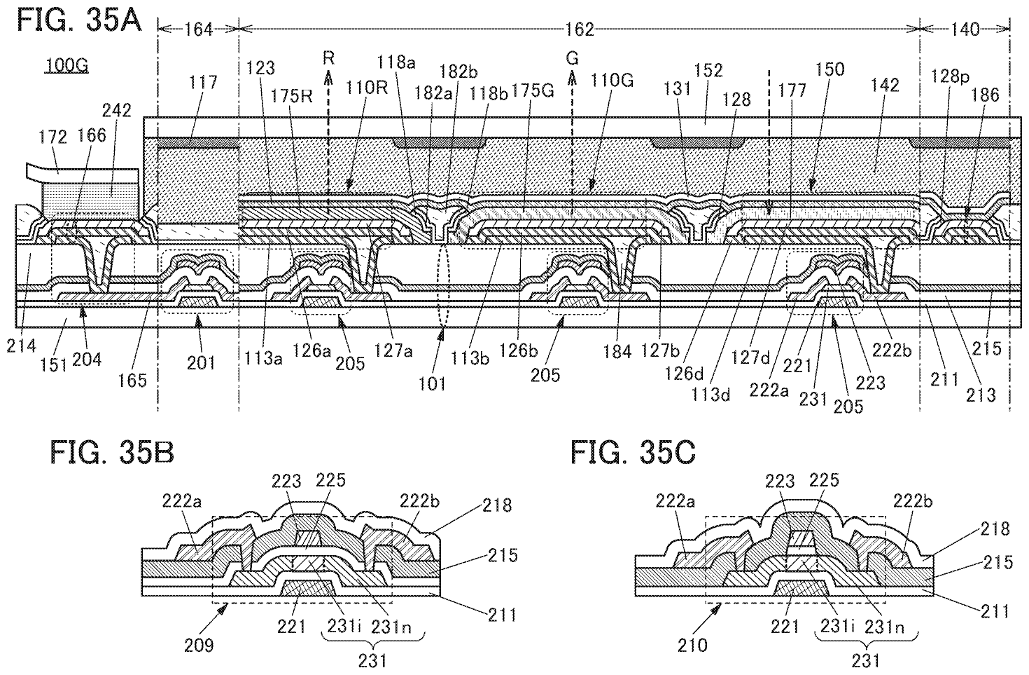

FIG. 34 is a perspective view of a display apparatus 100G, and FIG. 35A is a cross-sectional view of the display apparatus 100G.

In the display apparatus 100G, a substrate 152 and a substrate 151 are bonded to each other. In FIG. 34, the substrate 152 is denoted by a dashed line.

The display apparatus 100G includes a display portion 162, the connection portion 140, a circuit 164, a wiring 165, and the like. FIG. 34 illustrates an example where an IC 173 and an FPC 172 are mounted on the display apparatus 100G. Thus, the structure illustrated in FIG. 34 can be regarded as a display module including the display apparatus 100G, the IC (integrated circuit), and the FPC.

The connection portion 140 is provided outside the display portion 162. The connection portion 140 can be provided along one or more sides of the display portion 162. The number of connection portions 140 can be one or more. FIG. 34 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and electric power to the display portion 162 and the circuit 164. The signal and electric power are input to the wiring 165 from the outside through the FPC 172 or from the IC 173.

FIG. 34 illustrates an example in which the IC 173 is provided over the substrate 151 by a COG (Chip On Glass) method, a COF (Chip on Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 35A illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 35A includes a transistor 201, transistors 205, the light-emitting device 110R, the light-emitting device 110G, the light-receiving device 150, and the like between the substrate 151 and the substrate 152.

The description of Embodiment 1 can be referred to for the structures of the light-emitting device 110R, the light-emitting device 110G, and the light-receiving device 150, except for the structure of the pixel electrode.

The light-emitting device 110R includes a conductive layer 113a, a conductive layer 126a over the conductive layer 113a, and a conductive layer 127a over the conductive layer 126a. All of the conductive layer 113a, the conductive layer 126a, and the conductive layer 127a can be referred to as the pixel electrode, or one or two of them can be referred to as the pixel electrode.

The light-emitting device 110G includes the conductive layer 113b, the conductive layer 126b over the conductive layer 113b, and the conductive layer 127b over the conductive layer 126b.

The light-receiving device 150 includes a conductive layer 113d, a conductive layer 126d over the conductive layer 113d, and a conductive layer 127d over the conductive layer 126d.

The conductive layer 113a is connected to the conductive layer 222b included in the transistor 205 through an opening provided in an insulating layer 214. The end portion of the conductive layer 126a is positioned on the outer side of the end portion of the conductive layer 113a. The end portion of the conductive layer 126a and the end portion of the conductive layer 127a are aligned or substantially aligned with each other. For example, a conductive layer functioning as a reflective electrode can be used as the conductive layer 113a and the conductive layer 126a, and a conductive layer functioning as a transparent electrode can be used as the conductive layer 127a.

The description of the conductive layer 113a, the conductive layer 126a, and the conductive layer 127a can be referred to for the conductive layer 113b, the conductive layer 126b, and the conductive layer 127b in the light-emitting device 110G and the conductive layer 113d, the conductive layer 126d, and the conductive layer 127d in the light-emitting device in the light-receiving device 150; thus, the detailed description thereof is omitted.

Depressed portions are formed on the conductive layer 113a, the conductive layer 113b, and the conductive layer 113d to cover the openings provided in the insulating layer 214. A layer 184 is embedded in each of the depressed portions.

The layer 184 has a function of enabling planarization in the depressed portions of the conductive layer 113a, the conductive layer 113b, and the conductive layer 113d. The conductive layers 126a, 126b, and 126d electrically connected to the conductive layer 113a, the conductive layer 113b, and the conductive layer 113d, respectively, are provided over the conductive layer 113a, the conductive layer 113b, the conductive layer 113d, and the layer 184. Thus, regions overlapping with the depressed portions of the conductive layer 113a, the conductive layer 113b, and the conductive layer 113d can also be used as the light-emitting regions, increasing the aperture ratio of the pixels.

The layer 184 may be an insulating layer or a conductive layer. Any of a variety of inorganic insulating materials, organic insulating materials, and conductive materials can be used for the layer 184 as appropriate. In particular, the layer 184 is preferably formed using an insulating material.

An insulating layer containing an organic material can be suitably used for the resin layer 184. For the layer 184, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 184. As the photosensitive resin, a positive photosensitive material or a negative photosensitive material can be used.

When a photosensitive resin is used, the layer 184 can be formed through only light-exposure and development steps, reducing the influence of dry etching, wet etching, or the like on the surfaces of the conductive layer 113a, the conductive layer 113b, and the conductive layer 113d. When the layer 184 is formed using a negative photosensitive resin, the layer 184 can sometimes be formed using the same photomask (light-exposure mask) as the photomask used for forming the opening in the insulating layer 214.

Note that although FIG. 35A shows an example in which the top surface of the layer 184 has a flat surface, one embodiment of the present invention is not limited thereto. Moreover, in the cross-sectional view, the top surface of the insulating layer 184 has a shape that is recessed in the center and its vicinity, i.e., may have a concave curved surface, for example. Moreover, in the cross-sectional view, the top surface of the insulating layer 184 has a shape that is bulged in the center and its vicinity, i.e., has a convex curved surface. The top surface of the layer 184 may include one or both of a convex surface and a concave surface. The number of convex surfaces and the number of concave surfaces included in the top surface of the layer 184 are not limited and can each be one or more.

The level of the top surface of the layer 184 and the level of the top surface of the conductive layer 113 may be aligned or substantially aligned with each other, or may be different from each other. For example, the level of the top surface of the layer 184 may be either lower or higher than the level of the top surface of the conductive layer 113.

The top and side surfaces of the conductive layer 126a and the top and side surfaces of the conductive layer 127a are covered with the EL layer 175R. Similarly, the top surface and side surfaces of the conductive layer 126b and the top and side surfaces of the conductive layer 127b are covered with the EL layer 175G. The top and side surfaces of the conductive layer 126d and the top and side surfaces of the conductive layer 127d are covered with light-receiving layer 177. Accordingly, regions provided with the conductive layer 126a and the conductive layer 126b can be entirely used as the light-emitting regions of the light-emitting device 110R and the light-emitting device 110G, which enables the aperture ratio of the pixels to be increased. Similarly, a region provided with the conductive layer 126d can be entirely used as the light-receiving region of the light-emitting device 150, which enables the display apparatus to have a highly sensitive light-receiving function.

Each of the side surfaces of the EL layer 175R, the EL layer 175G, and the light-receiving layer 177 is covered with the insulating layer 182a and the insulating layer 182b. The sacrificial layer 118a is positioned between the EL layer 175R and the insulating layer 182a. The sacrificial layer 118b is positioned between the EL layer 175G and the insulating layer 182a, and the sacrificial layer 128 is positioned between the light-receiving layer 177 and the insulating layer 182a. The common electrode 123 is provided over the EL layer 175R, the EL layer 175G, the light-receiving layer 177, the insulating layer 182a, and the insulating layer 182b. The common electrode 123 is one continuous film shared by the plurality of light-emitting devices 110 and the light-receiving device 150.

The protective layer 131 is provided over the light-emitting device 110R, the light-emitting device 110G, and the light-receiving device 150. The protective layer 131 and the substrate 152 are bonded to each other with an adhesive layer 142. A solid sealing structure, a hollow sealing structure, or the like can be employed to seal the light-emitting devices. In FIG. 35A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting device. The space may be filled with a resin different from that of the frame-like adhesive layer 142.

A conductive layer 186 is provided over the insulating layer 214 in the connection portion 140. An example is described in which the conductive layer 186 has a stacked-layer structure of a conductive film obtained by processing the same conductive film as the conductive layer 113a, the conductive layer 113b, and the conductive layer 113d; a conductive film obtained by processing the same conductive film as the conductive layer 126a, the conductive layer 126b, and the conductive layer 126d; and a conductive film obtained by processing the same conductive film as the conductive layer 127a, the conductive layer 127b, and the conductive layer 127d. An end portion of the conductive layer 186 is covered with the sacrificial layer 128p, the insulating layer 182a, and the insulating layer 182b. The common electrode 123 is provided over the conductive layer 186. The conductive layer 186 is electrically connected to the common electrode 123. The conductive layer 186 and the common electrode 123 may be electrically connected to each in a state they are in direct in contact with each other, or may be electrically connected to each other through another conductive layer.

The display apparatus 100G has a top-emission structure. Light from the light-emitting device is emitted toward the substrate 152. For the substrate 152, a material having a high visible-light-transmitting property is preferably used. The pixel electrode contains a material that reflects visible light, and a counter electrode (common electrode 123) contains a material that transmits visible light.

A stacked-layer structure including the substrate 151 and the components thereover up to the insulating layer 214 corresponds to the substrate 101 in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen are not easily diffused is preferably used for at least one of the insulating layers covering the transistors. This is because such an insulating layer can function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The uppermost layer of the insulating layer 214 preferably has a function of an etching protective layer. Accordingly, a depressed portion can be prevented from being formed in the insulating layer 214 at the time of processing the conductive layer 113a, the conductive layer 126a, the conductive layer 127a, or the like. Alternatively, a depressed portion may be formed in the insulating layer 214 at the time of processing the conductive layer 113a, the conductive layer 126a, the conductive layer 127a, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. Either of a top-gate transistor structure and a bottom-gate transistor structure can be used. Alternatively, gates may be provided above and below a semiconductor layer in which a channel is formed.

The structure in which the semiconductor layer in which a channel is formed is provided between two gates is used for the transistor 201 and the transistor 205. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor). That is, an OS transistor is preferably used as the transistor included in the display apparatus of this embodiment.

As the oxide semiconductor having crystallinity, a CAAC (c-axis aligned crystalline)-OS, an nc (nanocrystalline)-OS, and the like are given.

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter, also referred to as an LTPS transistor) can be used. The LTPS transistor has high field-effect mobility and favorable frequency characteristics.

With use of Si transistors such as LTPS transistors, a circuit required to be driven at a high frequency (e.g., a source driver circuit) can be formed on the same substrate as the display portion. Thus, external circuits mounted on the display apparatus can be simplified, and costs of parts and mounting costs can be reduced.

An OS transistor has extremely higher field-effect mobility than a transistor using amorphous silicon. In addition, the OS transistor has an extremely low leakage current between a source and a drain in an off state (hereinafter also referred to as off-state current), and charge accumulated in a capacitor that is connected in series to the transistor can be retained for a long period. Furthermore, power consumption of the display apparatus can be reduced with an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than the off-state current of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when the transistor operates in a saturation region, an OS transistor can feed more stable current (saturation current) than a Si transistor even when the source-drain voltage gradually increases. Thus, by using an OS transistor as the driving transistor, stable current can be fed through the light-emitting device even when the current-voltage characteristics of the EL device vary, for example. In other words, when the OS transistor operates in the saturation region, the source-drain current hardly changes with an increase in the source-drain voltage; hence, the emission luminance of the light-emitting device can be stable.

As described above, with use of an OS transistor as a driving transistor included in the pixel circuit, it is possible to achieve “inhibition of black floating”, “increase in emission luminance”, “increase in gray level”, “inhibition of variation in light-emitting devices”, and the like.

The semiconductor layer preferably includes indium, an element M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the semiconductor layer is In-M-Zn oxide, the atomic ratio of In is preferably greater than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, and In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistor included in the circuit 164 and the transistor included in the display portion 162 may have the same structure or different structures. One structure or two or more kinds of structures may be employed for a plurality of transistors included in the circuit 164. Similarly, one structure or two or more kinds of structures may be employed for a plurality of transistors included in the display portion 162.

All of the transistors included in the display portion 162 may be OS transistors or all of the transistors included in the display portion 162 may be Si transistors. Alternatively, some of the transistors included in the display portion 162 may be OS transistors and the others may be Si transistors.

For example, when both an LTPS transistor and an OS transistor are used in the display portion 162, the display apparatus with low power consumption and high drive capability can be achieved. Note that a structure in which an LTPS transistor and an OS transistor are used in combination is referred to as LTPO in some cases. As a favorable example, it is preferable to use an OS transistor as a transistor or the like functioning as a switch for controlling electrical continuity between wirings and an LTPS transistor as a transistor or the like for controlling current.

For example, one transistor included in the display portion 162 functions as a transistor for controlling current flowing through the light-emitting device and can also be referred to as a driving transistor. One of a source and a drain of the driving transistor is electrically connected to a pixel electrode of the light-emitting device. An LTPS transistor is preferably used as the driving transistor. In that case, the amount of current flowing through the light-emitting device can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

FIG. 35B and FIG. 35C illustrate other structure examples of transistors.

The transistor 209 and the transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the low-resistance regions 231n, the conductive layer 222b connected to the other low-resistance region 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 35B illustrates an example of the transistor 209 where the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 35C, the insulating layer 225 overlaps with the channel formation region 231i of the semiconductor layer 231 and does not overlap with the low-resistance regions 231n. The structure illustrated in FIG. 35C can be manufactured by processing the insulating layer 225 using the conductive layer 223 as a mask, for example. In FIG. 35C, the insulating layer 215 is provided to cover the insulating layer 225 and the conductive layer 223, and the conductive layer 222a and the conductive layer 222b are connected to the corresponding low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is described in which the conductive layer 166 has a stacked-layer structure of a conductive film obtained by processing the same conductive film as the conductive layer 113a, the conductive layer 113b, and the conductive layer 113d; a conductive film obtained by processing the same conductive film as the conductive layer 126a, the conductive layer 126b, and the conductive layer 126d; and a conductive film obtained by processing the same conductive film as the conductive layer 127a, the conductive layer 127b, and the conductive layer 127d. On the top surface of the connection portion 204, the conductive layer 166 is exposed. Thus, the connection portion 204 and the FPC 172 can be electrically connected to each other through the connection layer 242.

A light-blocking layer 117 is preferably provided on the surface of the substrate 152 on the substrate 151 side. The light-blocking layer 117 can be provided between adjacent light-emitting devices, in the connection portion 140, and in the circuit 164, for example. A variety of optical members can be arranged on the outer surface of the substrate 152.

The protective layer 131 covering the light-emitting device can inhibit an impurity such as water from entering the light-emitting device, and increase the reliability of the light-emitting device.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### <Display Apparatus 100H>

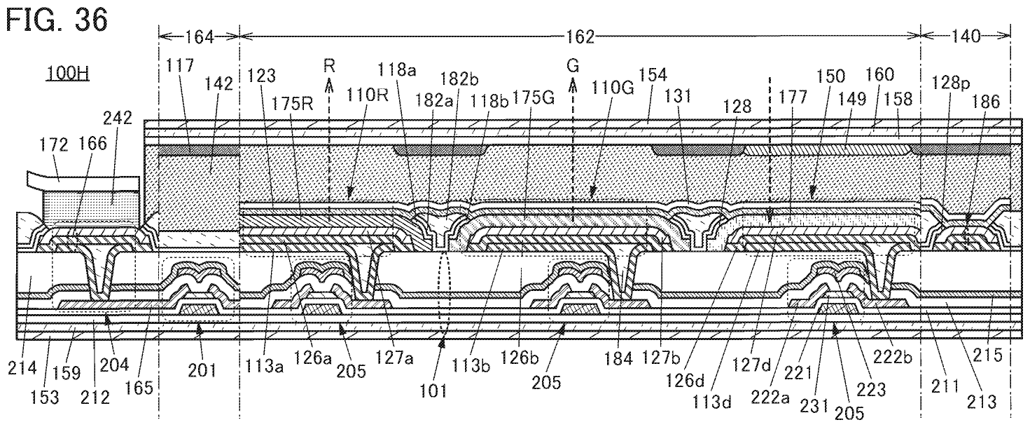

FIG. 36 illustrates a modification example of the display apparatus 100G. The display apparatus 100H differs from the display apparatus 100G mainly in that a substrate 153 instead of the substrate 151, an adhesive layer 159, and an insulating layer 212 are included and that a substrate 154 instead of the substrate 152, an adhesive layer 160, and an insulating layer 158 are included.

In the display apparatus 100H, the substrate 153 and the insulating layer 212 are bonded to each other with the adhesive layer 159. In addition, the substrate 154 and the insulating layer 158 are bonded to each other with the adhesive layer 160.

In FIG. 36, a filter 149 that filters out ultraviolet light is provided in a region overlapping with the light-receiving device 150. Note that a structure without the filter 149 can be employed.

When the display apparatus 100H illustrated in FIG. 36 is manufactured, first, a first manufacture substrate provided with the insulating layer 212, each transistor, the light-emitting device 110, the light-receiving device 150, and the like and a second manufacture substrate provided with the insulating layer 158, the light-blocking layer 117, the filter 149, and the like are bonded to each other with the adhesive layer 142. Then, the substrate 153 is bonded to a surface where the first manufacture substrate is separated and exposed with the adhesive layer 159. Accordingly, each component formed over the first manufacture substrate is transferred onto the substrate 153. In addition, the substrate 154 is bonded to a surface where the second manufacture substrate is separated and exposed with the adhesive layer 160. Accordingly, each component formed over the second manufacture substrate is transferred onto the substrate 154. The substrate 153 and the substrate 154 are preferably flexible. Accordingly, the display device 100H can be flexible. That is, the display apparatus 100H can be a flexible display.

The inorganic insulating film that can be used for the insulating layer 211, the insulating layer 213, and the insulating layer 215 can be used for the insulating layer 212 and the insulating layer 158.

This embodiment can be combined with the other embodiments as appropriate.

### Embodiment 3

In this embodiment, a light-emitting device that can be used in the display apparatus of one embodiment of the present invention will be described.

### <Structure Example of Light-Emitting Device>

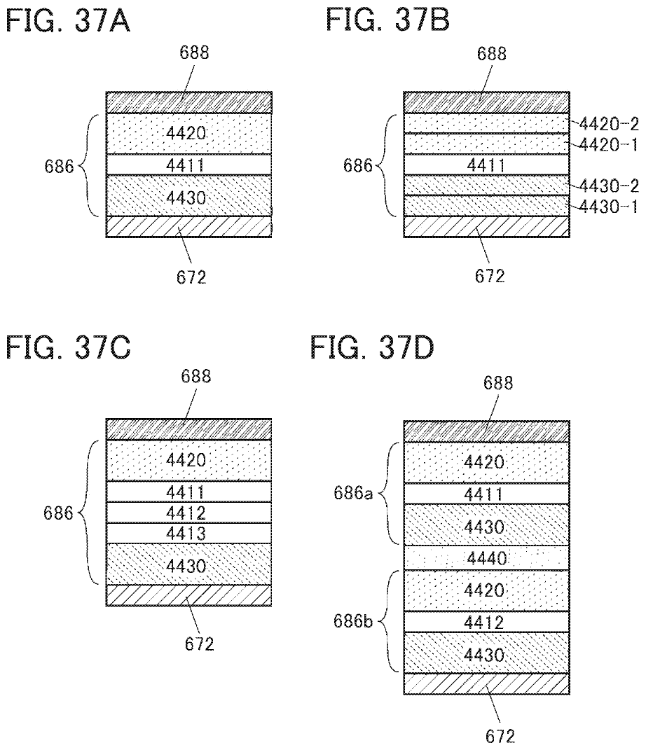

As illustrated in FIG. 37A, a light-emitting device includes an EL layer 686 between a pair of electrodes (an electrode 672 and an electrode 688). The EL layer 686 can be formed of a plurality of layers such as a layer 4420, a light-emitting layer 4411, and a layer 4430. The layer 4420 can include, for example, a layer containing a substance having a high electron-injection property (an electron-injection layer) and a layer containing a substance having a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between the pair of electrodes, can serve as a single light-emitting unit, and the structure in FIG. 37A is referred to as a single structure in this specification.

FIG. 37B is a modification example of the EL layer 686 included in the light-emitting device illustrated in FIG. 37A. Specifically, the light-emitting device illustrated in FIG. 37B includes a layer 4430-1 over the electrode 672, a layer 4430-2 over the layer 4430-1, the light-emitting layer 4411 over the layer 4430-2, a layer 4420-1 over the light-emitting layer 4411, a layer 4420-2 over the layer 4420-1, and the electrode 688 over the layer 4420-2. For example, in the case where the electrode 672 is an anode and the electrode 688 is a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the electrode 672 is as a cathode and the electrode 688 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. Such a layer structure enables efficient carrier injection into the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 37C is a variation of the single structure.

The structure in which a plurality of light-emitting units (an EL layer 686a and an EL layer 686b) are connected in series with an intermediate layer (charge-generation layer) 4440 therebetween as illustrated in FIG. 37D is referred to as a tandem structure in this specification. Note that in this specification and the like, the structure illustrated in FIG. 37D is referred to as a tandem structure; however, without being limited to this, a tandem structure may be referred to as a stack structure, for example. The tandem structure enables a light-emitting device capable of high-luminance light emission.

Also in FIG. 37C and FIG. 37D, the layer 4420 and the layer 4430 may each have a stacked-layer structure of two or more layers as illustrated in FIG. 37B.

The emission colors of the light-emitting devices can be changed to red, green, blue, cyan, magenta, yellow, white, or the like depending on a material of the EL layer 686. Furthermore, the color purity can be further increased when the light-emitting device has a microcavity structure.

The light-emitting device that emits white light preferably contains two or more kinds of light-emitting substances in the light-emitting layer. To obtain white light emission, two kinds of light-emitting substances are selected so that their emission colors have a relationship of complementary colors. For example, when an emission color of a first light-emitting layer and an emission color of a second light-emitting layer are complementary colors, the light-emitting device as a whole can be configured to emit white light. When three or more kinds of light-emitting substances are used, the light-emitting device is configured to emit white light as a whole by combining their emission colors. The same applies to a light-emitting device including three or more light-emitting layers.

The light-emitting layer preferably contains two or more selected from light-emitting substances that emit light of red (R), green (G), blue (B), yellow (Y), orange (O), and the like. Alternatively, the light-emitting layer preferably contains two or more light-emitting substances that emit light containing two or more of spectral components of R, G, and B.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 4

In this embodiment, a structure of a light-emitting and light-receiving device that can be used in a display apparatus of one embodiment of the present invention will be described. The structure can be the one in which a light-emitting and light-receiving device is added to the above-described display apparatus. Alternatively, the structure can be the one in which the light-receiving device is replaced with a light-emitting and light-receiving device. The display apparatus of one embodiment of the present invention can have a structure including a light-emitting device, a light-receiving device, and a light-emitting and light-receiving device. Alternatively, the display apparatus of one embodiment of the present invention can have a structure including a light-emitting device and a light-emitting and light-receiving device.

The light-emitting and light-receiving device has a light-emitting function and a light-receiving function. Here, a light-emitting and light-receiving device that emits red light and has a light-receiving function is described as an example. Note that for a method for manufacturing the light-emitting and light-receiving device, the above description of the method for manufacturing a light-receiving device can be referred to, and thus detailed description is omitted. Alternatively, for the method for manufacturing the light-emitting and light-receiving device, the above description of the method for manufacturing a light-emitting device can be referred to, and thus detailed description is omitted.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

In this embodiment, a top-emission display apparatus is described as an example.

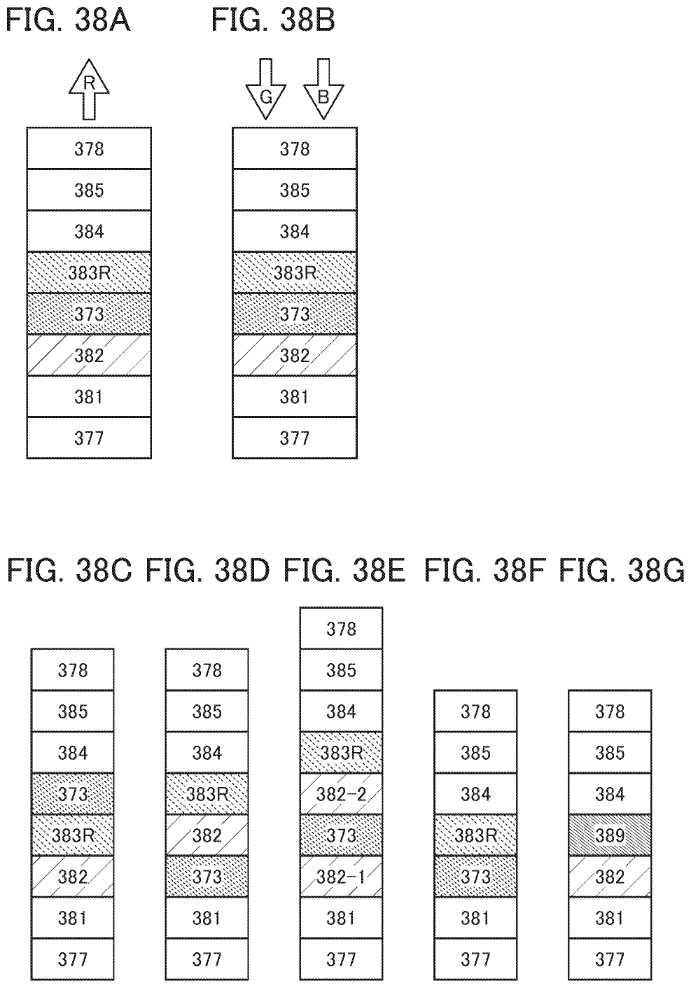

A light-emitting and light-receiving device illustrated in FIG. 38A includes an electrode 377, a hole-injection layer 381, a hole-transport layer 382, an active layer 373, a light-emitting layer 383R, an electron-transport layer 384, an electron-injection layer 385, and an electrode 378 that are stacked in this order.

The light-emitting layer 383R includes a light-emitting material that emits red light. The active layer 373 contains an organic compound that absorbs visible light. Alternatively, the active layer 373 may contain an organic compound that absorbs visible light and infrared light. Alternatively, the active layer 373 may contain an organic compound that absorbs visible light and an organic compound that absorbs infrared light. Note that it is preferable that the organic compound contained in the active layer 373 hardly absorbs at least light emitted by the light-emitting layer 383R. Thus, red light can be efficiently extracted from the light-emitting and light-receiving device, and one or more of light having a shorter wavelength than red light (e.g., green light and blue light) and light having a longer wavelength than red light (e.g., infrared light) can be detected with high accuracy.

FIG. 38A schematically shows that the light-emitting and light-receiving device functions as a light-emitting device. In FIG. 38A, red (R) light emitted from the light-emitting and light-receiving device is indicated by an arrow.

FIG. 38B schematically shows that the light-emitting and light-receiving device functions as a light-receiving device. In FIG. 38B, blue light (B) and green light (G) that are incident on the light-emitting and light-receiving device are indicated by arrows.

When voltage is applied between the electrode 377 and the electrode 378 in the light-emitting and light-receiving device, light incident on the light-emitting and light-receiving device can be detected and charge can be generated and extracted as current.

The light-emitting and light-receiving device can be regarded as having a structure of a light-emitting device to which the active layer 373 is added. That is, the light-emitting and light-receiving device can be formed concurrently with formation of a light-emitting device only by adding a step of depositing the active layer 373 in the manufacturing process of the light-emitting device. The light-emitting device and the light-emitting and light-receiving device can be formed over the same substrate. Thus, one or both of an image capturing function and a sensing function can be provided to the display portion without a significant increase in the number of manufacturing steps.

The stacking order of the light-emitting layer 383R and the active layer 373 is not limited. In the example illustrated in FIG. 38A and FIG. 38B, the active layer 373 is provided over the hole-transport layer 382, and the light-emitting layer 383R is provided over the active layer 373. The stacking order of the light-emitting layer 383R and the active layer 373 may be reversed, for example.

The light-emitting and light-receiving device may exclude at least one of the hole-injection layer 381, the hole-transport layer 382, the electron-transport layer 384, and the electron-injection layer 385. Furthermore, the light-emitting and light-receiving device may include another functional layer such as a hole-blocking layer or an electron-blocking layer.

In the light-emitting and light-receiving device, a conductive film that transmits visible light is used as the electrode through which light is extracted. A conductive film that reflects visible light is preferably used as the electrode through which light is not extracted.

The functions and materials of the layers constituting the light-emitting and light-receiving device are similar to those of the layers constituting the light-emitting devices and the light-receiving device and not described in detail here.

FIG. 38C to FIG. 38G illustrate examples of a stacked-layer structure of the light-emitting and light-receiving device.

A light-emitting and light-receiving device illustrated in FIG. 38C includes the electrode 377, the hole-injection layer 381, the hole-transport layer 382, the light-emitting layer 383R, the active layer 373, the electron-transport layer 384, the electron-injection layer 385, and the electrode 378.

In the example illustrated in FIG. 38C, the light-emitting layer 383R is provided over the hole-transport layer 382, and the active layer 373 is stacked over the light-emitting layer 383R.

As illustrated in FIG. 38A to FIG. 38C, the active layer 373 and the light-emitting layer 383R may be in contact with each other.

A buffer layer is preferably provided between the active layer 373 and the light-emitting layer 383R. In that case, the buffer layer preferably has a hole-transport property and an electron-transport property. For example, a bipolar substance is preferably used for the buffer layer. Alternatively, as the buffer layer, at least one of a hole-injection layer, a hole-transport layer, an electron-transport layer, an electron-injection layer, a hole-blocking layer, an electron-blocking layer, and the like can be used. FIG. 38D illustrates an example where the hole-transport layer 382 is used as the buffer layer.

The buffer layer provided between the active layer 373 and the light-emitting layer 383R can inhibit transfer of excitation energy from the light-emitting layer 383R to the active layer 373. Furthermore, the optical path length (cavity length) of the microcavity structure can be adjusted with the buffer layer. Thus, a high emission efficiency can be obtained from the light-emitting and light-receiving device including the buffer layer between the active layer 373 and the light-emitting layer 383R.

FIG. 38E illustrates an example in which a hole-transport layer 382-1, the active layer 373, a hole-transport layer 382-2, and the light-emitting layer 383R are stacked in this order over the hole-injection layer 381. The hole-transport layer 382-2 functions as a buffer layer. The hole-transport layer 382-1 and a hole-transport layer 281-2 may contain the same material or different materials. Instead of the hole-transport layer 281-2, any of the above layers that can be used as the buffer layer may be used. The positions of the active layer 373 and the light-emitting layer 383R may be interchanged.

The light-emitting and light-receiving device illustrated in FIG. 38F differs from the light-emitting and light-receiving device illustrated in FIG. 38A in not including the hole-transport layer 382. Thus, the light-emitting and light-receiving device may exclude at least one of the hole-injection layer 381, the hole-transport layer 382, the electron-transport layer 384, and the electron-injection layer 385. Furthermore, the light-emitting and light-receiving device may include another functional layer such as a hole-blocking layer or an electron-blocking layer.

The light-emitting and light-receiving device illustrated in FIG. 38G differs from the light-emitting and light-receiving device illustrated in FIG. 38A in including a layer 389 serving as both a light-emitting layer and an active layer instead of including the active layer 373 and the light-emitting layer 383R.

As the layer serving as both a light-emitting layer and an active layer, a layer containing three materials which are an n-type semiconductor that can be used for the active layer 373, a p-type semiconductor that can be used for the active layer 373, and a light-emitting substance that can be used for the light-emitting layer 383R can be used, for example.

An absorption band on the lowest energy side of an absorption spectrum of a mixed material of the n-type semiconductor and the p-type semiconductor and a maximum peak of an emission spectrum (PL spectrum) of the light-emitting substance preferably do not overlap with each other and are further preferably positioned fully apart from each other.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 5

In this embodiment, a metal oxide (also referred to as an oxide semiconductor) that can be used in the OS transistor described in the above embodiment will be described.

The metal oxide preferably contains at least one of indium and zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) can be given as examples of a crystal structure of an oxide semiconductor.

A crystal structure of a film or a substrate can be analyzed with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the XRD spectrum of the quartz glass substrate shows a peak with a substantially bilaterally symmetrical shape. On the other hand, the peak of the XRD spectrum of the IGZO film having a crystal structure has a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the one described above when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction described above, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, or the like.

Note that a crystal structure in which a clear crystal grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has a small amount of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS includes a void or a low-density region.

That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions randomly exist to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and less than 30%, further preferably higher than or equal to 0% and less than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), high field-effect mobility (μ), and excellent switching operation can be achieved.

A transistor using a CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration measured by secondary ion mass spectrometry (SIMS)) are lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy sometimes generates an electron serving as a carrier. Furthermore, bonding of part of hydrogen to oxygen bonded to a metal atom sometimes causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 6

In this embodiment, electronic devices each including a display apparatus of one embodiment of the present invention will be described.

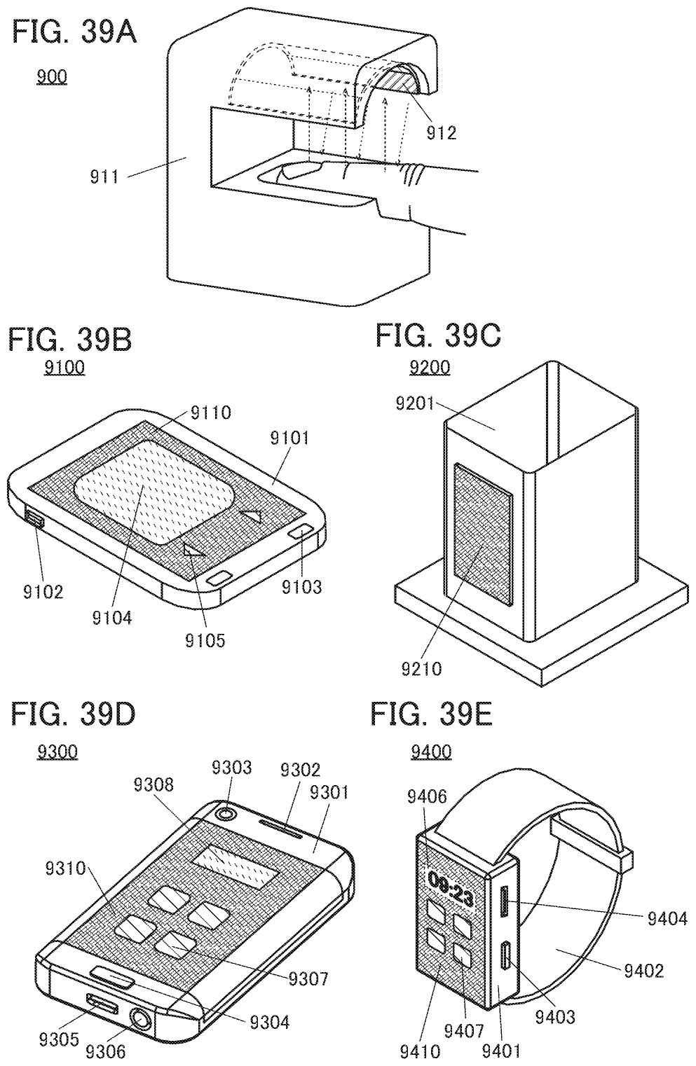

The display apparatus of one embodiment of the present invention can be provided in a variety of electronic devices. For example, the display apparatus of one embodiment of the present invention can be provided in a digital camera, a digital video camera, a digital photo frame, a portable game machine, a portable information terminal, an audio reproducing device, or the like, in addition to an electronic device with a comparatively large screen, such as a television device, a desktop or laptop computer, a tablet computer, a monitor for a computer or the like, digital signage, or a large game machine such as a pachinko machine. Structure examples of electronic device in which the display apparatus of one embodiment of the present invention can be provided are described with reference to FIG. 39A to FIG. 39E.

FIG. 39A is a diagram illustrating an example of an oximeter 900. The oximeter 900 includes a housing 911 and a light-emitting and receiving device 912. The housing 911 is provided with a cavity portion, and the light-emitting and receiving device 912 is provided to be in contact with a wall surface of the cavity portion.

The light-emitting and receiving device 912 has a function of a light source that emits light and a function of a sensor that detects light. For example, in the case where a target is put in the cavity portion of the housing 911, light that is emitted by the light-emitting and receiving device 912, irradiates the target, and is reflected by the target can be detected by the light-emitting and receiving device 912.

For example, in the case where a finger is put in the cavity portion of the housing 911, the color of blood is changed depending on oxygen saturation of hemoglobin contained in the blood (the percentage of oxygen-bound hemoglobin). Thus, the intensity of light reflected by the finger that is detected by the light-emitting and receiving device 912 is changed. For example, the intensity of red light that is detected by the light-emitting and receiving device 912 is changed. Accordingly, the oximeter 900 can measure oxygen saturation through detection of the intensity of reflected light by the light-emitting and receiving device 912. The oximeter 900 can be a pulse oximeter, for example.

The display apparatus of one embodiment of the present invention can be employed in the light-emitting and receiving device 912. In this case, the light-emitting and receiving device 912 includes at least a light-emitting device that emits red light (R). In addition, the light-emitting and receiving device 912 preferably includes a light-emitting device that emits infrared light (IR). There is a large difference between the red light (R) reflectance of oxygen-bound hemoglobin and the red light (R) reflectance of oxygen-unbound hemoglobin. On the other hand, there is a small difference between the infrared light (IR) reflectance of oxygen-bound hemoglobin and the infrared light (IR) reflectance of oxygen-unbound hemoglobin. Therefore, the light-emitting and receiving device 912 includes not only a light-emitting device that emits red light (R) but also a light-emitting device that emits infrared light (IR), so that the oximeter 900 can measure oxygen saturation with high accuracy.

In the case where the display apparatus of one embodiment of the present invention is employed as the light-emitting and receiving device 912, the light-emitting and receiving device 912 is preferably flexible. When the light-emitting and receiving device 912 is flexible, the light-emitting and receiving device 912 can have a curved shape. Accordingly, the finger or the like can be irradiated with light uniformly, and oxygen saturation or the like can be measured with high accuracy.

FIG. 39B is a diagram illustrating an example of a portable data terminal 9100. The portable data terminal 9100 includes a display portion 9110, a housing 9101, a key 9102, a speaker 9103, and the like. The portable data terminal 9100 can be a tablet, for example. Here, the key 9102 can be a key for switching the on/off of a power source, for example. That is, the key 9102 can be a power switch, for example. Alternatively, the key 9102 can be an operation key to be used to make an electronic device perform a desired operation, for example.

The display portion 9110 can display information 9104, operation buttons (also referred to as operation icons or simply icons) 9105, and the like.

When the display apparatus of one embodiment of the present invention is provided in the portable data terminal 9100, the display portion 9110 can have a function of a touch sensor or a near-touch sensor.

FIG. 39C is a diagram illustrating an example of digital signage 9200. The digital signage 9200 can have a structure where a display portion 9210 is attached to a column 9201.

When the display apparatus of one embodiment of the present invention is provided in the digital signage 9200, the display portion 9210 can have a function of a touch sensor or a near-touch sensor.

FIG. 39D is a diagram illustrating an example of a portable information terminal 9300. The portable information terminal 9300 includes a display portion 9310, a housing 9301, a speaker 9302, a camera 9303, a key 9304, a connection terminal 9305, a connection terminal 9306, and the like. For example, the portable information terminal 9300 can be a smartphone. Note that the connection terminal 9305 can be a micro USB terminal, a lightning terminal, or a Type-C terminal, or the like, for example. In addition, the connection terminal 9306 can be an earphone jack, for example.

The display portion 9310 can display, for example, an operation button 9307. The display portion 9310 can also display information 9308. Examples of the information 9308 include display indicating incoming e-mails, SNS (social networking services), phone calls, and the like; the titles of e-mails, SNS, and the like; the senders of e-mails, SNS, and the like; dates; time; remaining battery; the reception strength of an antenna; and the like.

When the display apparatus of one embodiment of the present invention is provided in the portable information terminal 9300, the display portion 9310 can have a function of a touch sensor or a near-touch sensor.

FIG. 39E is a diagram illustrating an example of a wristwatch-type portable information terminal 9400. The portable information terminal 9400 includes a display portion 9410, a housing 9401, a wristband 9402, a key 9403, a connection terminal 9404, and the like. Note that the connection terminal 9404 can be a micro USB terminal, a lightning terminal, or a Type-C terminal, or the like, for example, like the connection terminal 9305 or the like.

The display portion 9410 can display information 9406, operation buttons 9407, and the like. FIG. 39E illustrates an example in which time is displayed on the display portion 9410 as the information 9406.

When the display apparatus of one embodiment of the present invention is provided in the portable information terminal 9400, the display portion 9410 can have a function of a touch sensor or a near-touch sensor.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### REFERENCE NUMERALS

20B: light-emitting device, 20G: light-emitting device, 20R: light-emitting device, 20: light-emitting device, 21a: electrode, 21b: electrode, 21c: electrode, 21d: electrode, 23: electrode, 25B: EL layer, 25G: EL layer, 25R: EL layer, 25: EL layer, 27a: first functional layer, 27b: first functional layer, 27c: first functional layer, 27: first functional layer, 29a: second functional layer, 29b: second functional layer, 29c: second functional layer, 29: second functional layer, 30PS: light-receiving device, 35PS: light-receiving layer, 37PS: third functional layer, 39PS: fourth functional layer, 41B: light-emitting layer, 41G: light-emitting layer, 41R: light-emitting layer, 43PS: active layer, 50: substrate, 52: finger, 53: layer, 57: layer, 59: substrate, 65: region, 67: fingerprint, 69: contact portion, 100A: display apparatus, 100B: display apparatus, 100C: display apparatus, 100D: display apparatus, 100E: display apparatus, 100F: display apparatus, 100G: display apparatus, 100H: display apparatus, 100: display apparatus, 101: substrate, 103: pixel, 110B: light-emitting device, 110G: light-emitting device, 110R: light-emitting device, 110: light-emitting device, 111a: electrode, 111b: electrode, 111c: electrode, 111d: electrode, 111p: electrode, 111: electrode, 112B: light-emitting layer, 112G: light-emitting layer, 112R: light-emitting layer, 112: light-emitting layer, 113a: conductive layer, 113b: conductive layer, 113d: conductive layer, 113: conductive layer, 115a: first functional layer, 115b: first functional layer, 115c: first functional layer, 115d: first functional layer, 115f: functional film, 115p: first functional layer, 115: first functional layer, 116a: second functional layer, 116b: second functional layer, 116c: second functional layer, 116d: second functional layer, 116f: functional film, 116p: second functional layer, 116: second functional layer, 117: light-blocking layer, 118a: sacrificial layer, 118b: sacrificial layer, 118c: sacrificial layer, 118f: sacrificial film, 118: sacrificial layer, 119a: sacrificial layer, 119b: sacrificial layer, 119c: sacrificial layer, 119f: sacrificial film, 120B: subpixel, 120G: subpixel, 120R: subpixel, 120: substrate, 122: resin layer, 123f: conductive layer, 123: common electrode, 125: protective layer, 126a: conductive layer, 126b: conductive layer, 126d: conductive layer, 127a: conductive layer, 127b: conductive layer, 127d: conductive layer, 128f: sacrificial film, 128p: sacrificial layer, 128: sacrificial layer, 129f: sacrificial film, 129p: sacrificial layer, 129: sacrificial layer, 130: subpixel, 131: protective layer, 133p: resist mask, 133: resist mask, 134a: resist mask, 134b: resist mask, 134c: resist mask, 135: resist mask, 140: connection portion, 142: adhesive layer, 149: filter, 150: light-receiving device, 151: substrate, 152: substrate, 153: substrate, 154: substrate, 155f: functional film, 155: third functional layer, 156f: functional film, 156: fourth functional layer, 157f: active film, 157: active layer, 158: insulating layer, 159: adhesive layer, 160: adhesive layer, 162: display portion, 164: circuit, 165: wiring, 166: conductive layer, 172: FPC, 173: IC, 175B: EL layer, 175G: EL layer, 175R: EL layer, 175: EL layer, 177: light-receiving layer, 182a: insulating layer, 182af: insulating film, 182b: insulating layer, 182: insulating layer, 184: layer, 186: conductive layer, 191B: FMM, 191G: FMM, 191R: FMM, 201: transistor, 204: connection portion, 205: transistor, 209: transistor, 210: transistor, 211: insulating layer, 212: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 373: active layer, 377: electrode, 378: electrode, 381: hole-injection layer, 382: hole-transport layer, 383R: light-emitting layer, 384: electron-transport layer, 385: electron-injection layer, 389: layer, 672: electrode, 686a: EL layer, 686b: EL layer, 686: EL layer, 688: electrode, 911: housing, 912: light-emitting and receiving device, 4411: light-emitting layer, 4412: light-emitting layer, 4413: light-emitting layer, 4420: layer, 4430: layer, 9100: portable data terminal, 9101: housing, 9102: key, 9103: speaker, 9104: information, 9110: display portion, 9200: digital signage, 9201: column, 9210: display portion, 9300: portable information terminal, 9301: housing, 9302: speaker, 9303: camera, 9304: key, 9305: connection terminal, 9306: connection terminal, 9307: operation button, 9308: information, 9310: display portion, 9400: portable information terminal, 9401: housing, 9402: wristband, 9403: key, 9404: connection terminal, 9406: information, 9407: operation button, 9410: display portion

1. A display apparatus comprising:
a light-receiving device;
a first light-emitting device; and
an insulating layer,
wherein the light-receiving device comprises a first electrode, a light-receiving layer, and a common electrode that are stacked in this order,
wherein the first light-emitting device comprises a second electrode, a first EL layer, and the common electrode that are stacked in this order,
wherein the light-receiving layer comprises a first functional layer, a second functional layer, and an active layer between the first functional layer and the second functional layer,
wherein the first functional layer comprises a first substance having a hole-transport property,
wherein the second functional layer comprises a second substance having an electron-transport property,
wherein an end portion of the active layer, an end portion of the first functional layer, and an end portion of the second functional layer are aligned or substantially aligned with one another,
wherein the first EL layer comprises a third functional layer, a fourth functional layer, and a first light-emitting layer between the third functional layer and the fourth functional layer,
wherein the third functional layer comprises a third substance having a hole-transport property,
wherein the fourth functional layer comprises a fourth substance having an electron-transport property, and
wherein the insulating layer comprises a region in contact with a side surface of the light-receiving layer and a region in contact with a side surface of the first EL layer.

2. The display apparatus according to claim 1, wherein the first substance is the same as the third substance.

3. The display apparatus according to claim 1, wherein the second substance is the same as the fourth substance.

4. The display apparatus according to claim 1,
wherein the active layer comprises a fifth substance, and
wherein the first light-emitting layer comprises a sixth substance different from the fifth substance.

5. The display apparatus according to claim 1, wherein the side surface of the light-receiving layer is perpendicular or substantially perpendicular to a surface where the light-receiving layer is formed.

6. The display apparatus according to claim 1, wherein the side surface of the first EL layer is perpendicular or substantially perpendicular to a surface where the first EL layer is formed.

7. The display apparatus according to claim 1, wherein an end portion of the first light-emitting layer, an end portion of the third functional layer, and an end portion of the fourth functional layer are aligned or substantially aligned with one another.

8. The display apparatus according to claim 7, wherein the first light-emitting layer has a smaller thickness in a region in contact with the insulating layer than a thickness in a region not in contact with the insulating layer.

9. The display apparatus according to claim 1, wherein an end portion of the first light-emitting layer is positioned more inwardly than an end portion of the third functional layer and an end portion of the fourth functional layer.

10. The display apparatus according to claim 1,
wherein an end portion of the light-receiving layer is positioned more inwardly than an end portion of the first electrode, and
wherein the insulating layer comprises a region in contact with the side surface of the light-receiving layer and a region in contact with a top surface and a side surface of the first electrode.

11. The display apparatus according to claim 1,
wherein an end portion of the first EL layer is positioned more inwardly than an end portion of the second electrode, and
wherein the insulating layer comprises a region in contact with the side surface of the first EL layer and a region in contact with a top surface and a side surface of the second electrode.

12. The display apparatus according to claim 1, wherein the active layer comprises a region in contact with the first electrode with the first functional layer therebetween.

13. The display apparatus according to claim 1, wherein the active layer comprises a region in contact with the first electrode with the second functional layer therebetween.

14. The display apparatus according to claim 1, wherein the first light-emitting layer comprises a region overlapping with the second electrode with the third functional layer therebetween.

15. The display apparatus according to claim 1, wherein the first light-emitting layer comprises a region overlapping with the second electrode with the fourth functional layer therebetween.

16. The display apparatus according to claim 1, further comprising a second light-emitting device,
wherein the second light-emitting device comprises a third electrode, a second EL layer, and the common electrode that are stacked in this order,
wherein the second EL layer comprises a fifth functional layer, a sixth functional layer, and a second light-emitting layer between the fifth functional layer and the sixth functional layer,
wherein the fifth functional layer comprises the third substance, and
wherein the sixth functional layer comprises the fourth substance.

17. The display apparatus according to claim 1, further comprising a second light-emitting device,
wherein the second light-emitting device comprises a third electrode, a second EL layer, and the common electrode that are stacked in this order, and
wherein the second EL layer comprises the third functional layer, the fourth functional layer, and a second light-emitting layer between the third functional layer and the fourth functional layer.
